(19) United States
(12) Patent Application Publication
(10) Pub. No.: US 2026/0073957 A1
(43) Pub. Date: Mar. 12, 2026

(54) SEMICONDUCTOR MEMORY DEVICE

(71) Applicant: SAMSUNG ELECTRONICS CO., LTD., Suwon-si (KR)

(72) Inventors: Keonhee PARK, Suwon-si (KR); Yeonjin LEE, Suwon-si (KR); Haewook JEONG, Suwon-si (KR)

(73) Assignee: SAMSUNG ELECTRONICS CO., LTD., Suwon-si (KR)

(21) Appl. No.: 19/323,463

(22) Filed: Sep. 9, 2025

(30) Foreign Application Priority Data
Sep. 10, 2024 (KR) 10-2024-0123426

(51) Int. Cl. G11C 5/06; G11C 11/22; H10B 53/10; H10B 53/20

(52) U.S. Cl. CPC G11C 5/063; G11C 11/221; H10B 53/10; H10B 53/20

(57) ABSTRACT

A semiconductor memory device includes a write bit line and a read word line extending in a first horizontal direction and spaced apart from each other in a second horizontal direction, a write word line, a read bit line, and a source line between the write bit line and the read word line and extending in a vertical direction and being spaced apart in the first horizontal direction, a capacitor electrode having a first portion and a second portion, a capacitor dielectric layer, a first gate dielectric layer covering a side surface of the first portion, a first channel layer covering the first gate dielectric layer, a second gate dielectric layer covering a portion of a side surface of the write word line, and a second channel layer connected to the second portion of the capacitor electrode and to the write bit line and covering the second gate dielectric layer.

### CROSS-REFERENCE TO RELATED APPLICATION

This application is based on and claims priority under 35 U.S.C. § 119 to Korean Patent Application No. 10-2024-0123426 filed on Sep. 10, 2024 in the Korean Intellectual Property office, the disclosure of which being incorporated by reference herein in its entirety.

### BACKGROUND

The present disclosure relates to a semiconductor memory device, and more particularly, to a three-dimensional (3D) two-transistor-one-capacitor (2T1C) semiconductor memory device.

As electronic products are required to be miniaturized, multi-functional, and high-performance, high-capacity semiconductor memory devices are required, and to provide high-capacity semiconductor memory devices, an increased degree of integration is required. Because the degree of integration of two-dimensional semiconductor memory devices is mainly determined by the area occupied by unit memory cells, the degree of integration of the two-dimensional semiconductor memory devices is increasing but is still limited. To address this issue, 3D semiconductor memory devices having increased memory capacity by stacking a plurality of memory cells on substrates in a vertical direction are proposed.

### SUMMARY

It is an aspect to provide a three-dimensional (3D) semiconductor memory device having improved degree of integration and improved operation reliability.

According to an aspect of one or more embodiments, there is provided a semiconductor memory device comprising a write bit line and a read word line each extending in a first horizontal direction, the write bit line being spaced apart from the read word line in a second horizontal direction orthogonal to the first horizontal direction; a write word line, a read bit line, and a source line, each between the write bit line and the read word line and extending in a vertical direction, the write word line, the read bit line, and the source line spaced apart from each other in the first horizontal direction; a capacitor electrode comprising a first portion and a second portion; a capacitor dielectric layer arranged between the capacitor electrode and the read word line; a first gate dielectric layer covering a side surface of the first portion of the capacitor electrode; a first channel layer adjacent to the read bit line and the source line and covering the first gate dielectric layer; a second gate dielectric layer covering a portion of a side surface of the write word line; and a second channel layer connected to the second portion of the capacitor electrode and to the write bit line and covering the second gate dielectric layer.

According to another aspect of one or more embodiments, there is provided a semiconductor memory device comprising a plurality of memory cells each including a capacitor, a read transistor, and a write transistor, the plurality of memory cells spaced apart from each other in rows in a first horizontal direction and in columns in a second horizontal direction, and spaced apart from each other in a vertical direction. The capacitor comprises a capacitor electrode including a first portion and a second portion, a read word line extending in the first horizontal direction, and a capacitor dielectric layer arranged between the first portion of the capacitor electrode and the read word line. The read transistor comprises a source line extending in the vertical direction, a read bit line extending in the vertical direction and spaced apart from the source line in the first horizontal direction, the first portion of the capacitor electrode, a first gate dielectric layer covering a side surface of the first portion of the capacitor electrode, and a first channel layer adjacent to each of the read bit line and the source line and covering the first gate dielectric layer. The write transistor comprises the second portion of the capacitor electrode, a bit line extending in the first horizontal direction and from the read word line in the second horizontal direction, a write word line extending in the vertical direction, a second gate dielectric layer covering a portion of a side surface of the write word line, and a second channel layer connected to the second portion of the capacitor electrode and to the write bit line and covering the second gate dielectric layer.

According to yet another aspect of one or more embodiments, there is provided a semiconductor memory device comprising a plurality of memory cells, each including a capacitor, a read transistor, and a write transistor, the plurality of memory cells spaced apart from each other in rows in a first horizontal direction and in columns a second horizontal direction, and spaced apart from each other in a vertical direction. The capacitor comprises a capacitor electrode in which a first portion having a semi-circular shape in plan view and a second portion having a bar shape extending in the first horizontal direction are integrated, a read word line extending longer than the second portion of the capacitor electrode in the first horizontal direction, and a capacitor dielectric layer arranged between the first portion of the capacitor electrode and the read word line. The read transistor comprises a source line extending in the vertical direction, a read bit line extending in the vertical direction and spaced apart from the source line in the first horizontal direction, the first portion of the capacitor electrode, a first gate dielectric layer covering a side surface of the first portion of the capacitor electrode and having a half-ring shape in plan view, a first channel layer having a half-ring shape in plan view, the first channel layer adjacent to each of the read bit line and the source line and covering the first gate dielectric layer, and a source/drain contact layer arranged between the source line and the first channel layer and arranged between the read bit line and the first channel layer. The write transistor comprises the second portion of the capacitor electrode, a write bit line extending in the first horizontal direction and spaced apart from the read word line in the second horizontal direction, a write word line extending in the vertical direction, a second gate dielectric layer covering a portion of a side surface of the write word line and having a ring shape in plan view, and a second channel layer having a half-ring shape in plan view, the second channel layer connected to each of the second portion of the capacitor electrode and the write bit line and covering the second gate dielectric layer. The write bit line is spaced apart from the read word line in the second horizontal direction, and the write word line, the read bit line, and the source line are sequentially spaced apart from each other in the first horizontal direction between the write bit line and the read word line that are spaced apart from each other in the second horizontal direction.

### BRIEF DESCRIPTION OF THE DRAWINGS

Various embodiments will be more clearly understood from the following detailed description taken in conjunction with the accompanying drawings, in which:

FIG. 1 is a perspective view of a cell memory array of a semiconductor memory device, according to an embodiment;

FIGS. 2A and 2B are respectively a perspective view of a memory cell of a semiconductor memory device and a plan view of an equivalent circuit diagram thereof, according to embodiments;

FIGS. 3A through 3D, 4A through 4D, 5A through 5D, 6A through 6D, 7A through 7D, 8A through 8D, 9A through 9D, 10A through 10D, 11A through 11D, 12A through 12D, 13A through 13D, 14A through 14C, 15A through 15C, 16A through 16C, 17A through 17C, 18A through 18C, 19A through 19C, 20A through 20C, 21A through 21C, 22A through 22C, 23A through 23D, 24A through 24D, 25A through 25D, and 26A through 26D are plan views and cross-sectional views of a manufacturing method of a semiconductor memory device according to a process sequence, according to embodiments, and FIGS. 27A through 27D are diagrams of a semiconductor memory device, according to embodiments;

FIG. 28 is a perspective view of a cell memory array of a semiconductor memory device, according to an embodiment;

FIGS. 29A and 29B are respectively a perspective view of a memory cell of a semiconductor memory device and a plan view of an equivalent circuit diagram thereof, according to embodiments;

FIGS. 30A through 30C and 31A through 31C are plan views and cross-sectional views of a manufacturing method of a semiconductor memory device according to a process sequence, according to embodiments, and FIGS. 32A through 32D are diagrams of a semiconductor memory device according to embodiments; and

FIGS. 33A and 33B are plan views of equivalent circuit diagrams of memory cells of a semiconductor memory device, according to embodiments.

### DETAILED DESCRIPTION

As used in this specification, a phrase using the form “at least one of A, B, or C” includes within its scope “only A”, “only B”, “only C”, “A and B”, “A and C”, “B and C” and “A, B, and C.”

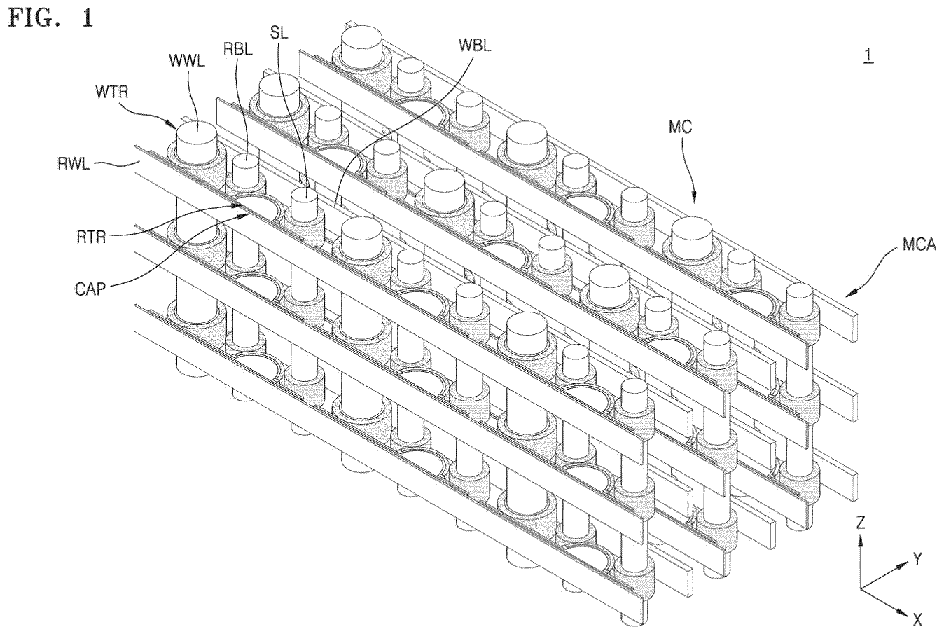

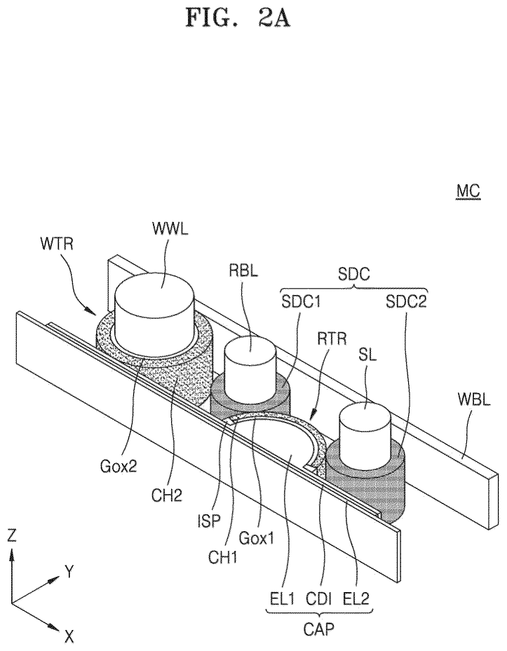

FIG. 1 is a perspective view of a cell memory array of a semiconductor memory device 1, according to an embodiment.

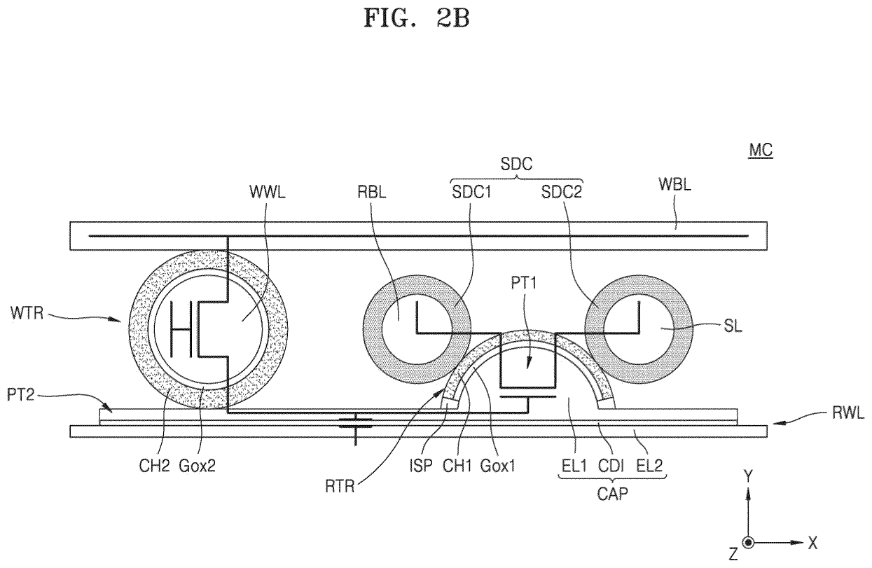

Referring to FIG. 1, the semiconductor memory device 1 may include a memory cell array MCA. The memory cell array MCA may include a plurality of memory cells MC spaced apart from each other in a first horizontal direction (e.g., an X direction), a second horizontal direction (e.g., a Y direction) orthogonal to the first horizontal direction, and spaced apart from each other in a vertical direction (e.g., Z direction), and arranged to form rows in the first horizontal direction and columns in the second horizontal direction. Each of the plurality of memory cells MC may include a write transistor WTR, a read transistor RTR, and a capacitor CAP (see also FIG. 2A). The semiconductor memory device 1 may include a semiconductor memory device of a three-dimensional (3D) two-transistor-one-capacitor (2T1C). A source of the read transistor RTR may be interconnected to a source line SL, a drain thereof may be interconnected to a read bit line RBL, and a gate thereof may be interconnected to a first electrode of a capacitor CAP. A source of the write transistor WTR may be interconnected to the first electrode of the capacitor CAP, a drain thereof may be interconnected to a write bit line WBL, and a gate thereof may be interconnected to a write word line WWL. The capacitor CAP may include the first electrode, a second electrode, and a capacitor dielectric layer arranged between the first electrode and the second electrode. The second electrode of the capacitor CAP may be referred to as a read word line RWL.

In the memory cell array MCA, a plurality of read word lines RWL may be spaced apart from each other in each of the second horizontal direction and the vertical direction, and may extend in the first horizontal direction. Each of the plurality of read word lines RWL may have a bar shape extending in the first horizontal direction. For example, the memory cells MC arranged in the first horizontal direction may share the read word line RWL.

In the memory cell array MCA, a plurality of write bit lines WBL may be spaced apart from each other in each of the second horizontal direction and the vertical direction, and may extend in the first horizontal direction. In the memory cell array MCA, the plurality of read word lines RWL and the plurality of write bit lines WBL may be alternately arranged in the second horizontal direction at the same vertical level. The memory cells MC arranged in the first horizontal direction may share the write bit line WBL.

In the memory cell array MCA, a plurality of write word lines WWL, a plurality of read bit lines RBL, and a plurality of source lines SL may be spaced apart from each other in each of the first horizontal direction and the second horizontal direction, and may extend in the vertical direction. The memory cells MC arranged in the vertical direction may share the write word line WWL, the read bit line RBL, and the source line SL. The write word line WWL, the read bit line RBL, and the source line SL may be repeatedly arranged in the first horizontal direction.

A portion of each of the plurality of read word lines RWLs corresponding to one memory cell MC, among the plurality of read word lines RWL may function as the second electrode of the capacitor CAP. The first electrodes of the capacitor CAP may be arranged apart from each other in each of the first horizontal direction, the second horizontal direction, and the vertical direction. The first electrode of the capacitor CAP may include a first portion adjacent to the read bit line RBL and the source line SL between the read bit line RBL and the source line SL, and a second portion extending in the first horizontal direction between the write transistor WTR and the read transistor RTR. The first portion of the first electrode of the capacitor CAP may have a semicircular shape in plan view, and the second portion thereof may have a bar shape extending in the first horizontal direction. The first portion and the second portion of the first electrode of the capacitor CAP may be integrally formed. The first electrode of the capacitor CAP included in one memory cell MC may be spaced apart from the first electrode of the capacitor CAP included in another memory cell MC. The memory cells MC arranged in the first horizontal direction may share one read word line RWL via the second electrode of the capacitors CAP included in the memory cells MC.

In some embodiments, the capacitor dielectric layer of the capacitor CAP may include an insulating material having hysteresis characteristics. The capacitor CAP may include a ferroelectric capacitor in which a capacitor dielectric layer includes a ferroelectric material. For example, the semiconductor memory device 1 may include a 3D two-transistor metal-ferroelectric field-effect transistor (2T-MFeFET) or a 3D two-transistor metal-ferroelectric-metal field-effect transistor (2T-MFMFET).

FIGS. 2A and 2B are a perspective view of the memory cell MC of a semiconductor memory device and a plan view of an equivalent circuit diagram thereof, according to embodiments, respectively.

Referring to FIGS. 2A and 2B, the memory cell MC may include the write transistor WTR, the read transistor RTR, and the capacitor CAP. In some embodiments, the memory cell MC may include a 2T-MFeFET or a 2T-MFMFET in which the capacitor CAP includes a ferroelectric capacitor.

The capacitor CAP may include a first electrode EL1, a second electrode EL2, and a capacitor dielectric layer CDI arranged between the first electrode EL1 and the second electrode EL2. The first electrode EL1 of the capacitor CAP may include a first portion PT1 adjacent to the read bit line RBL and the source line SL, between the read bit line RBL and the source line SL, and a second portion PT2 extending in the first horizontal direction between the write transistor WTR and the read transistor RTR. The first portion PT1 of the first electrode EL1 of the capacitor CAP may have a semicircular shape in plan view (see FIG. 2B), and the second portion PT2 thereof may have a bar shape extending in the first horizontal direction in plan view. The first portion PT1 and the second portion PT2 of the first electrode EL1 of the capacitor CAP may be integrally formed. The second electrode EL2 of the capacitor CAP may have a bar shape extending in the first horizontal direction. An extension length of the second electrode EL2 of the capacitor CAP in the first horizontal direction may be greater than an extension length of the second portion PT2 of the first electrode EL1 of the capacitor CAP. In other words, as shown in FIG. 2B, the second electrode EL2 may extend in the first horizontal direction (e.g., the X direction) beyond the second portion PT2, such that lateral sides of the second electrode EL2 and lateral sides of the second portion PT2 are not coplanar. The second electrode EL2 of the capacitor CAP may be referred to as the read word line RWL. The first electrode EL1 of the capacitor CAP may be referred to as a capacitor electrode. In some embodiments, an extension length of the capacitor dielectric layer CDI of the capacitor CAP in the first horizontal direction may be generally the same as an extension length of the second portion PT2 of the first electrode EL1 of the capacitor CAP. In some embodiments, lateral sides of the capacitor dielectric layer CDI may be coplanar with lateral sides of the second portion PT2.

Each of the first electrode EL1 and the second electrode EL2 may include doped silicon, a metal, conductive metal nitride, conductive metal silicide, conductive metal oxide, or a combination thereof. The capacitor dielectric layer CDI may include at least one of a high-k dielectric material and a ferroelectric material having a dielectric constant higher than a dielectric constant of silicon oxide. In some embodiments, the capacitor CAP may include a ferroelectric capacitor including a ferroelectric material which is an insulating material in which the capacitor dielectric layer CDI of the capacitor CAP has hysteresis characteristics.

The read transistor RTR may include a first channel layer CH1 and a first gate dielectric layer Gox1. A first side (e.g., the right side in the example illustrated in FIG. 2B) and a second side (e.g., the left side in the example illustrated in FIG. 2B) of the first channel layer CH1 may include the source and the drain of the read transistor RTR, respectively. The first side of the first channel layer CH1 may be interconnected to the source line SL, and the second side of the first channel layer CH1 may be interconnected to the read bit line RBL, as illustrated in the example of FIG. 2B. The first gate dielectric layer Gox1 and the first channel layer CH1 may have a semicircular shape or a half-ring shape in plan view. The first gate dielectric layer Gox1 may cover a side surface of the first electrode EL1 of the capacitor CAP, and the first channel layer CH1 may cover the first gate dielectric layer Gox1. The first channel layers CH1 may include the first gate dielectric layer Gox1 therebetween, and may be spaced apart from the first electrode EL1 of the capacitor CAP. The first electrode EL1 of the capacitor CAP may include a gate electrode of the read transistor RTR. For example, the read transistor RTR may include the first channel layer CH1, the first gate dielectric layer Gox1, the source line SL, the read bit line RBL, and the first portion PT1 of the first electrode EL1 of the capacitor CAP.

A source/drain contact layer SDC may be arranged in each of between the first channel layer CH1 and the source line SL, and the first channel layer CH1 and the read bit line RBL. The source/drain contact layer SDC may include a drain contact layer SDC1 arranged between the first channel layer CH1 and the read bit line RBL, and a source contact layer SDC2 arranged between the first channel layer CH1 and the source line SL. In plan view, the drain contact layer SDC1 may surround at least a portion of the read bit line RBL, and the source contact layer SDC2 may surround at least a portion of the source line SL. In some embodiments, in plan view, the drain contact layer SDC1 may completely surround the read bit line RBL, and the source contact layer SDC2 may completely surround the source line SL. For example, when each of the source line SL and the read bit line RBL has a circular shape in plan view, the source/drain contact layer SDC may have a ring shape in plan view.

An insulating spacer ISP may be arranged between the first channel layer CH1 and the first electrode EL1 of the capacitor CAP. For example, the insulating spacer ISP may be arranged between the second portion PT2 of the first electrode EL1 of the capacitor CAP and the first channel layer CH1. In some embodiments, the insulating spacer ISP may be arranged between the second portion PT2 of the first electrode EL1 of the capacitor CAP and the first channel layer CH1, and between the second portion PT2 of the first electrode EL1 of the capacitor CAP and the first gate dielectric layer Gox1. The insulating spacer ISP may insulate the first channel layer CH1 from the first electrode EL1 of the capacitor CAP. For example, the insulating spacer ISP may include silicon oxide.

The first electrode EL1 may be arranged between the first gate dielectric layer Gox1 of the read transistor RTR and the capacitor dielectric layer CDI of the capacitor CAP. In other words, the first electrode EL1 may be shared by the read transistor RTR and the capacitor CAP. The semiconductor memory device 1 may read data stored in the memory cell MC by sensing a ratio of the capacitance of the capacitor CAP and the capacitance of the read transistor RTR. Accordingly, because the semiconductor memory device 1 according to the embodiments illustrated in FIGS. 1-2B may read data stored in the memory cell MC without the capacitor CAP having a large capacitance, the capacitor CAP may be implemented in a small size, and the power consumption of the capacitor CAP may be reduced.

The write transistor WTR may include a second channel layer CH2 and a second gate dielectric layer Gox2. A first side and a second side of the second channel layer CH2 may include the source and the drain of the write transistor WTR, respectively. The first side (e.g., the bottom in the example illustrated in FIG. 2B) of the second channel layer CH2 may be interconnected to the second portion PT2 of the first electrode EL1 of the capacitor CAP, and the second side (e.g., the top in the example illustrated in FIG. 2B) of the second channel layer CH2 may be interconnected to the write bit line WBL. The second gate dielectric layer Gox2 may cover a portion of a side surface of the write word line WWL, and the second channel layer CH2 may cover the second gate dielectric layer Gox2. The second channel layers CH2 may include the second gate dielectric layer Gox2 therebetween and may be spaced apart from the write word line WWL. The write word line WWL may include a gate electrode of the write transistor WTR. For example, the write transistor WTR may include the second channel layer CH2, the second gate dielectric layer Gox2, the second portion PT2 of the first electrode EL1 of the capacitor CAP, the write bit line WBL, and the write word line WWL.

In plan view, the second gate dielectric layer Gox2 and the second channel layer CH2 may surround at least a portion of the write word line WWL. In some embodiments, in plan view, the second gate dielectric layer Gox2 and the second channel layer CH2 may completely surround the write word line WWL. For example, the second gate dielectric layer Gox2 and the second channel layer CH2 may have a ring shape in plan view.

The second electrode EL2 of the capacitor CAP, that is, the read word line RWL, may extend in the first horizontal direction. The write bit line WBL may extend in the first horizontal direction. The read word line RWL and the write bit line WBL may be spaced apart from each other in the second horizontal direction. Other components of the memory cell MC may be positioned between the read word line RWL and the write bit line WBL. For example, between the read word line RWL and the write bit line WBL, the capacitor dielectric layer CDI, the first electrode EL1, the insulating spacer ISP, the first gate dielectric layer Gox1, the first channel layer CH1, the read bit line RBL, the source line SL, the source/drain contact layer SDC including the drain contact layer SDC1 and the source contact layer SDC2, the second channel layer CH2, the second gate dielectric layer Gox2, and the write word line WL may be positioned.

Between the read word line RWL and the write bit line WBL, the write word line WWL, the read bit line RBL, and the source line SL may be arranged apart from each other in the first horizontal direction. In plan view, when each of the write word line WWL, the read bit line RBL, and the source line SL has a circular shape, the diameter of the write word line WWL may be greater than the diameter of the read bit line RBL and the diameter of the source line SL. In some embodiments, the diameter of the read bit line RBL and the diameter of the source line SL may have substantially the same value. In plan view, the first portion PT1 of the first electrode EL1 of the capacitor CAP may be positioned between the read bit line RBL, the source line SL, and the second electrode EL2.

Referring to FIGS. 1, 2A, and 2B together, in the semiconductor memory device 1 according to various embodiments, the write word line WWL, the read bit line RBL, and the source line SL may extend in the vertical direction (e.g., the Z direction), share memory cells MC arranged in the vertical direction, and because the write bit line WBL and the read word line RWL extend in the first horizontal direction (e.g., the X direction) and share the memory cells MC arranged in the first horizontal direction, a plurality of memory cells MC may constitute the memory cell array MCA arranged in three-dimensions. The semiconductor memory device 1 according to various embodiments may sense the capacitance ratio of the capacitor CAP to the read transistor RTR, and thus, the capacitor CAP of a small size may be implemented and the power consumption thereof may be reduced.

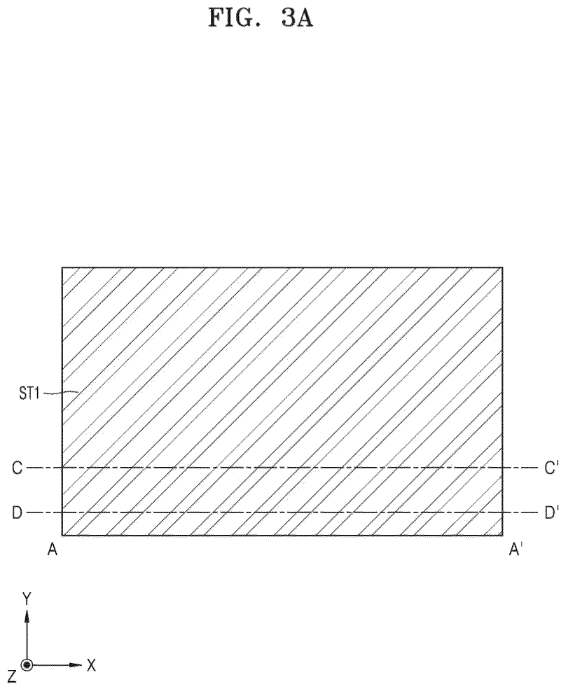

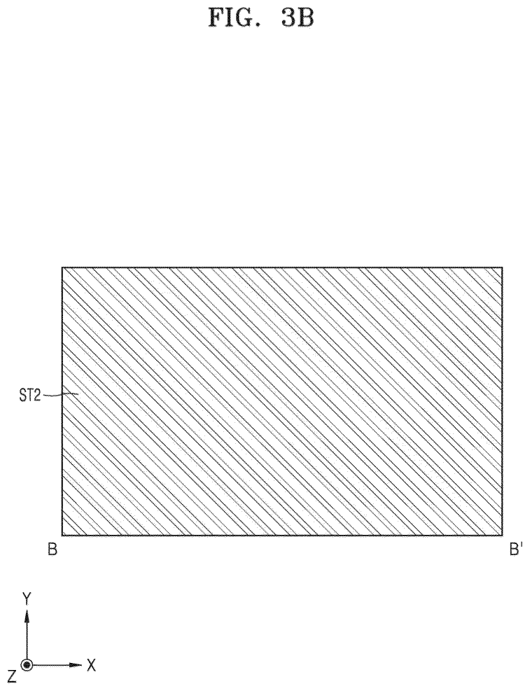

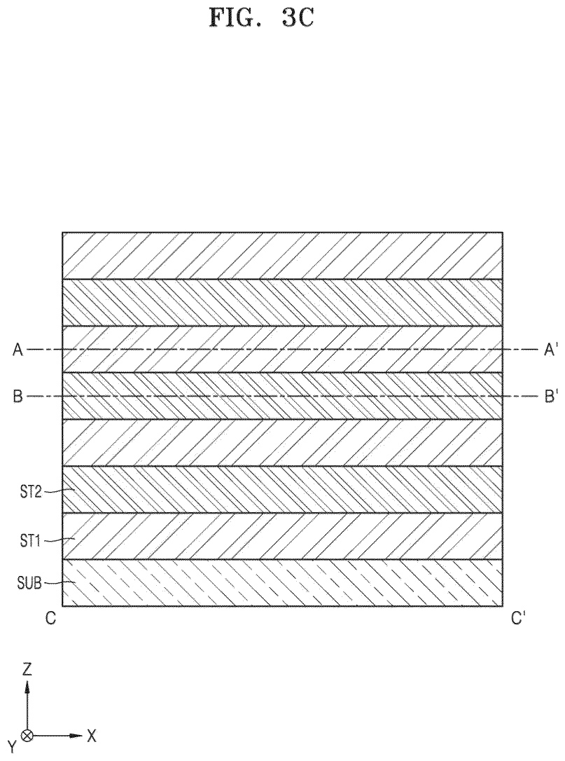

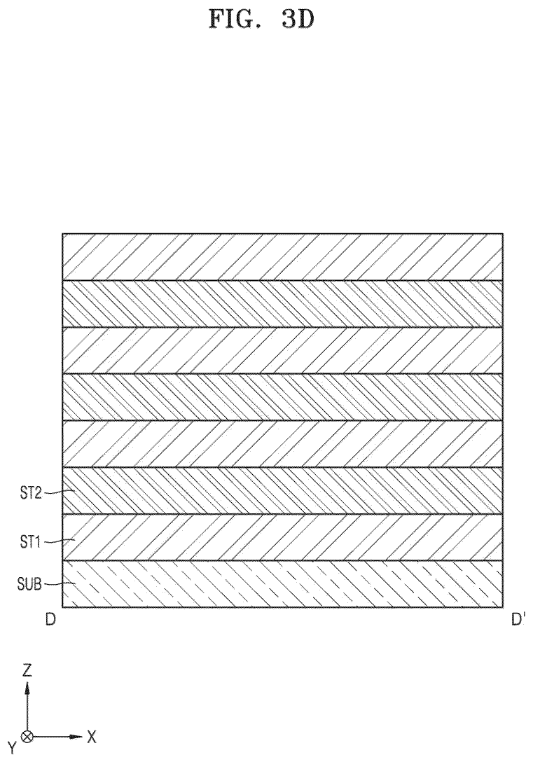

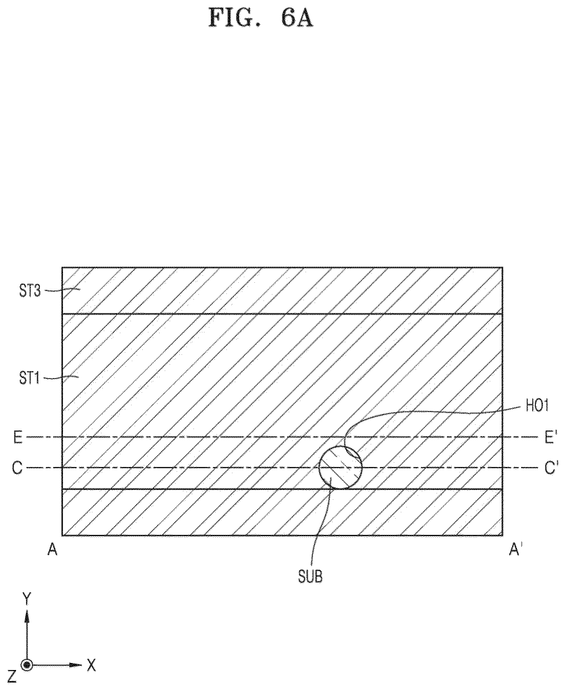

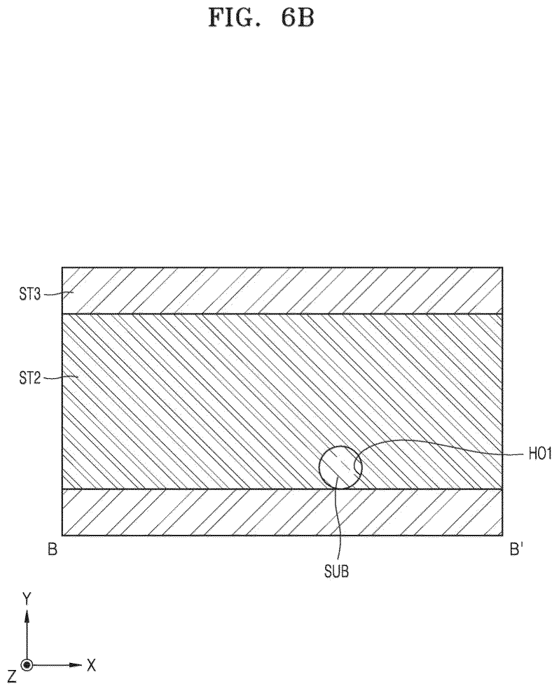

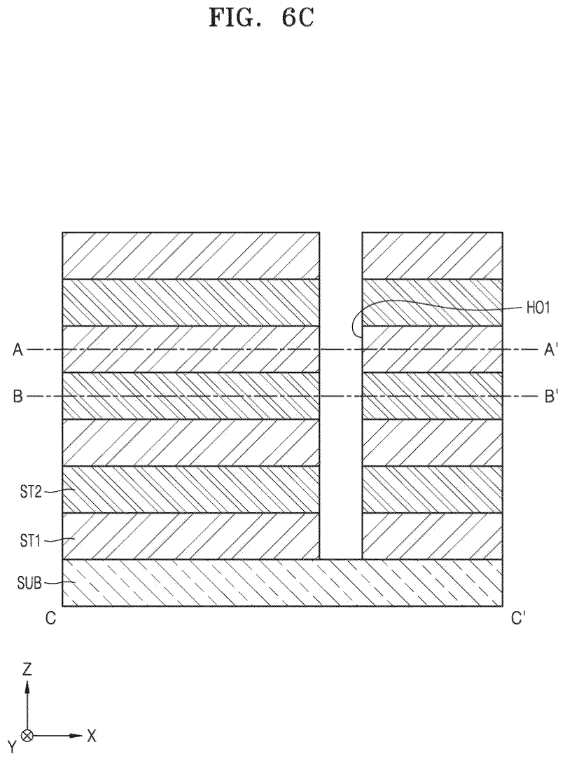

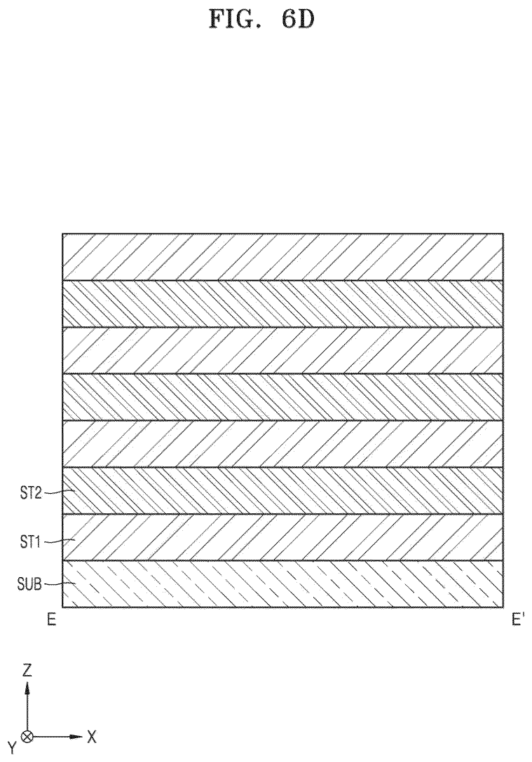

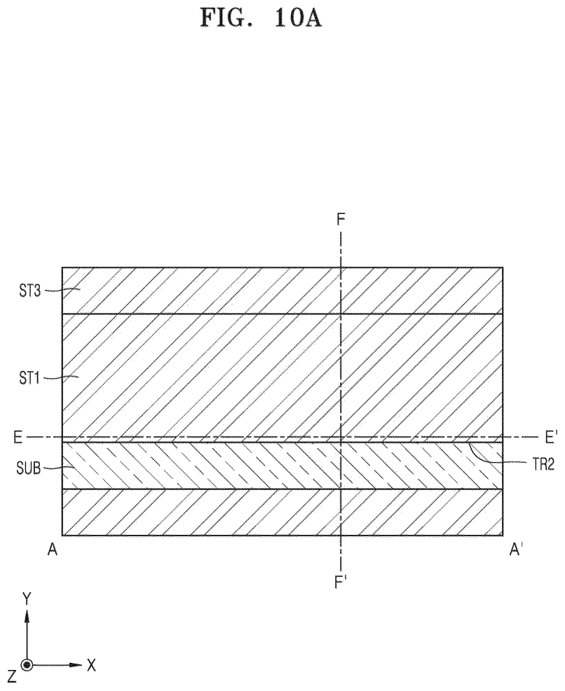

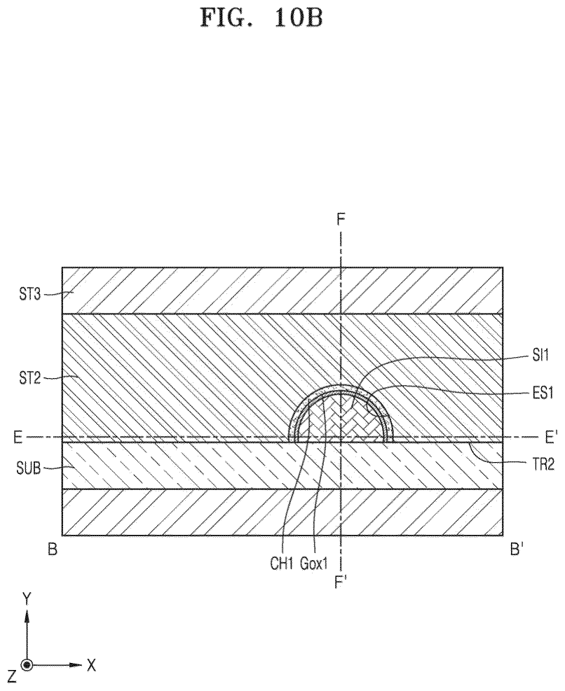

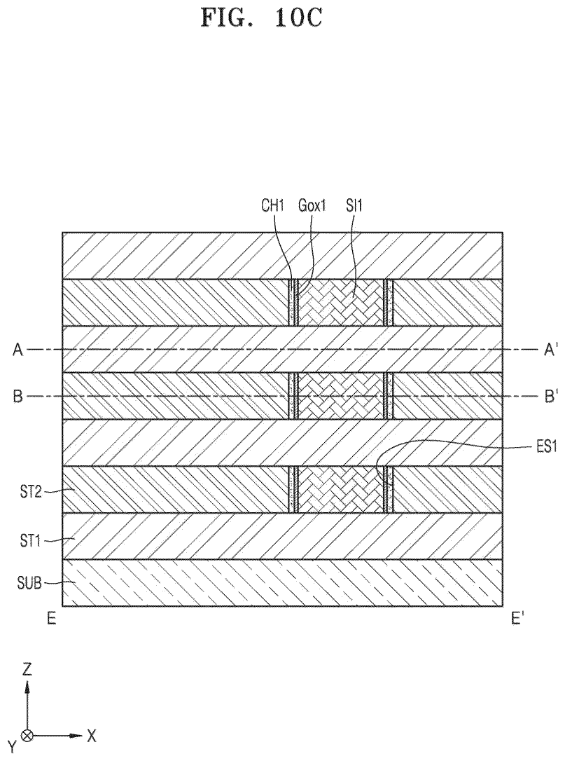

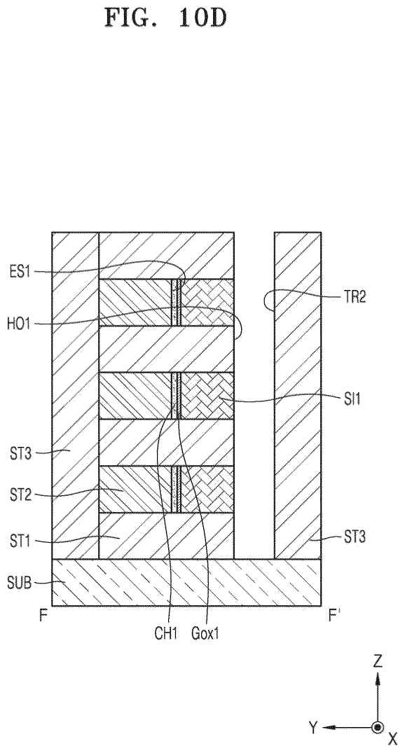

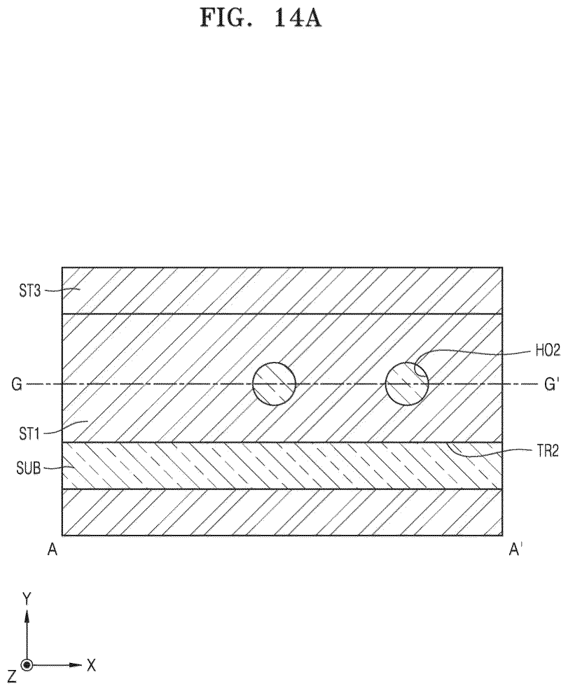

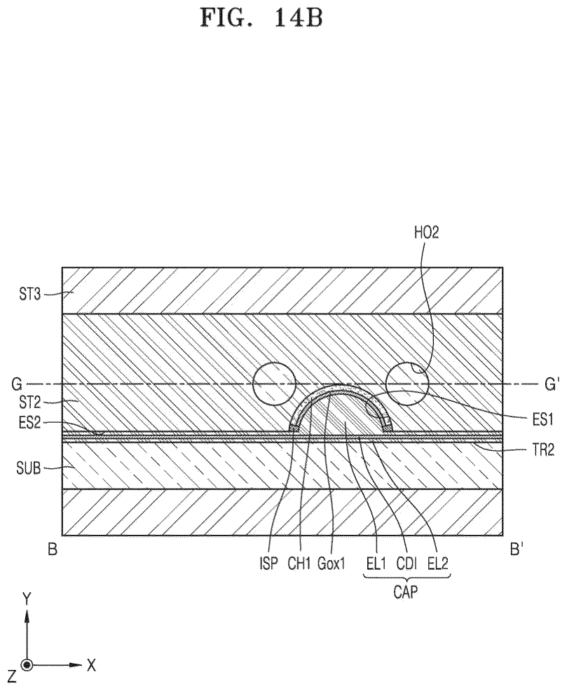

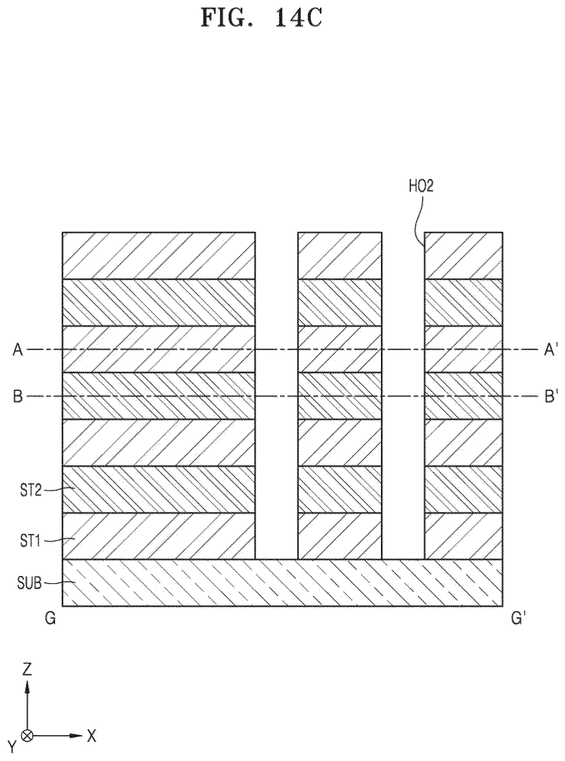

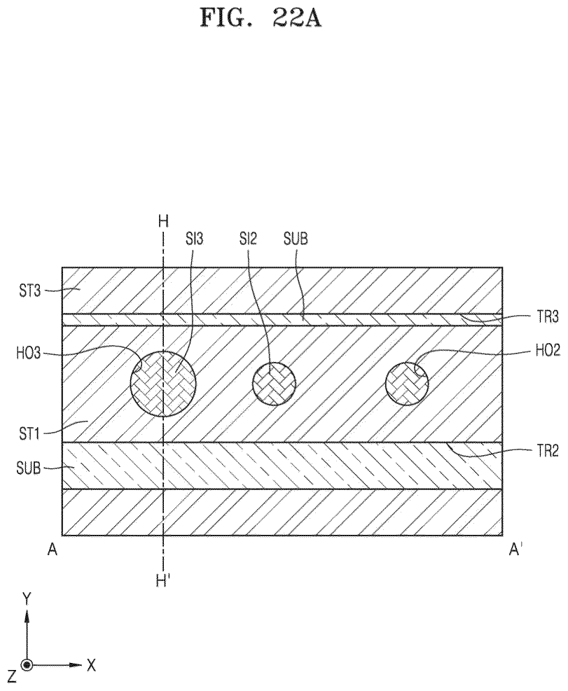

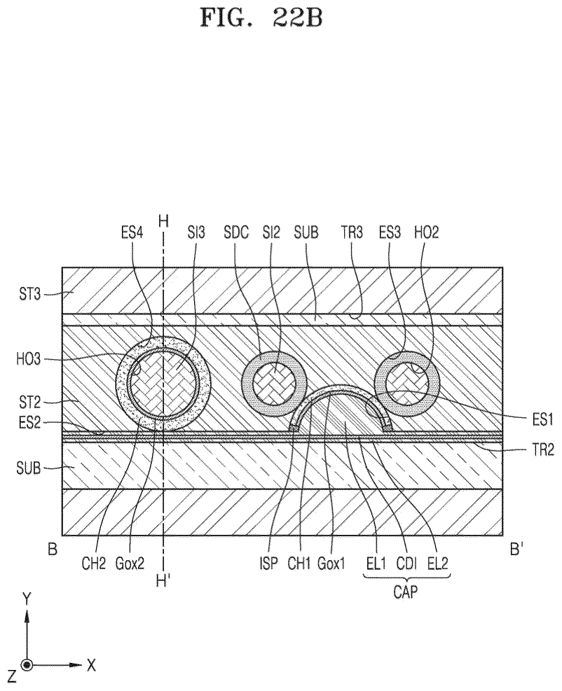

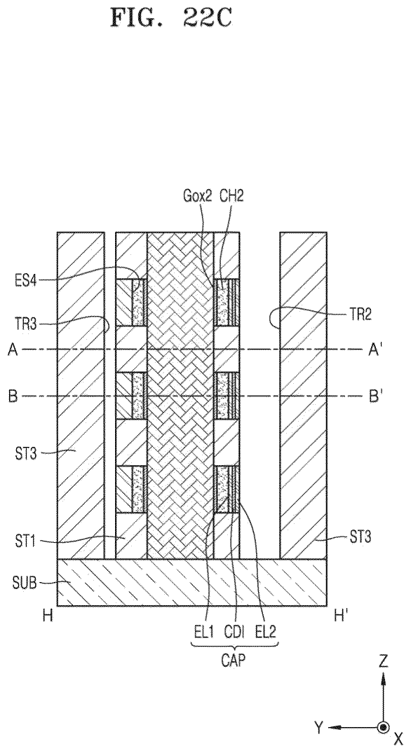

FIGS. 3A through 3D, 4A through 4D, 5A through 5D, 6A through 6D, 7A through 7D, 8A through 8D, 9A through 9D, 10A through 10D, 11A through 11D, 12A through 12D, 13A through 13D, 14A through 14C, 15A through 15C, 16A through 16C, 17A through 17C, 18A through 18C, 19A through 19C, 20A through 20C, 21A through 21C, 22A through 22C, 23A through 23D, 24A through 24D, 25A through 25D, and 26A through 26D are plan views and cross-sectional views of a manufacturing method of a semiconductor memory device according to a process sequence, according to embodiments, and FIGS. 27A through 27D are diagrams of a semiconductor memory device, according to embodiments. FIGS. 3A, 4A, 5A, 6A, 7A, 8A, 9A, 10A, 11A, 12A, 13A, 14A, 15A, 16A, 17A, 18A, 19A, 20A, 21A, 22A, 23A, 24A, 25A, 26A, and 27A may be plan views taken from the upper side along lines A-A′ in FIGS. 3C, 4C, 5C, 6C, 7C, 8C, 9C, 10C, 11C, 12C, 13C, 14C, 15C, 16C, 17C, 18C, 19C, 20C, 21C, 22C, 23C, 24C, 25C, 26C, and 27C, respectively. FIGS. 3B, 4B, 5B, 6B, 7B, 8B, 9B, 10B, 11B, 12B, 13B, 14B, 15B, 16B, 17B, 18B, 19B, 20B, 21B, 22B, 23B, 24B, 25B, 26B, and 27B may be plan views taken from the upper side along lines B-B′ in FIGS. 3C, 4C, 5C, 6C, 7C, 8C, 9C, 10C, 11C, 12C, 13C, 14C, 15C, 16C, 17C, 18C, 19C, 20C, 21C, 22C, 23C, 24C, 25C, 26C, and 27C, respectively. FIGS. 3C, 4C, 5C, 6C, 7C, 8C, and 9C may be cross-sectional views taken along lines C-C′ in 3A, 4A, 5A, 6A, 7A, 8A, and 9A, respectively, FIGS. 3D, 4D, and 5D may be cross-sectional views taken along lines D-D′ in FIGS. 3A, 4A, and 5A, respectively. FIGS. 6D, 7D, 8D, 9D, 10C, 11C, 12C, and 13C may be cross-sectional views taken along lines E-E′ in FIG. FIGS. 6A, 7A, 8A, 9A, 10A, 11A, 12A, and 13A, respectively. FIGS. 10D, 11D, 12D, and 13D may be cross-sectional views taken along lines F-F′ in FIGS. 10A, 11A, 12A, and 13A, respectively. FIGS. 14C, 15C, 16C, 17C, 18C, 19C, 20C, 21C, 23C, 24C, 25D, 26D, and 27D may be cross-sectional views taken along lines G-G′ in FIGS. 14A, 15A, 16A, 17A, 18A, 19A, 20A, 21A, 23A, 24A, 25A, 26A, and 27A, respectively. FIGS. 22C, 23D, 24D, 25D, 26D, and 27D may be cross-sectional views taken along lines H-H′ in FIGS. 22A, 23A, 24A, 25A, 26A, and 27A, respectively.

Referring to FIGS. 3A through 3D together, a plurality of first sacrificial layers ST1 and a plurality of second sacrificial layers ST2 may be formed on a substrate SUB. The plurality of first sacrificial layers ST1 and the plurality of second sacrificial layers ST2 may be alternately stacked on the substrate SUB. The plurality of first sacrificial layers ST1 may be arranged apart from each other on the substrate SUB in the vertical direction (e.g., the Z direction), and the plurality of second sacrificial layers ST2 may be arranged apart from each other on the substrate SUB in the vertical direction. In some embodiments, the number of first sacrificial layers ST1 stacked on the substrate SUB may be one more than the number of second sacrificial layers ST2 stacked on the substrate SUB. For example, the second sacrificial layer ST2 may be between two first sacrificial layers ST1 adjacent to each other in the vertical direction. In FIGS. 3A through 3D, four first sacrificial layers ST1 and three second sacrificial layers ST2 are illustrated to be stacked on the substrate SUB, but embodiments are not limited thereto. For example, on the substrate SUB, five or more, or tens to hundreds of first sacrificial layers ST1, and four or more, or tens to hundreds of second sacrificial layers ST2 may be stacked.

The substrate SUB may include, for example, silicon (Si), for example, crystalline Si, polycrystalline Si, or amorphous Si. In some embodiments, the substrate SUB may include at least one compound semiconductor of a semiconductor element such as germanium (Ge), silicon germanium (SiGe), silicon carbide (SiC), gallium arsenide (GaAs), indium arsenide (InAs), and/or indium phosphide (InP). In some embodiments, the substrate SUB may include a silicon-on-insulator (SOI) substrate or a germanium-on-insulator (GEOI) substrate. For example, the substrate SUB may include a buried oxide (BOX) layer. The substrate SUB may include a conductive region, for example, a well doped with impurities, or a structure doped with impurities. The substrate SUB may include a wiring for electrical connection between components formed on the substrate SUB and an insulating layer surrounding the wiring.

The first sacrificial layer ST1 and the second sacrificial layer ST2 may include a material having etch selectivity with respect to the substrate SUB. The first sacrificial layer ST1 and the second sacrificial layer ST2 may include a material having etch selectivity with respect to each other. In some embodiments, each of the first sacrificial layer ST1 and the second sacrificial layer ST2 may include a semiconductor material. For example, one of the first sacrificial layer ST1 and the second sacrificial layer ST2 may include Si, and the other may include SiGe. In some embodiments, for example, the first sacrificial layer ST1 and the second sacrificial layer ST2 may include SiGe having different Ge concentrations.

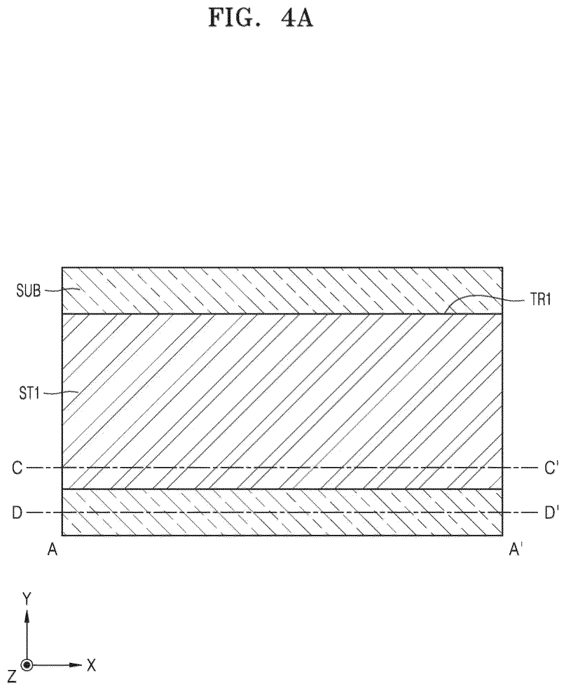

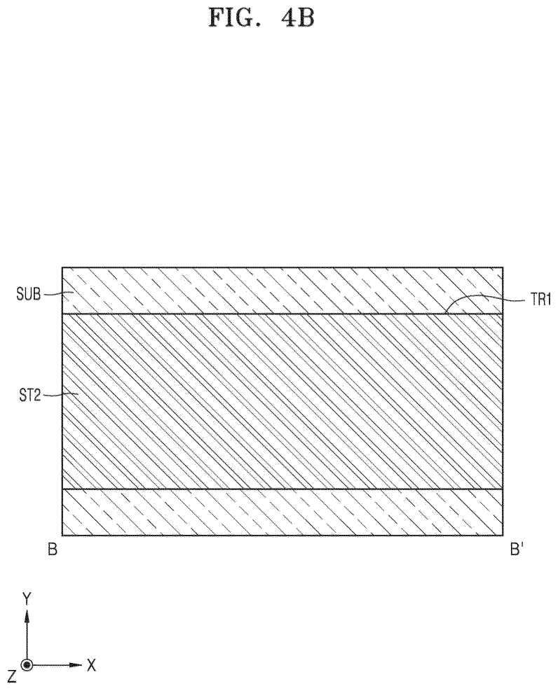

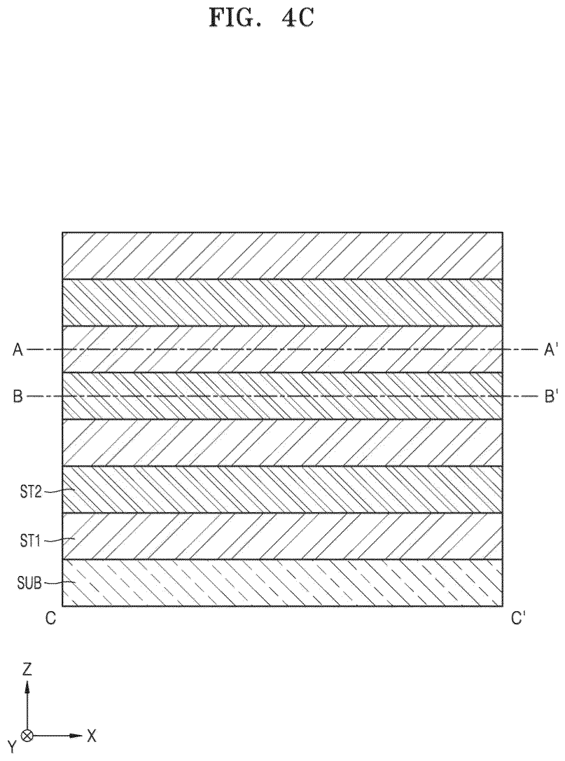

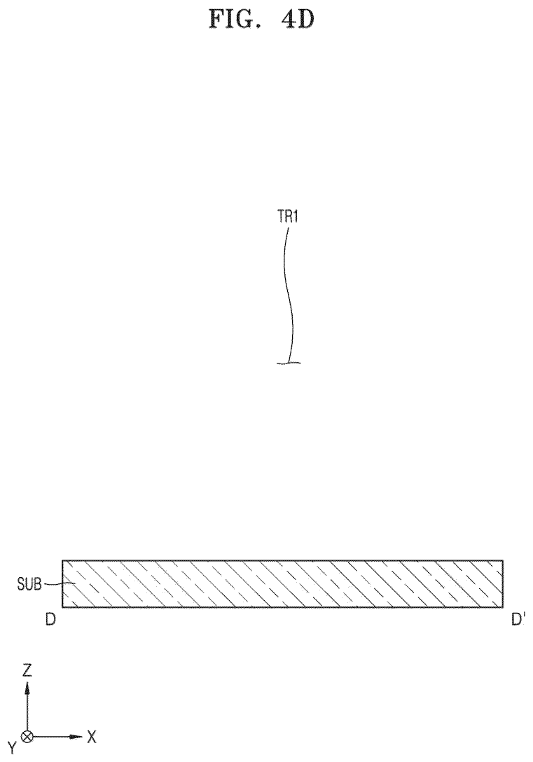

Referring to FIGS. 4A through 4D, by removing a portion of a stacked structure of the plurality of first sacrificial layers ST1 and the plurality of second sacrificial layers ST2, a plurality of first trenches TR1 penetrating the stacked structure of the plurality of first sacrificial layers ST1 and the plurality of second sacrificial layers ST2 may be formed. In plan view, the plurality of first trenches TR1 may extend in the first horizontal direction (e.g., the X direction), and may be spaced apart from each other in the second horizontal direction (e.g., the Y direction). Each of the plurality of first trenches TR1 may have a generally uniform horizontal width in the second horizontal direction and may extend in the first horizontal direction.

In FIGS. 4A through 4D, two first trenches TR1 are illustrated to be formed at both ends in the second horizontal direction, but this configuration is an example only and first trenches TR1 arranged apart from each other in the second horizontal direction may be further formed. The memory cell MC illustrated in FIGS. 2A and 2B may be formed between two first trenches TR1 adjacent to each other in the second horizontal direction. A portion of the substrate SUB may be exposed on a bottom surface of each of the plurality of first trenches TR1.

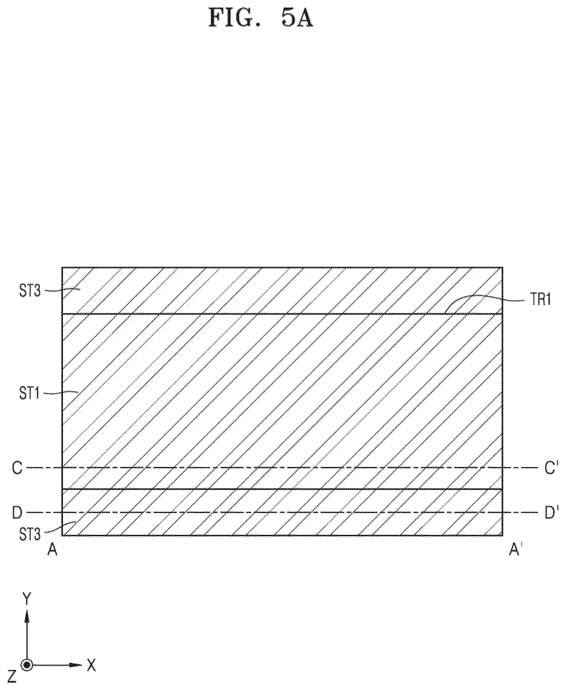

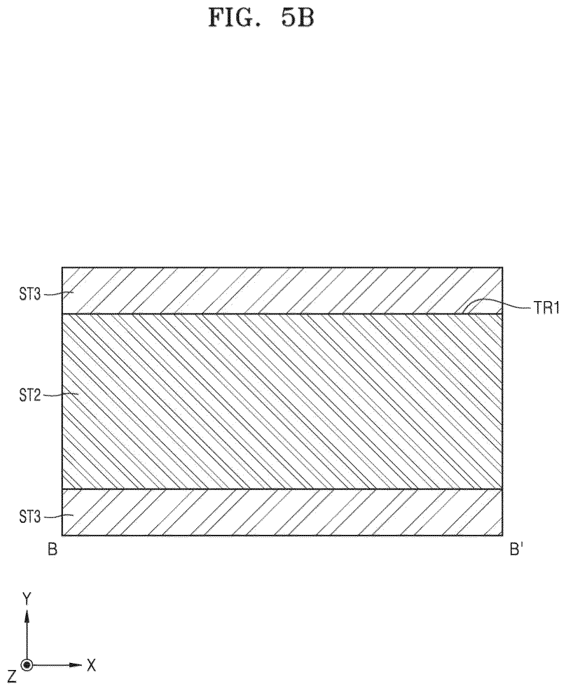

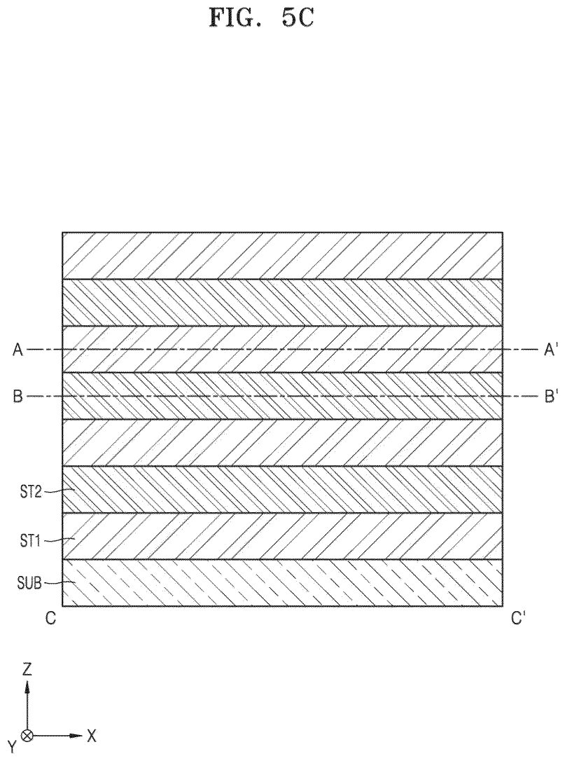

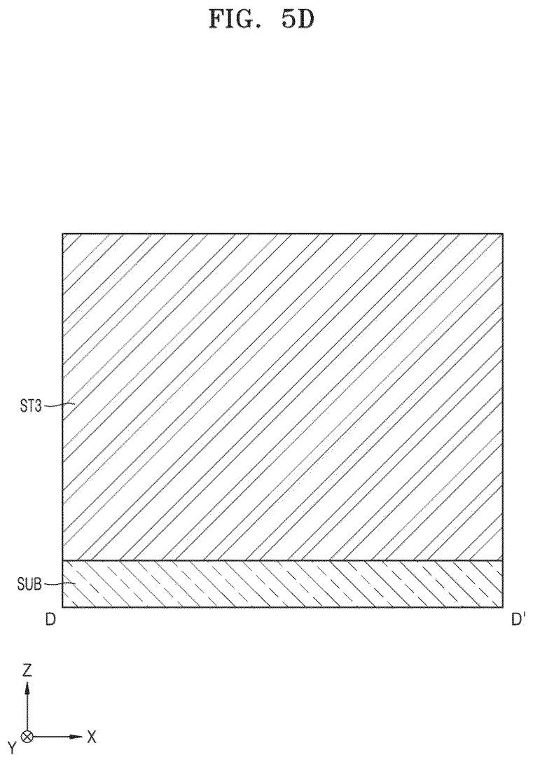

Referring to FIGS. 5A through 5D together, a plurality of third sacrificial layers ST3 respectively filling the plurality of first trenches TR1 may be formed. The third sacrificial layer ST3 may include a material having etch selectivity with respect to each of the substrate SUB and the second sacrificial layer ST2. In some embodiments, the third sacrificial layer ST3 may include a material having the same or similar etching characteristics as or to etching characteristics of the first sacrificial layer ST1. For example, the third sacrificial layer ST3 may include the same material as the first sacrificial layer ST1.

The third sacrificial layer ST3 may be formed to have an upper surface at the same vertical level as an upper surface of an uppermost first sacrificial layer ST1 among the plurality of first sacrificial layers ST1. For example, after a sacrificial material layer filling the plurality of first trenches TR1 and covering the stacked structure of the plurality of first sacrificial layers ST1 and the plurality of second sacrificial layers ST2 is formed, by removing a portion of an upper side of the sacrificial material layer until the upper surface of the uppermost first sacrificial layer ST1 is exposed among the plurality of first sacrificial layers ST1, the third sacrificial layer ST3 may be formed.

Referring to FIGS. 6A through 6D, by removing a portion of the stacked structure of the plurality of first sacrificial layers ST1 and the plurality of second sacrificial layers ST2, a first through hole HO1 penetrating the stacked structure of the plurality of first sacrificial layers ST1 and the plurality of second sacrificial layers ST2 may be formed. A portion of the substrate SUB may be exposed on a bottom surface of the first through hole HO1. In some embodiments, the first through hole HO1 may be formed such that a horizontal cross-section thereof has a circular shape.

The first through hole HO1 may be formed adjacent to the third sacrificial layer ST3. For example, the first through hole HO1 may be formed to be adjacent to one of the two third sacrificial layers ST3 between two third sacrificial layers ST3 adjacent to each other in the second horizontal direction. A portion of the third sacrificial layer ST3 may be exposed on an inner side surface of the first through hole HO1, but embodiments are not limited thereto. For example, when the first through hole HO1 is formed to be in contact with one third sacrificial layer ST3, a portion of the third sacrificial layer ST3 may be exposed on the inner side surface of the first through hole HO1. For example, when the first through hole HO1 is formed to be adjacent to but not in contact with one third sacrificial layer ST3, a portion of the third sacrificial layer ST3 may not be exposed on the inner side surface of the first through hole HO1.

In some embodiments, one third sacrificial layer ST3 and the other third sacrificial layer ST3 different from the one third sacrificial layer ST3 of two third sacrificial layers ST3 adjacent to each other in the second horizontal direction may be simply referred to as one third sacrificial layer ST3 and the other third sacrificial layer ST3. For convenience of description, the third sacrificial layer ST3 illustrated on a lower side of the two third sacrificial layers ST3 illustrated in FIG. 6A may be referred to as one third sacrificial layer ST3, and the third sacrificial layer ST3 illustrated on an upper side thereof may be referred to as the other third sacrificial layer ST3.

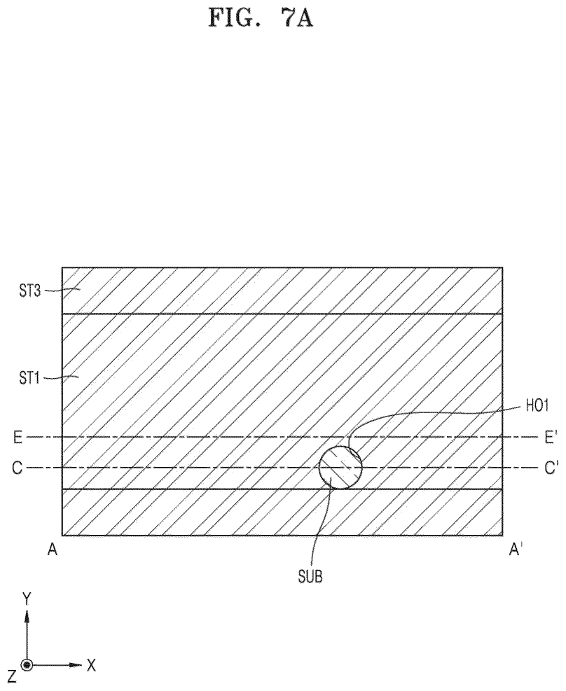

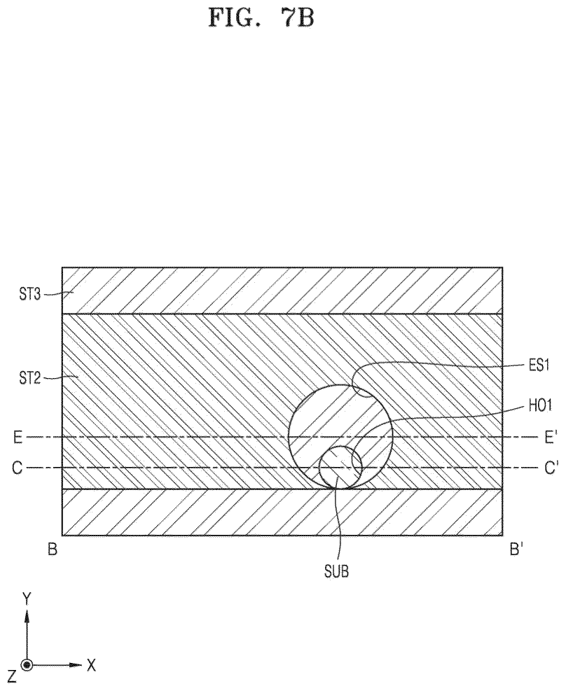

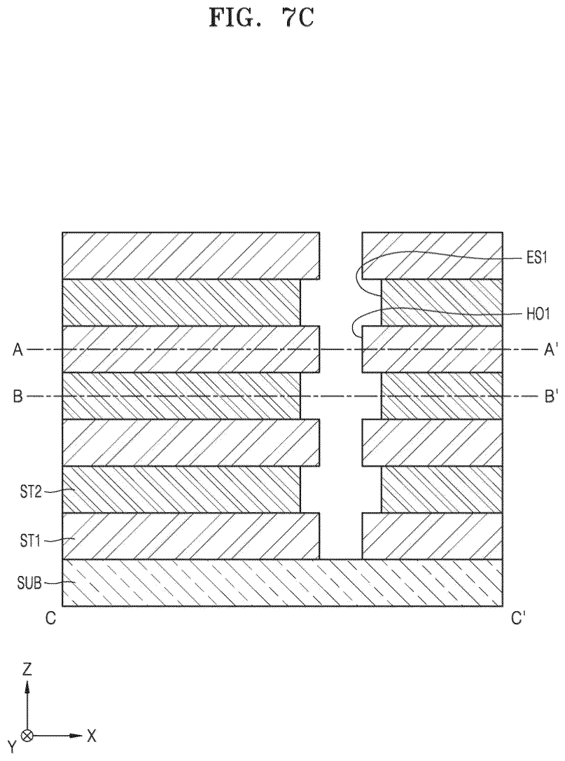

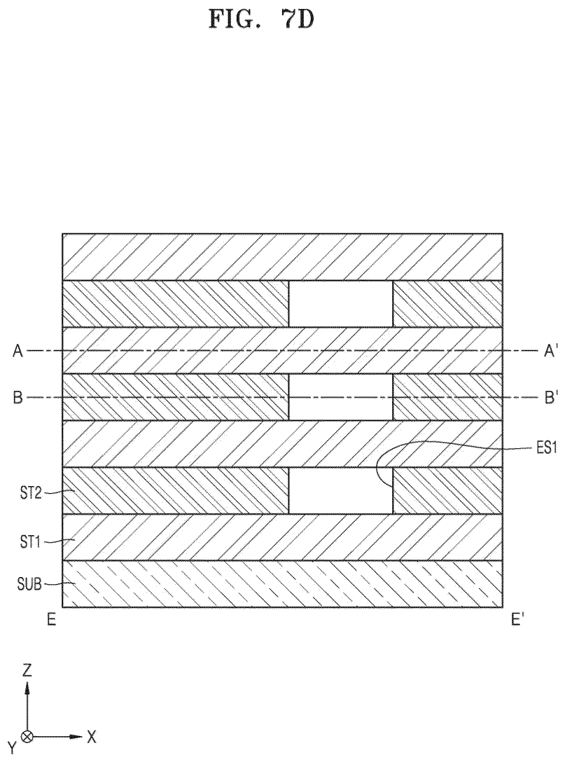

Referring to FIGS. 7A through 7D together, a plurality of first expansion spaces ES1 may be formed by removing portions of the plurality of second sacrificial layers ST2 through the first through hole HO1. A horizontal width of each of the plurality of first expansion spaces ES1 may have a value greater than a horizontal width of the first through hole HO1. The plurality of first expansion spaces ES1 may communicate with the first through hole HO1. Because the first through hole HO1 is arranged adjacent to one third sacrificial layer ST3, each of the plurality of first expansion spaces ES1 may be formed to extend from the first through hole HO1 farther from the one third sacrificial layer ST3. Although FIG. 7B illustrates that a horizontal cross-section of the first expansion space ES1 is formed to have a circular shape, this illustration is for convenience, and each of the plurality of first expansion spaces ES1 may be limited in space expansion due to one third sacrificial layer ST3 to be formed to have a circular shape in which a lower side of the horizontal cross-section thereof is downwardly crushed.

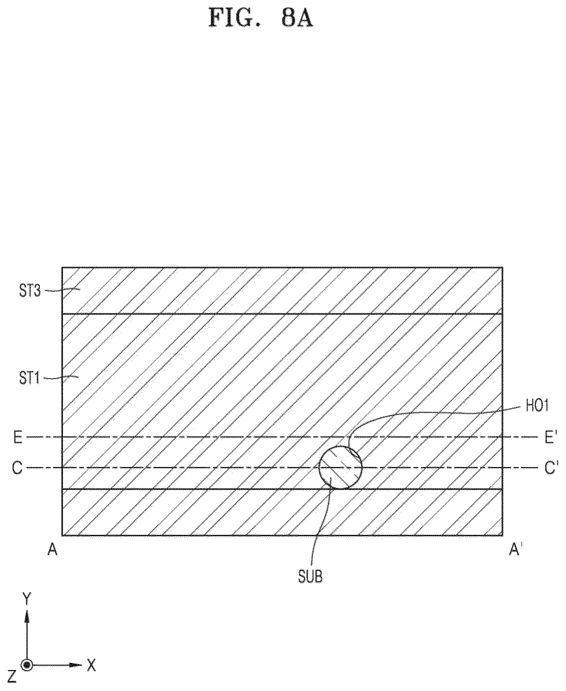

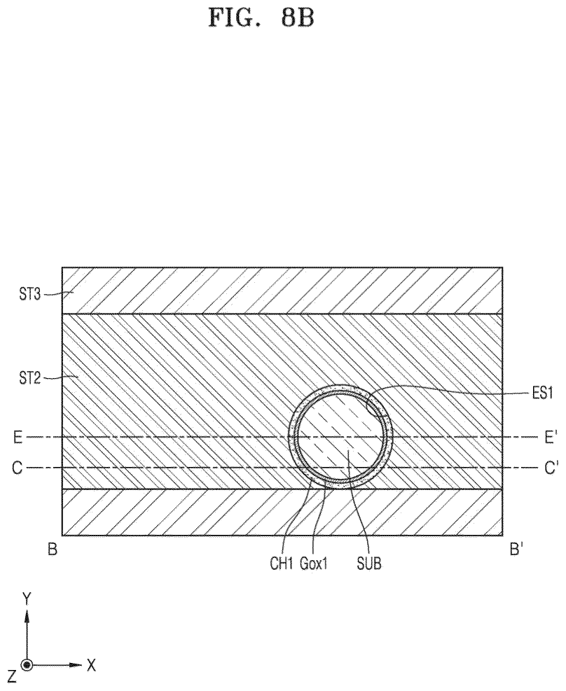

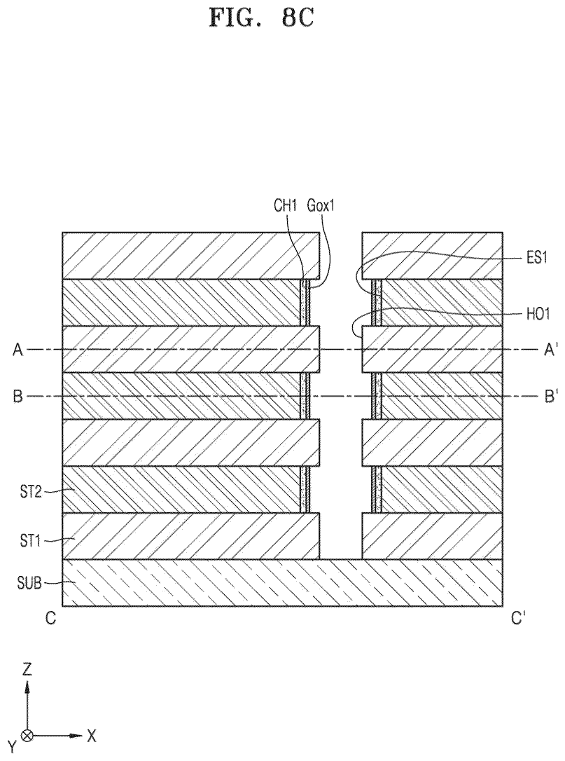

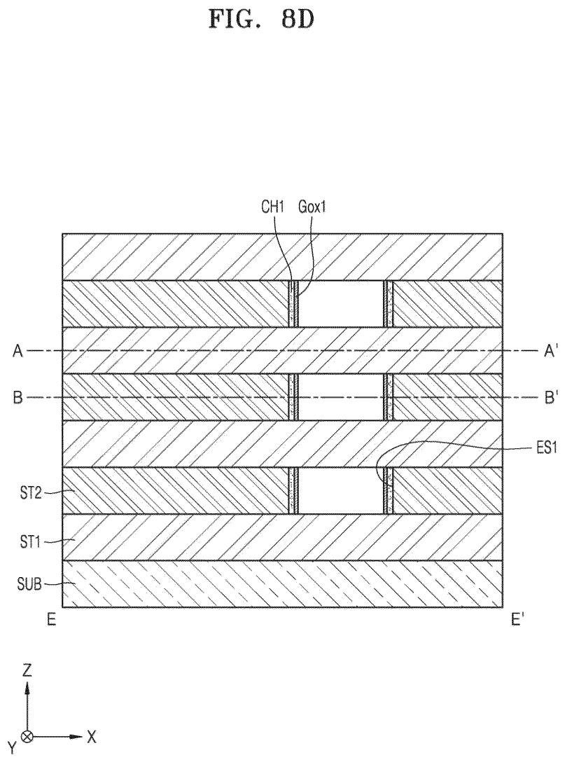

Referring to FIGS. 8A through 8D together, the first channel layer CH1 and the first gate dielectric layer Gox1 covering sidewalls of the plurality of second sacrificial layers ST2 exposed in each of the plurality of first expansion spaces ES1 may be sequentially formed.

The first channel layer CH1 may include a material having etch selectivity with respect to each of the first sacrificial layer ST1, the second sacrificial layer ST2, and the third sacrificial layer ST3. The first channel layer CH1 may include a semiconductor material, such as Si, Ge, or SiGe, a two-dimensional (2D) material semiconductor, or an oxide semiconductor material. For example, the 2D material semiconductor may include molybdenum oxide (MoS₂), tungsten diselenide (WSe₂), graphene, carbon nano tube, or a combination thereof. For example, the oxide semiconductor material may include InₓGa_{y}Zn₂O, InₓGa_{y}Si_{z}O, InₓSn_{y}Zn₂O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. For example, the first channel layer CH1 may include a single layer or multiple layers of the oxide semiconductor material. In some embodiments, the first channel layer CH1 may include a material having band gap energy greater than that of silicon. For example, the first channel layer CH1 may include a material having a band gap energy of about 1.5 eV to about 5.6 eV. For example, when the first channel layer CH1 has a band gap energy of about 2.0 eV to about 4.0 eV, the first channel layer CH1 may include a material having optimal channel performance.

The first gate dielectric layer Gox1 may include at least one of silicon oxide, a high-k dielectric material or a ferroelectric material having a dielectric constant greater than a dielectric constant of silicon oxide. In some embodiments, the first gate dielectric layer Gox1 may have a stacked structure of a first dielectric layer including silicon oxide and a second dielectric layer including at least one of a high-k dielectric material and a ferroelectric material. For example, a high-k dielectric material and a ferroelectric material may include at least one of hafnium oxide (HfO), hafnium silicate (HfSiO), hafnium oxynitride (HfON), hafnium silicon oxynitride (HfSiON), or lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium tantalum oxide bismuth (STB), bismuth ferrous oxide (BFO), strontium titanium oxide (SrTiO), yttrium oxide (YO), aluminum oxide (AlO), or lead scandium tantalum oxide (PbScTaO).

For example, after a first channel material layer and a first gate dielectric material layer conformally covering the inner surfaces of the first through hole HO1 and the plurality of first expansion spaces ES1 are sequentially formed, by removing portions covering the inner surface of the first through hole HO1 and portions covering the surface of the first sacrificial layer ST1 in the plurality of first expansion spaces ES1, in the first channel material layer and the first gate dielectric layer, the first channel layer CH1 and the first gate dielectric layer Gox1 covering the sidewalls of the plurality of second sacrificial layers ST2 exposed in each of the plurality of first expansion spaces ES1 may be formed. In some embodiments, after the first channel material layer and the first gate dielectric material layer conformally covering the inner surfaces of the first through hole HO1 and the first expansion space ES1 are formed, a mold layer filling the first through hole HO1 and the plurality of first expansion spaces ES1 may be formed. Thereafter, a portion of the mold layer filling the first through hole HO1, a portion of the first channel material layer covering the inner surface of the first through hole HO1, and a portion of the first gate dielectric material layer may be removed, and in a state where the remaining portion of the mold layer filling the plurality of first expansion spaces ES1 remain, by removing portions covering the surface of the first sacrificial layer ST1 in the first channel material layer and the first gate dielectric material layer and removing the remaining portion of the mold layer, the first channel layer CH1 and the first gate dielectric layer Gox1 covering sidewalls of the plurality of second sacrificial layers ST2 exposed in each of the plurality of first expansion spaces ES1 may be formed.

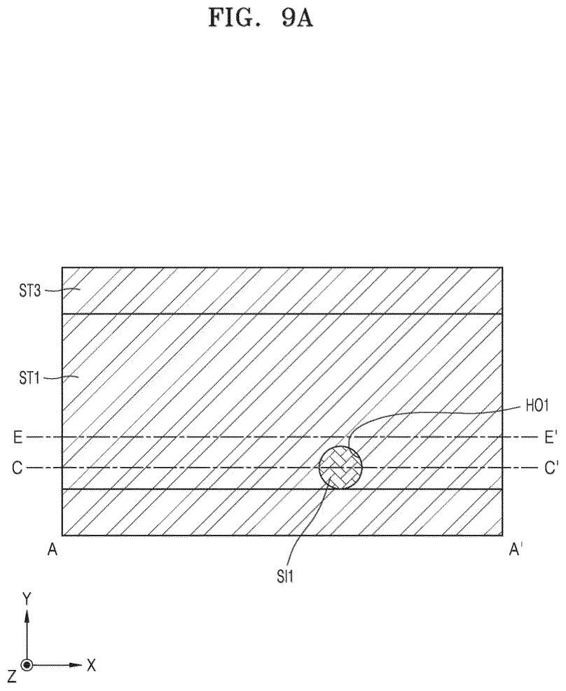

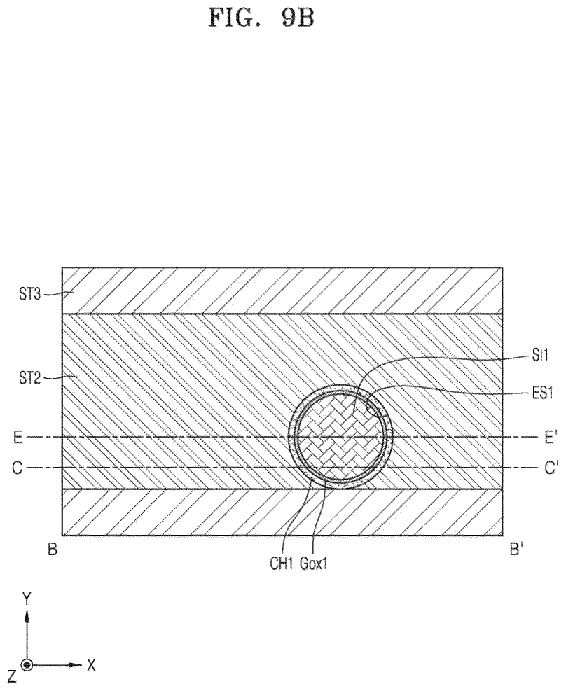

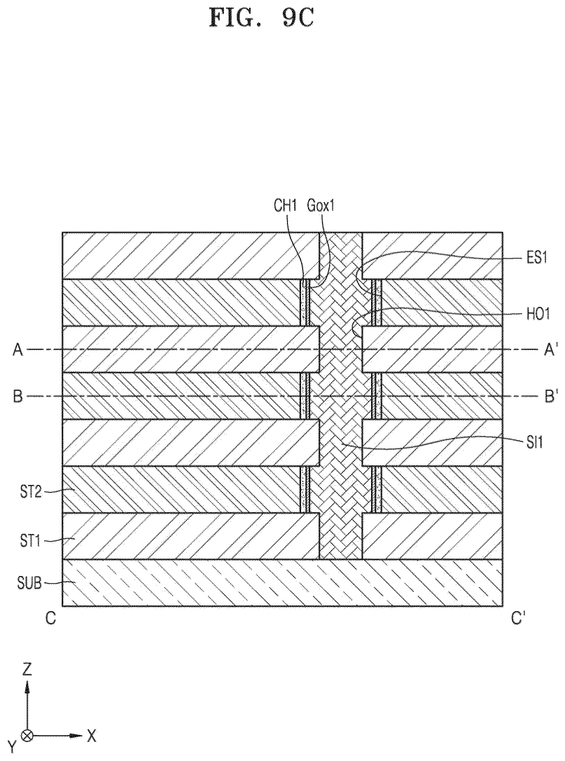

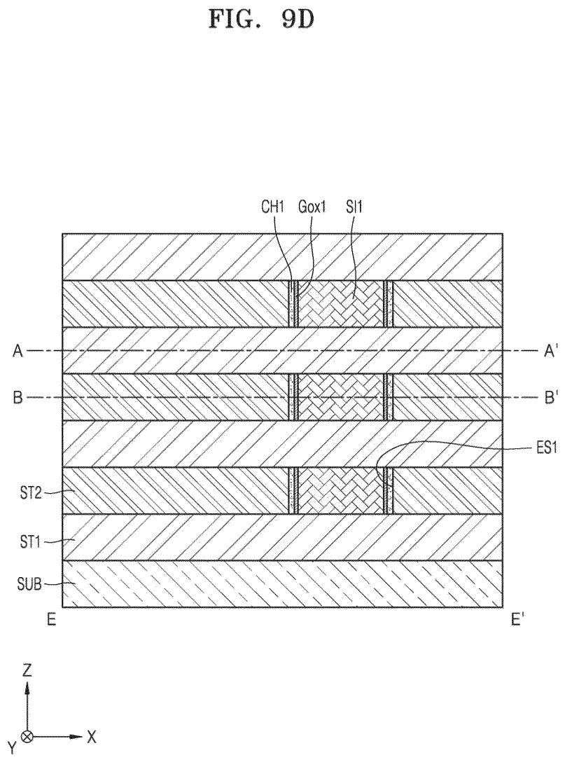

Referring to FIGS. 9A through 9D together, a first sacrificial insulating layer SI1 filling the first through hole HO1 and a plurality of first expansion spaces ES1 may be formed. The first sacrificial insulating layer SI1 may be formed to fill all of the first through hole HO1 and the plurality of first expansion spaces ES1. The first sacrificial insulating layer SI1 may include a material having etch selectivity with respect to each of the first sacrificial layer ST1, the second sacrificial layer ST2, the third sacrificial layer ST3, and the first gate dielectric layer Gox1. For example, the first sacrificial insulating layer SI1 may include silicon nitride, silicon oxynitride, or silicon carbide.

Referring to FIGS. 10A through 10D together, by removing a portion of the stacked structure of the plurality of first sacrificial layers ST1 and the plurality of second sacrificial layers ST2, and a portion of each of the first channel layer CH1, the first gate dielectric layer Gox1, and the first sacrificial insulating layer SI1 adjacent to one third sacrificial layer ST3, a second trench TR2 penetrating the stacked structure of the plurality of first sacrificial layers ST1 and the plurality of second sacrificial layers ST2. In plan view, the second trench TR2 may be formed to extend in the first horizontal direction. The second trench TR2 may be formed to be adjacent to one third sacrificial layer ST3. The second trench TR2 may be formed to overlap both the first through hole HO1 illustrated in FIGS. 9A through 9D in the vertical direction, and a portion of each of the first through hole HO1, the first channel layer CH1 filling the first through hole HO1, the first gate dielectric layer Gox1, and the first sacrificial insulating layer SI1 may be removed. The second trench TR2 may be formed to overlap portions of the plurality of first expansion spaces ES1 in the vertical direction, but not to overlap the remaining portions. For example, as a result of the formation of the second trench TR2, the planar shape of each of the plurality of first expansion spaces ES1 may generally have a semi-circular shape in which a lower portion thereof is removed. For example, as a result of the formation of the second trench TR2, the first gate dielectric layer Gox1 and the first channel layer CH1 may have a semi-circular or half-ring shape in plan view.

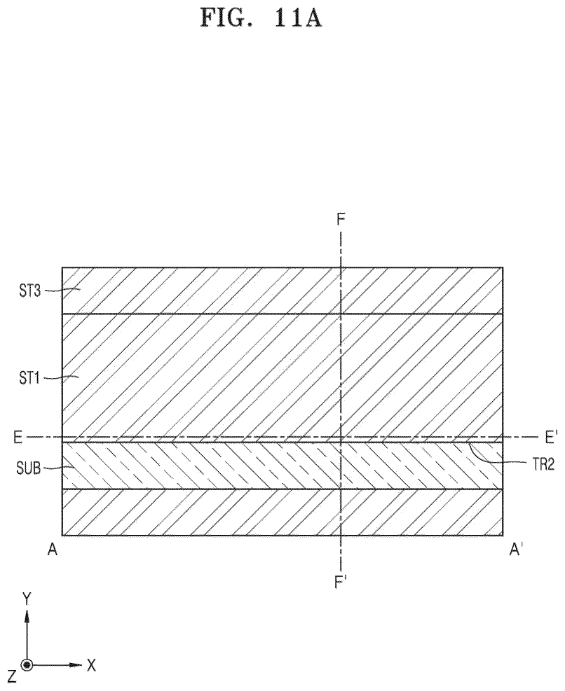

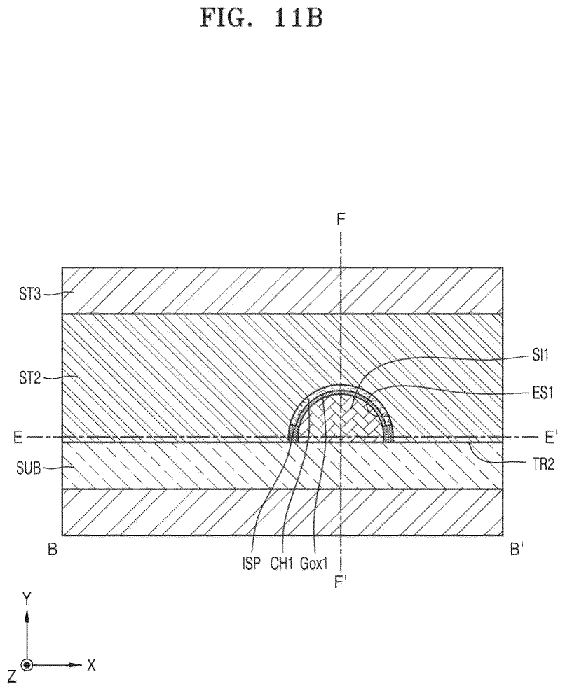

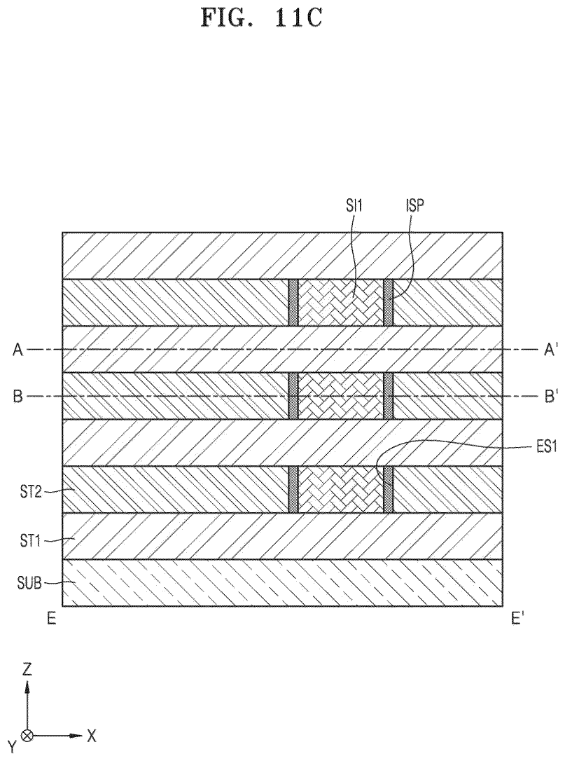

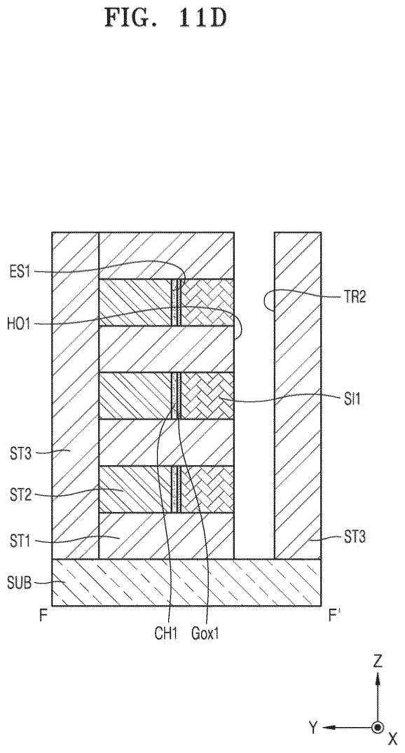

Referring to FIGS. 11A through 11D together, after a portion of the first channel layer CH1 and a portion of the first gate dielectric layer Gox1 exposed in the second trench TR2 are removed, the insulating spacer ISP filling spaces, in which a portion of the first channel layer CH1 and a portion of the first gate dielectric layer Gox1 are removed, may be formed. The remaining portion of the first channel layer CH1 and the remaining portion of the first gate dielectric layer Gox1 may be spaced apart from the second trench TR2 with the insulating spacer ISP arranged therebetween.

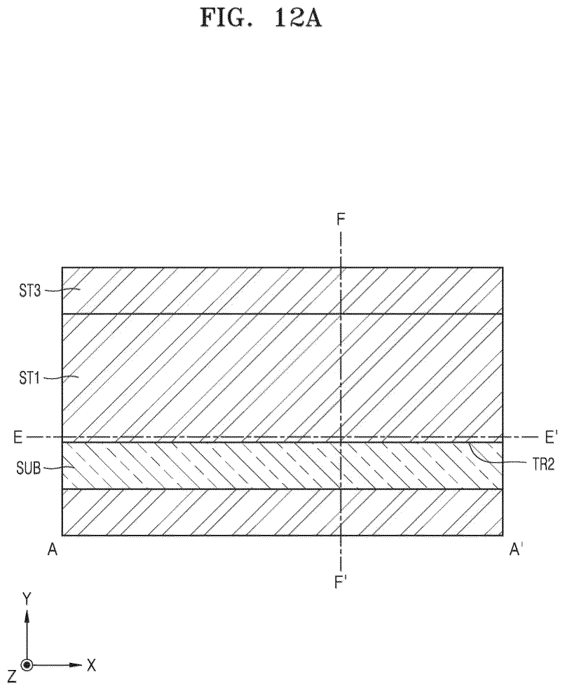

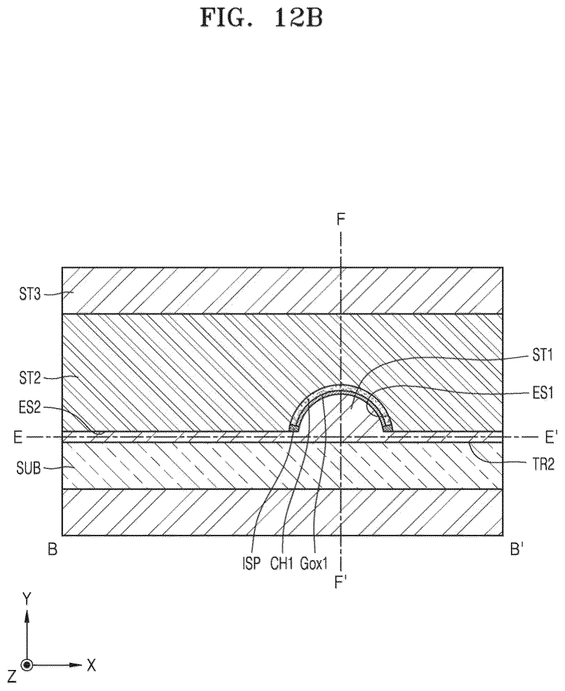

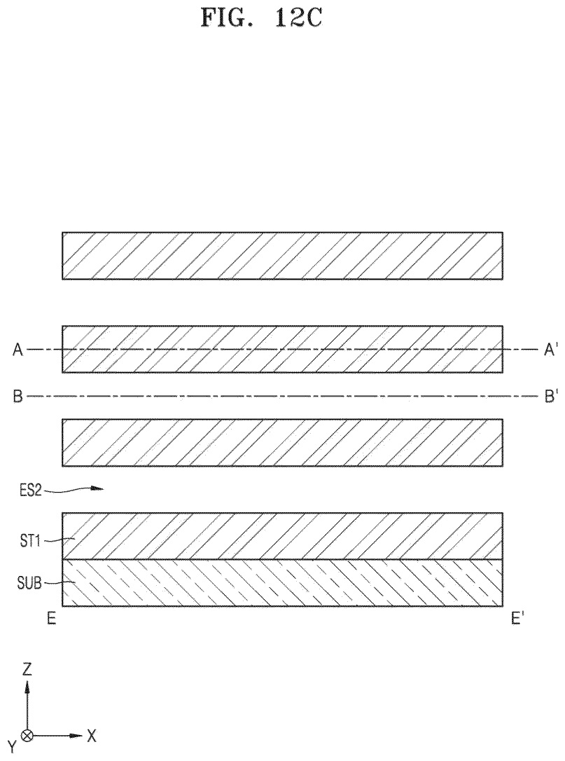

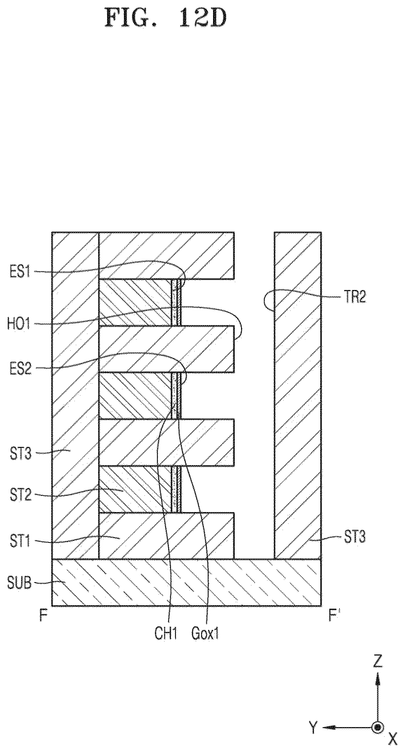

Referring to FIGS. 11A through 11D, and FIGS. 12A through 12D together, a plurality of second expansion spaces ES2 may be formed by removing portions of the plurality of second sacrificial layers ST2 through the second trench TR2. The second trench TR2 and the plurality of second expansion spaces ES2 may be interconnected to each other. In the process of forming the plurality of second expansion spaces ES2, a portion of the insulating spacer ISP may be also removed, but the remaining portion thereof may remain, and thus the first channel layer CH1 and the first gate dielectric layer Gox1 may not be exposed in the plurality of second expansion spaces ES2. For example, the first channel layer CH1 and the first gate dielectric layer Gox1 may be spaced apart from the plurality of second expansion spaces ES2 with the insulating spacer ISP therebetween. Each of the plurality of second expansion spaces ES2 may be formed to extend in the first horizontal direction in plan view, between two first sacrificial layers ST1 adjacent to each other in the vertical direction.

After the plurality of second expansion spaces ES2 are formed, all of the first sacrificial insulating layers SI1 may be removed.

Referring to FIGS. 11A through 11D, 12A through 12D, and 13A through 13D together, a plurality of capacitors CAP including a plurality of first electrodes EL1 which sequentially fill a space, from which the first sacrificial insulating layer SI1 has been removed, and the plurality of second expansion spaces ES2, a plurality of capacitor dielectric layers CDI, and a plurality of second electrodes EL2, may be formed. For example, after an electrode material layer filling at least a portion of the second trench TR2, a space from which the first sacrificial insulating layer SI1 has been removed, and the plurality of second expansion space ES2 is formed, the plurality of first expansion spaces ES1 may be formed by removing a portion of the electrode material layer filling at least a portion of the second trench TR2, and the other portion of the electrode material layer filling a portion of each of the plurality of second expansion spaces ES2, and then, a plurality of capacitor dielectric layers CDI covering the plurality of first electrodes EL1 and filling other portions of the plurality of second expansion spaces ES2 and a plurality of second electrodes EL2 filling the remaining portions of the plurality of second expansion space ES2 may be formed.

The first portion (PT1 in FIGS. 2A and 2B) of the first electrode EL1 of the capacitor CAP may have a semi-circular shape in plan view, and the second portion (PT2 in FIGS. 2A and 2B) thereof may have a bar shape extending in the first horizontal direction. The second portion PT2 of the first electrode EL1 of the capacitor CAP may include a portion of the first electrode EL1 of the capacitor CAP arranged in each of the plurality of second expansion spaces ES2, and the first portion PT1 of the first electrode EL1 of the capacitor CAP may include a remaining portion of the first electrode EL1 of the capacitor CAP filling a space from which the first sacrificial insulating layer SI1 has been removed. The second electrode EL2 of the capacitor CAP may have a bar shape extending in the first horizontal direction.

Each of the first electrode EL1 and the second electrode EL2 may include doped silicon, a metal, conductive metal nitride, conductive metal silicide, conductive metal oxide, or a combination thereof. For example, each of the first electrode EL1 and the second electrode EL2 may include a metal layer, such as Co, Ti, Ni, W, Mo, Ru, Pt, Ir, and/or Ta, a metal nitride layer, such as TiN, TiSiN, TiAlN, TaN, TaSiN, TaAlN, and/or WN, and a conductive metal oxide, such as RuO, PtO, IrO, SRO(SrRuO), BSRO((Ba, Sr)RuO), CRO(CaRuO), BaRuO, and/or La(Sr, Co)O, or a combination thereof. The capacitor dielectric layer CDI may include at least one of a high-k dielectric material or a ferroelectric material having a dielectric constant higher than that of silicon oxide. For example, the capacitor dielectric layer CDI may include at least one of a metal oxide or a dielectric material having a perovskite structure. In some embodiments, the capacitor dielectric layer CDI may include at least one of hafnium oxide (HfO), hafnium silicate (HfSiO), hafnium oxynitride (HfON), hafnium silicon oxynitride (HfSiON), or lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium tantalum oxide bismuth (STB), bismuth ferrous oxide (BFO), strontium titanium oxide (SrTiO), yttrium oxide (YO), aluminum oxide (AlO), or lead scandium tantalum oxide (PbScTaO), a material doped with yttrium (Y), magnesium (Mg), silicon (Si), or barium (Ba) thereon. In some embodiments, the capacitor CAP may include a ferroelectric capacitor including a ferroelectric material which is an insulating material in which the capacitor dielectric layer CDI of the capacitor CAP has hysteresis characteristics.

Referring to FIGS. 14A through 14C, by removing portions of the stacked structure of the plurality of first sacrificial layers ST1 and the plurality of second sacrificial layers ST2, a plurality of second through holes HO2 penetrating the stacked structure of the plurality of first sacrificial layers ST1 and the plurality of second sacrificial layers ST2 may be formed. For example, two second through holes HO2 may be formed adjacent to each other in one first expansion space ES1. In some embodiments, the second through hole HO2 may be formed such that a horizontal cross-section thereof has a circular shape.

Each of the two second through holes HO2 may be formed adjacent to the first expansion space ES1, but not in contact with the first expansion space ES1. The first channel layer CH1 may not be exposed in each of the two second through holes HO2. For example, the plurality of first sacrificial layers ST1 and the plurality of second sacrificial layers ST2 may be exposed on an inner side wall of each of the two second through holes HO2, and the substrate SUB may be exposed on a bottom surface thereof.

Two second through holes HO2 adjacent to one first expansion space ES1 may be formed to be spaced apart from each other in the first horizontal direction. Two second through holes HO2 adjacent to one first expansion space ES1 may be formed to be more adjacent to the other third sacrificial layer ST3 than the one first expansion space ES1. The second through hole HO2 may be formed to be spaced apart from each of a plurality of second trenches TR2 and the third sacrificial layer ST3 in the second horizontal direction, between the plurality of second trenches TR2 and the third sacrificial layer ST3 in plan view. For example, the second through hole HO2 may be formed by removing a portion of each of the plurality of first sacrificial layers ST1 and the plurality of second sacrificial layers ST2, positioned between the plurality of second trenches TR2 and the third sacrificial layer ST3 in plan view.

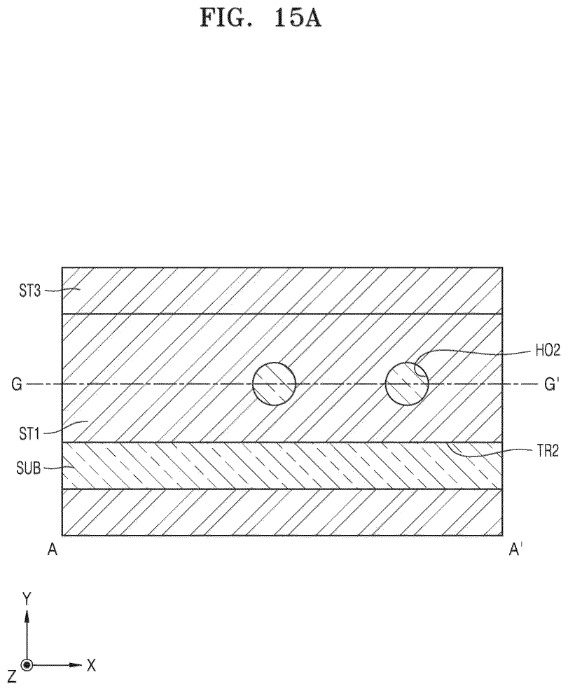

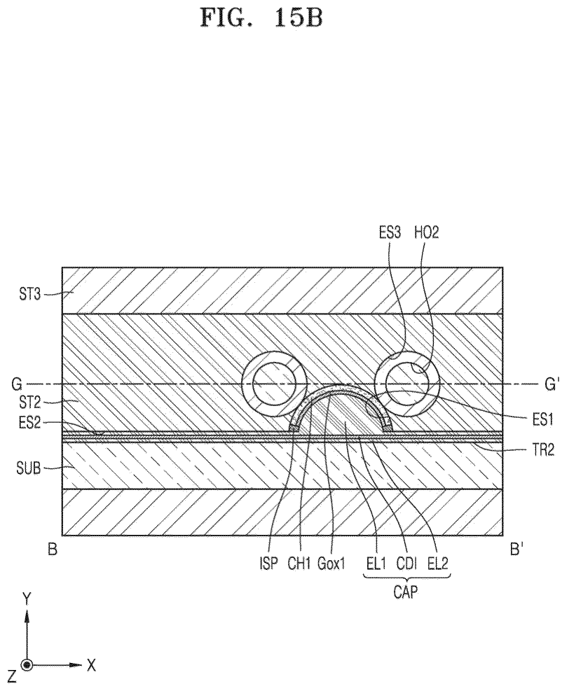

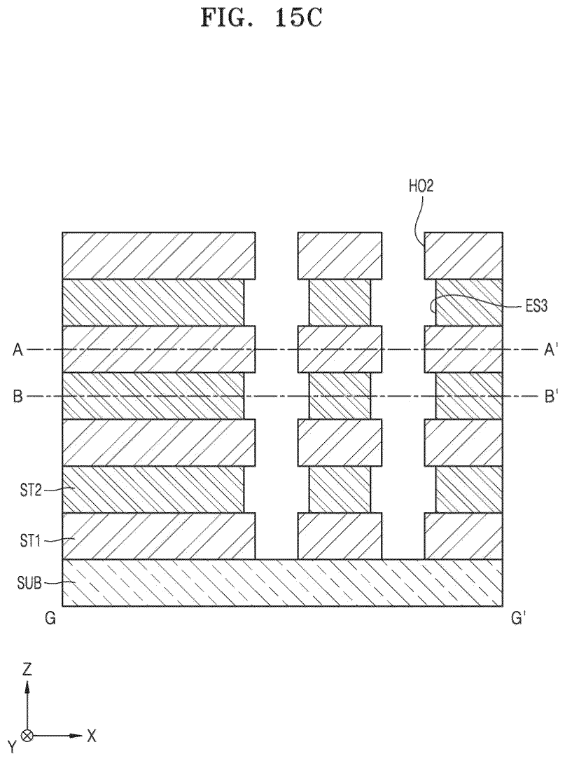

Referring to FIGS. 15A through 15C together, by removing portions of the plurality of second sacrificial layers ST2 through the plurality of second through holes HO2, a plurality of third expansion spaces ES3 may be formed. The plurality of third expansion spaces ES3 may be interconnected to the second through hole HO2. A horizontal width of each of the plurality of third expansion spaces ES3 may have a value greater than a horizontal width of the second through hole HO2. When a planar shape of the second through hole HO2 has a circular shape, the planar shape of each of the plurality of third expansion spaces ES3 may have a circular shape. For example, the diameter of each of the plurality of third expansion spaces ES3 may be greater than the diameter of the second through hole HO2.

The plurality of third expansion spaces ES3 may be formed to be respectively in contact with the plurality of first expansion spaces ES1. For example, a portion of the first channel layer CH1 may be exposed on an inner sidewall of each of the plurality of third expansion spaces ES3.

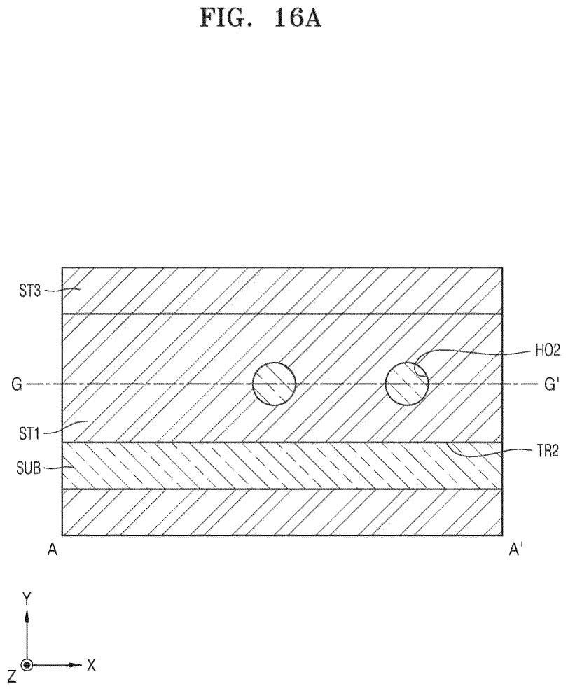

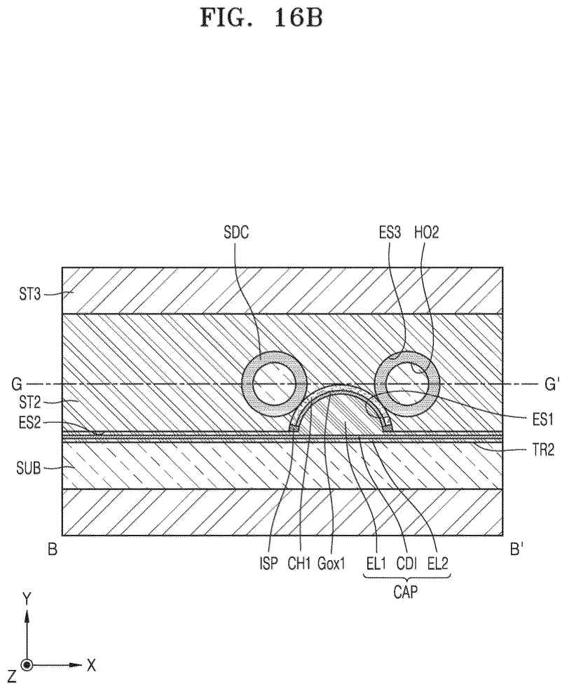

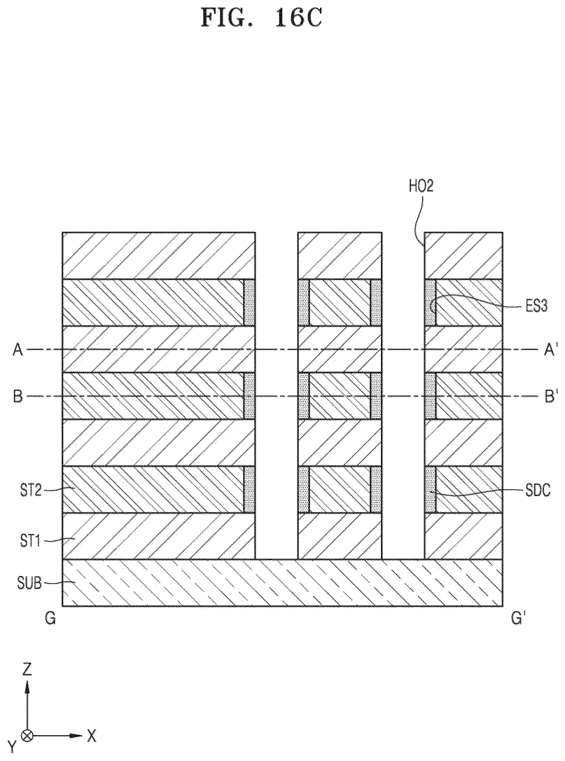

Referring to FIGS. 16A through 16C together, the source/drain contact layer SDC filling each of the plurality of third expansion spaces ES3 may be formed. For example, when the second through hole HO2 has a circular shape in plan view, the source/drain contact layer SDC may have a ring shape in plan view. The source/drain contact layer SDC may include a semiconductor material, a 2D material semiconductor, or an oxide semiconductor material. After a contact material layer filling all of the second through hole HO2 and the plurality of third expansion spaces ES3, by removing a portion of the contact material layer filling the second through hole HO2, a plurality of source/drain contact layers SDC may be formed.

In some embodiments, before the source/drain contact layer SDC is formed, a doping process of injecting impurities into a portion of the first channel layer CH1 exposed on an inner wall of each of the plurality of third expansion spaces ES3 may be performed. For example, when the first channel layer CH1 is formed to include a first impurity to have a first conductivity type, by injecting a second impurity into a portion of the first channel layer CH1 exposed on the inner wall of each of the plurality of third expansion spaces ES3, a portion of the first channel layer CH1 exposed on the inner wall of each of the plurality of third expansion spaces ES3 may have the second conductivity type different from the first conductivity type. In some embodiments, the first conductivity type may be of a p-type and the second conductivity type may be of an n-type. In some embodiments, in some embodiments, the first conductivity type may be of an n-type and the second conductivity type may be of a p-type. In some embodiments, the source/drain contact layer SDC may be formed to include a second impurity to have a second conductivity type.

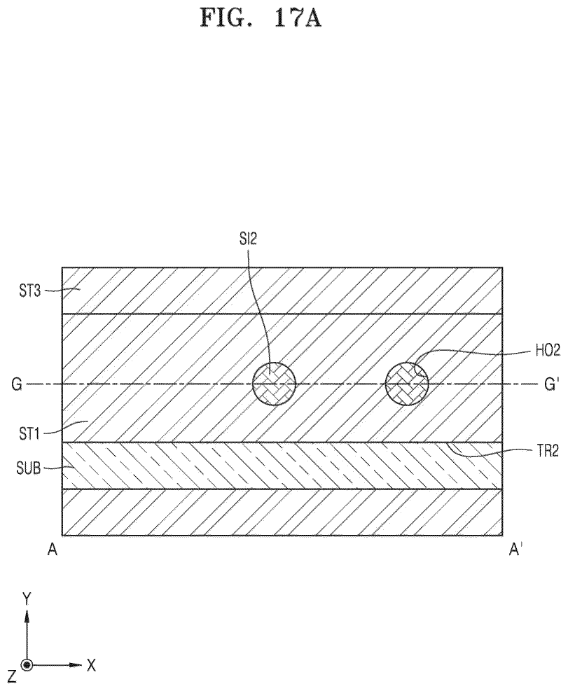

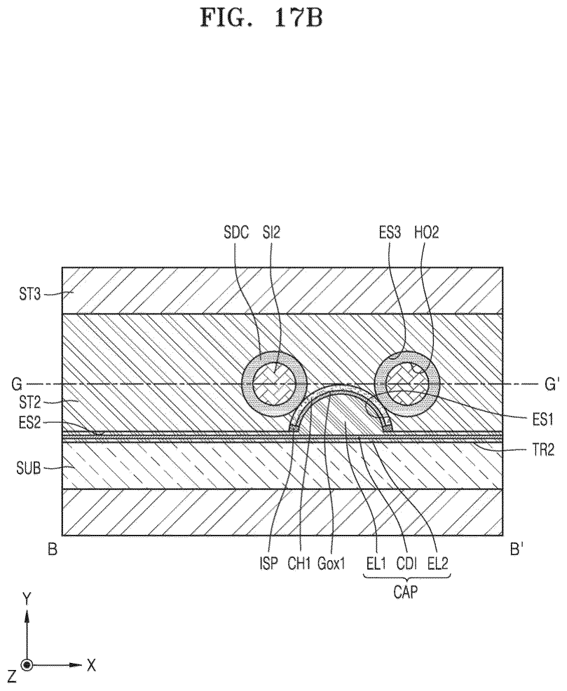

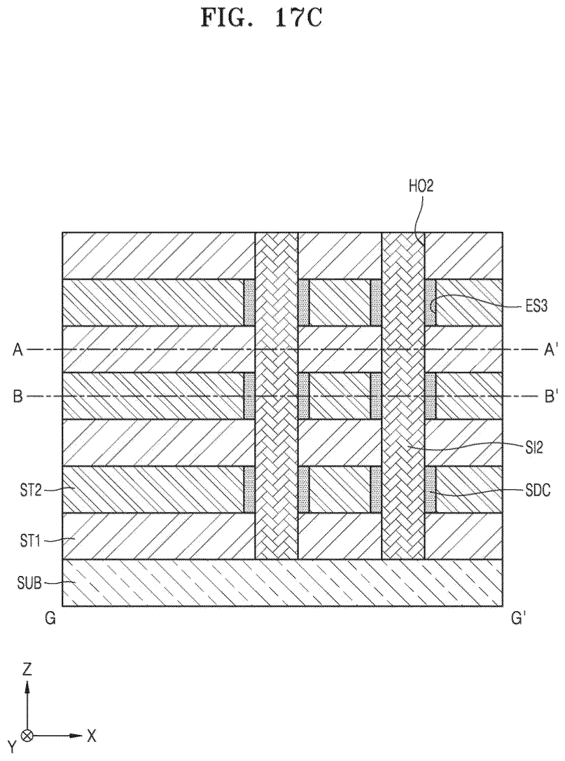

Referring to FIGS. 17A through 17C together, a second sacrificial insulating layer SI2 filling the plurality of second through holes HO2 may be formed. The second sacrificial insulating layer SI2 may be formed to completely fill the plurality of second through holes HO2. The second sacrificial insulating layer SI2 may include a material having etch selectivity with respect to each of the first sacrificial layer ST1, the second sacrificial layer ST2, the third sacrificial layer ST3, and the source/drain contact layer SDC. For example, the second sacrificial insulating layer SI2 may include silicon nitride, silicon oxynitride, or silicon carbide.

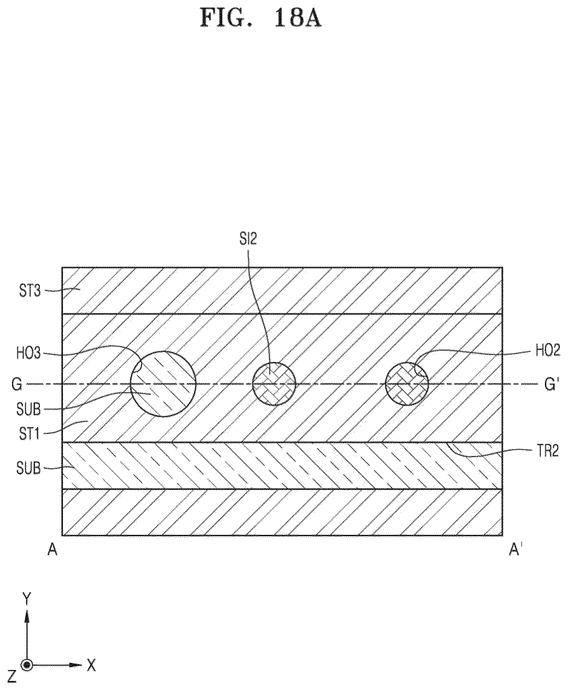

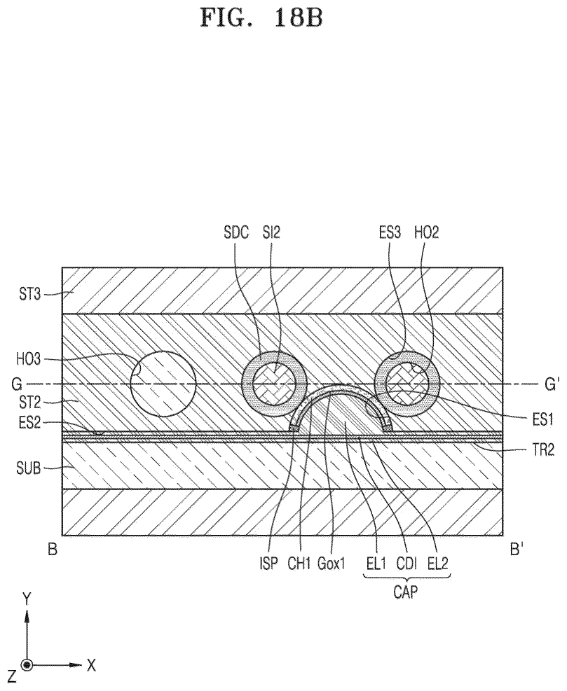

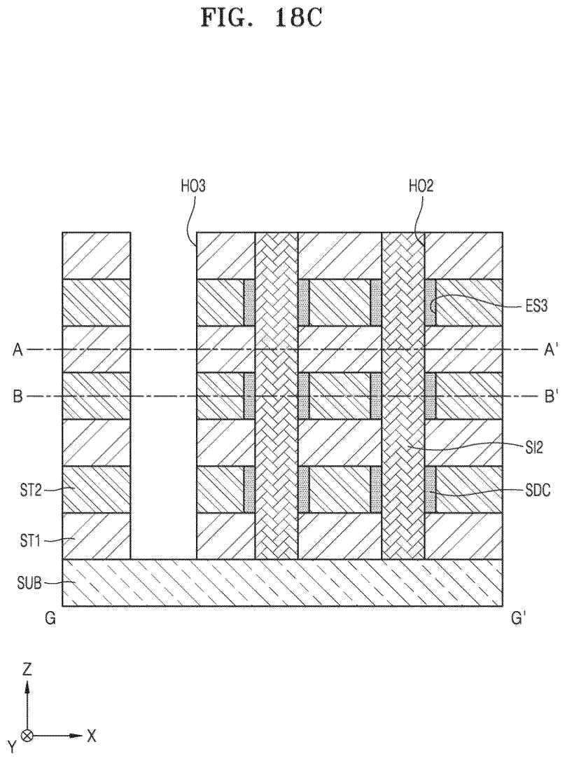

Referring to FIGS. 18A through 18C, by removing portions of the stacked structure of the plurality of first sacrificial layers ST1 and the plurality of second sacrificial layers ST2, a third through holes HO3 penetrating the stacked structure of the plurality of first sacrificial layers ST1 and the plurality of second sacrificial layers ST2 may be formed. In some embodiments, the third through hole HO3 may be formed such that a horizontal cross-section thereof has a circular shape. The third through hole HO3 may be formed to be adjacent to the plurality of second through holes HO2 and the plurality of third expansion spaces ES3. The source/drain contact layer SDC may not be exposed in the third through hole HO3. For example, the plurality of first sacrificial layers ST1 and the plurality of second sacrificial layers ST2 may be exposed on an inner side wall of the third through hole HO3, and the substrate SUB may be exposed on a bottom surface thereof.

The third through hole HO3 may be formed to be spaced apart from each of a plurality of second trenches TR2 and the third sacrificial layer ST3 in the second horizontal direction, between the plurality of second trenches TR2 and the third sacrificial layer ST3 in plan view. For example, the third through hole HO3 may be formed by removing a portion of each of the plurality of first sacrificial layers ST1 and the plurality of second sacrificial layers ST2, positioned between the plurality of second trenches TR2 and the third sacrificial layer ST3 in plan view.

The third through hole HO3 and two second through holes HO2 may be formed to be spaced apart from each other in the first horizontal direction. In some embodiments, the third through hole HO3 and two second through holes HO2 may be formed to be aligned with each other in the first horizontal direction. The third through hole HO3 may not be arranged between the two second through holes HO2 adjacent to the first expansion space ES1. For example, the third through hole HO3 may be formed to be spaced apart from the first expansion space ES1 and the entire two second through holes HO2 adjacent to the first expansion space ES1 in the first horizontal direction. For example, in the first horizontal direction, the third through hole HO3, one second through hole HO2, the first expansion space ES1, and the other second through hole HO2 may be arranged in order.

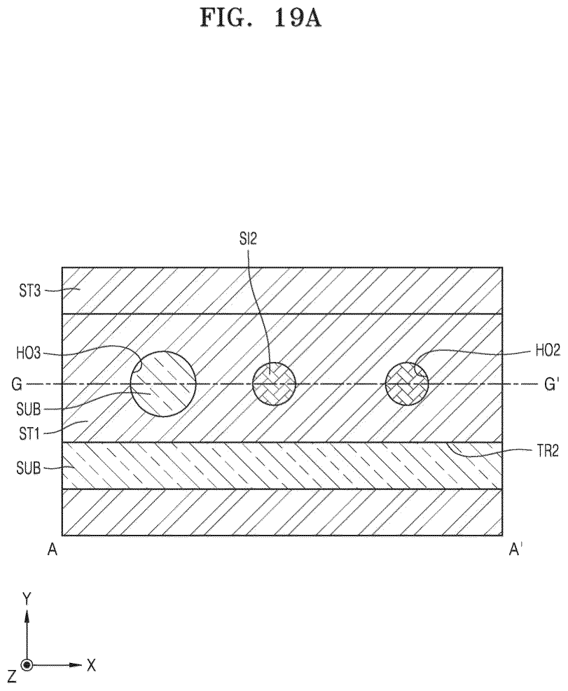

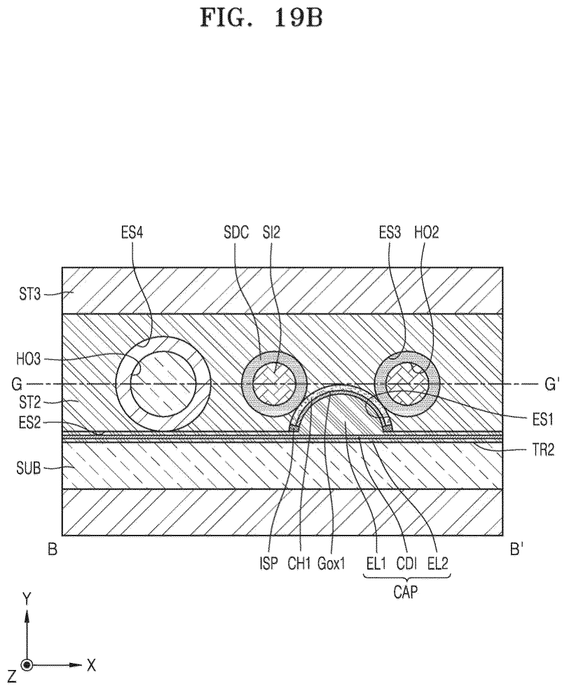

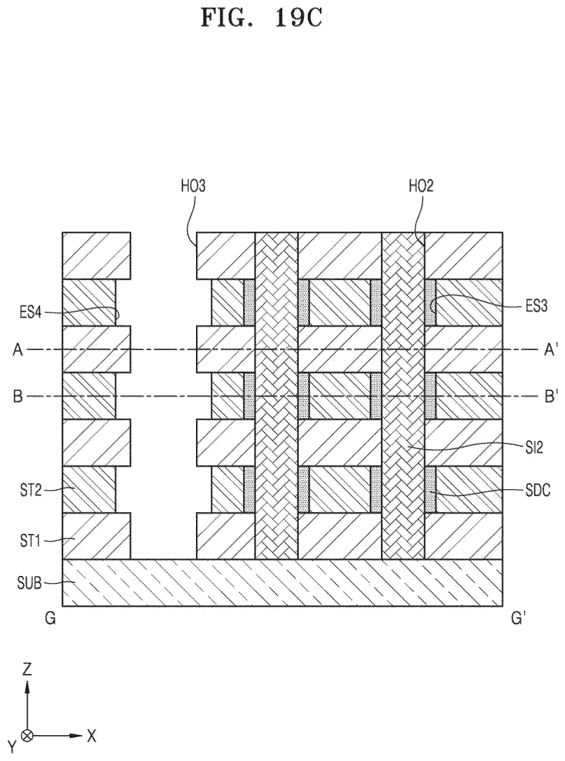

Referring to FIGS. 19A through 19C together, a plurality of fourth expansion spaces ES4 may be formed by removing portions of the plurality of second sacrificial layers ST2 through the third through hole HO3. The plurality of fourth expansion spaces ES4 may be interconnected to third through hole HO3. A horizontal width of each of the plurality of fourth expansion spaces ES4 may be greater than a horizontal width of the third through hole HO3. When a planar shape of the third through hole HO3 has a circular shape, the planar shape of each of the plurality of fourth expansion spaces ES4 may have a circular shape. For example, the diameter of each of the plurality of fourth expansion spaces ES4 may be greater than the diameter of the third through hole HO3.

The plurality of fourth expansion spaces ES4 may be formed to be respectively in contact with the plurality of second expansion spaces ES2. For example, a portion of the first electrode EL1 may be exposed on an inner sidewall of each of the plurality of fourth expansion spaces ES4.

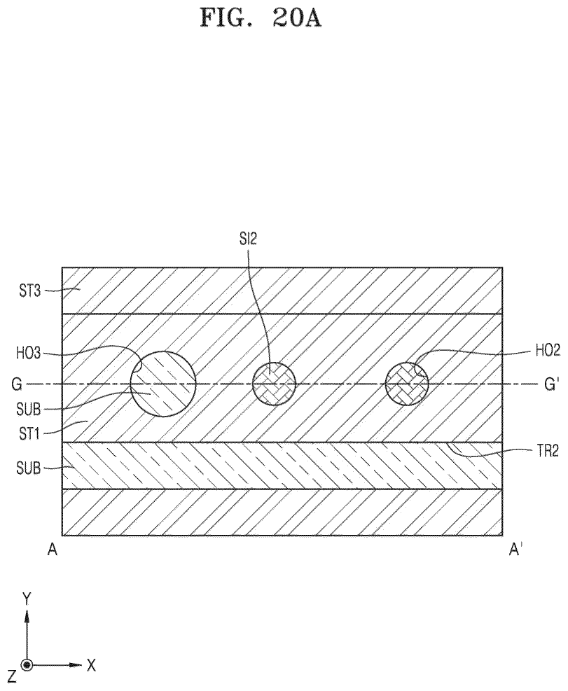

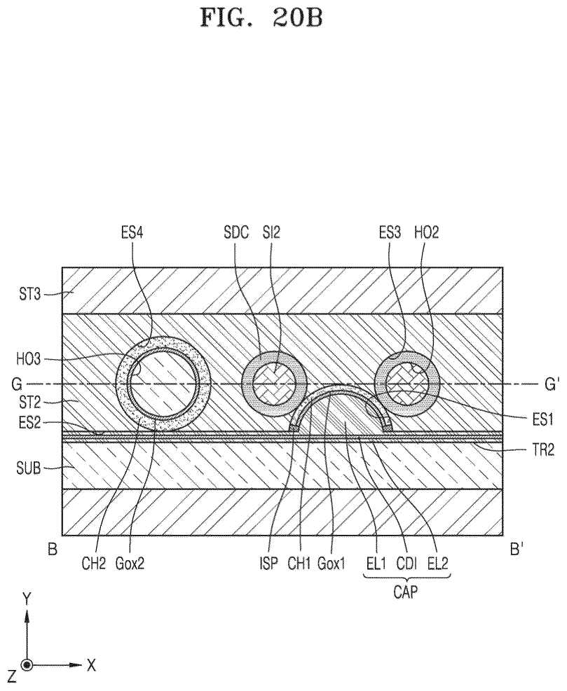

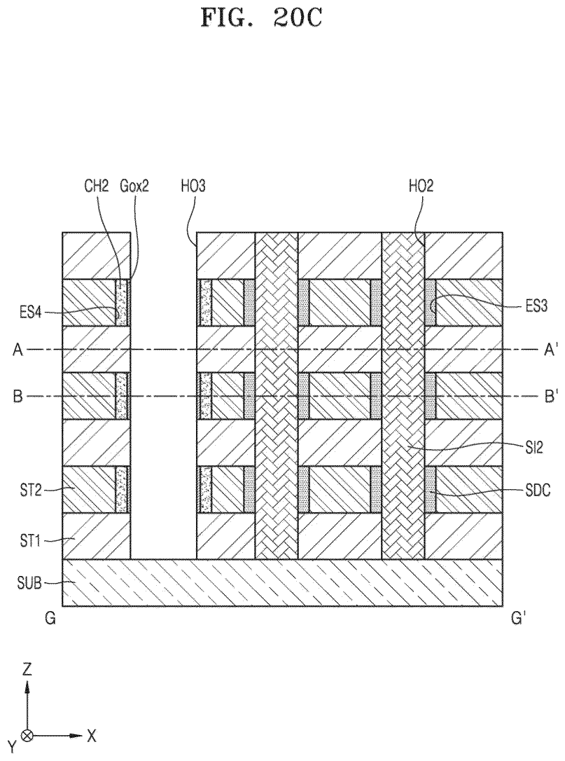

Referring to FIGS. 20A through 20C together, the second channel layer CH2 and the second gate dielectric layer Gox2 covering a surface of the first electrode EL1 and the sidewalls of the plurality of second sacrificial layers ST2 exposed in each of the plurality of fourth expansion spaces ES4 may be sequentially formed.

The second channel layer CH2 may include a material having etch selectivity with respect to each of the first sacrificial layer ST1, the second sacrificial layer ST2, and the third sacrificial layer ST3. The second channel layer CH2 may include a semiconductor material, a 2D semiconductor material, or an oxide semiconductor material. The second gate dielectric layer Gox2 may include at least one of silicon oxide, a high-k dielectric material or a ferroelectric material having a dielectric constant greater than a dielectric constant of silicon oxide.

For example, after a second channel material layer and a second gate dielectric material layer conformally covering the inner surfaces of the third through hole HO3 and the plurality of fourth expansion spaces ES4 are sequentially formed, by removing portions covering the inner surface of the third through hole HO3 and portions covering the surface of the first sacrificial layer ST1 in the plurality of fourth expansion spaces ES4, in the second channel material layer and the second gate dielectric material layer, the second channel layer CH2 and the second gate dielectric layer Gox2 covering the surface of the first electrode EL1 and the sidewalls of the plurality of second sacrificial layers ST2 exposed in each of the plurality of fourth expansion spaces ES4 may be formed. In some embodiments, after the second channel material layer and the second gate dielectric material layer conformally covering inner surfaces of the third through hole HO3 and the fourth expansion space ES4 are formed, a mold layer filling the third through hole HO3 and the plurality of fourth expansion spaces ES4 may be formed. Thereafter, a portion of the mold layer filling the third through hole HO3, a portion of the second channel material layer covering the inner surface of the third through hole HO3, and a portion of the second gate dielectric material layer may be removed, and in a state where the remaining portion of the mold layer filling the plurality of fourth expansion spaces ES4 remain, by removing portions covering the surface of the first sacrificial layer ST1 in the second channel material layer and the second gate dielectric layer and removing the remaining portion of the mold layer, the second channel layer CH2 and the second gate dielectric layer Gox2 covering the sidewalls of the plurality of second sacrificial layers ST2 exposed in each of the plurality of fourth expansion spaces ES4 may be formed.

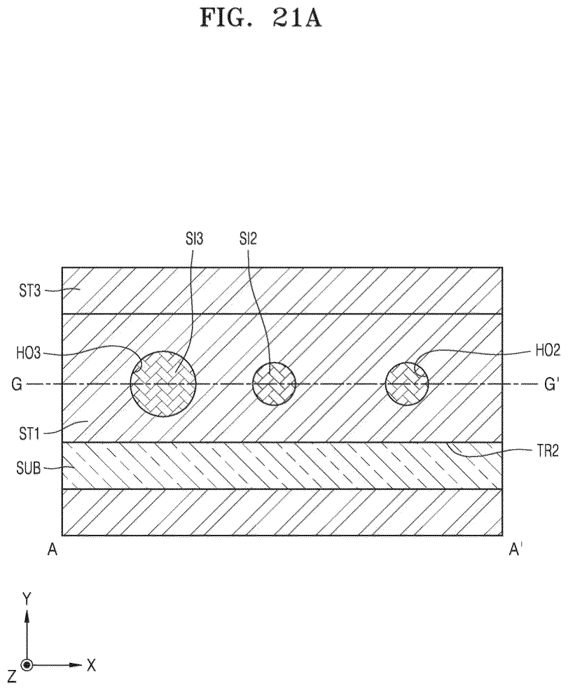

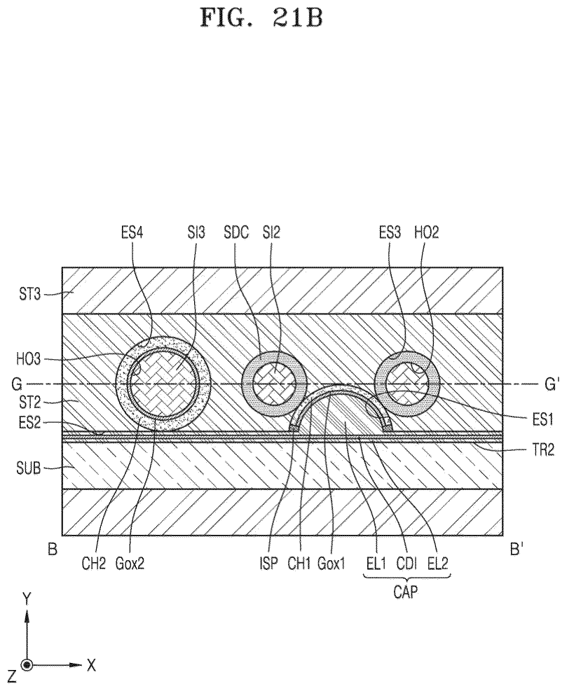

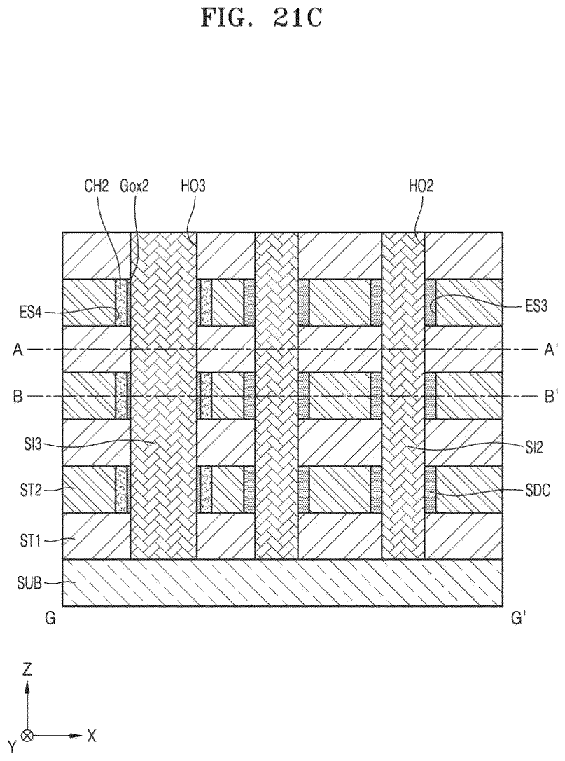

Referring to FIGS. 21A through 21C together, a third sacrificial insulating layer SI3 filling the third through hole HO3 may be formed. The third sacrificial insulating layer SI3 may be formed to completely fill the third through hole HO3. The third sacrificial insulating layer SI3 may include a material having etch selectivity with respect to each of the first sacrificial layer ST1, the second sacrificial layer ST2, the third sacrificial layer ST3, and the second gate dielectric layer Gox2. For example, the third sacrificial insulating layer SI3 may include silicon nitride, silicon oxynitride, or silicon carbide.

Referring to FIGS. 22A through 22C, by removing a portion of a stacked structure of the plurality of first sacrificial layers ST1 and the plurality of second sacrificial layers ST2, a third trench TR3 penetrating the stacked structure of the plurality of first sacrificial layers ST1 and the plurality of second sacrificial layers ST2. In plan view, the third trench TR3 may extend in the first horizontal direction. The third trench TR3 may be formed adjacent to another third sacrificial layer ST3. In some embodiments, a sidewall of another third sacrificial layer ST3 may be exposed in the third trench TR3. The third trench TR3 may be formed to be spaced apart from the plurality of third expansion spaces ES3 and the plurality of fourth expansion spaces ES4. For example, the source/drain contact layer SDC and the second channel layer CH2 may not be exposed in the third trench TR3.

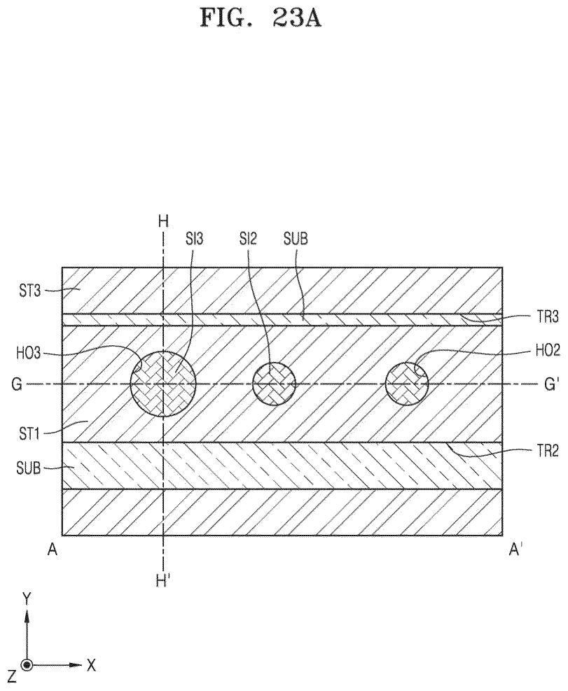

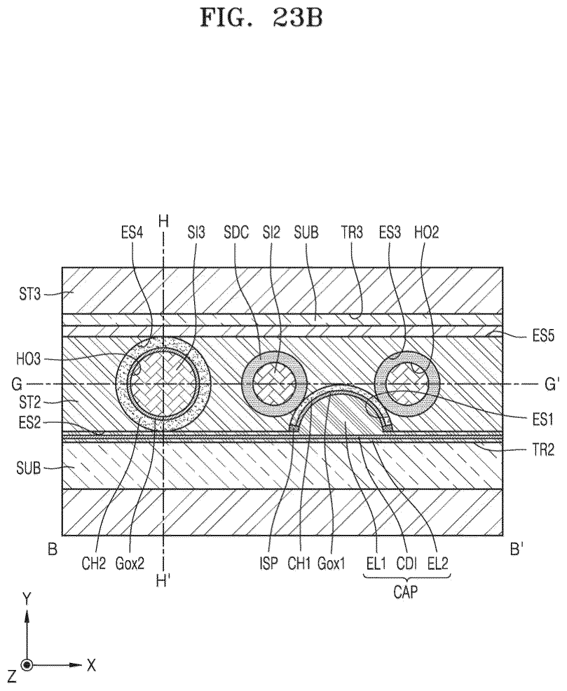

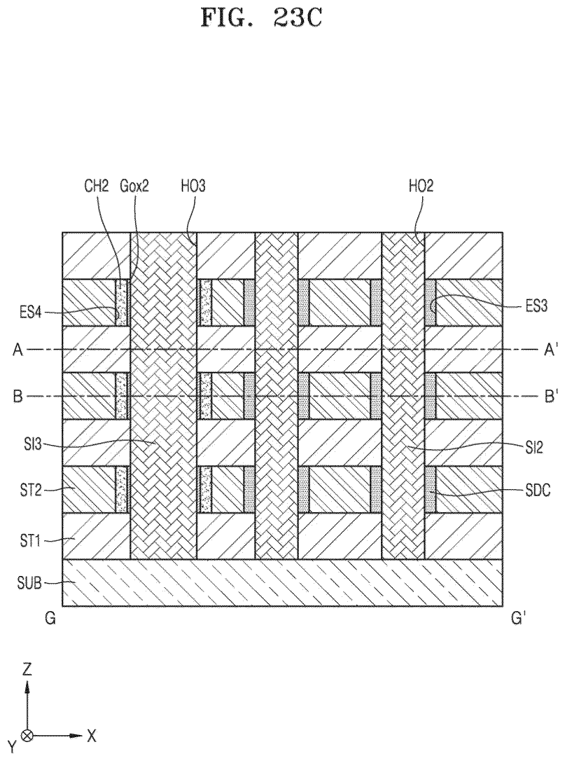

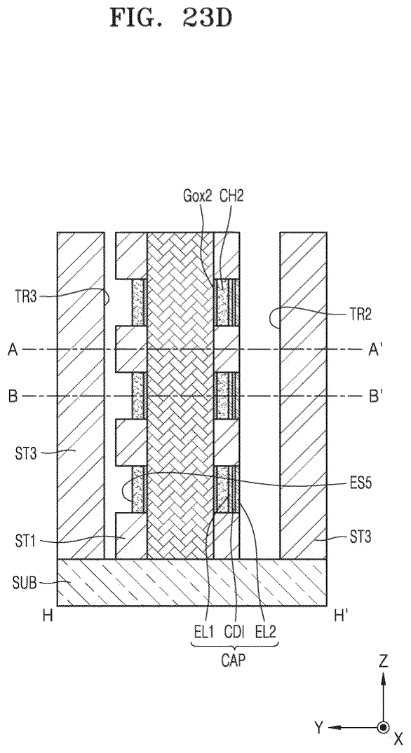

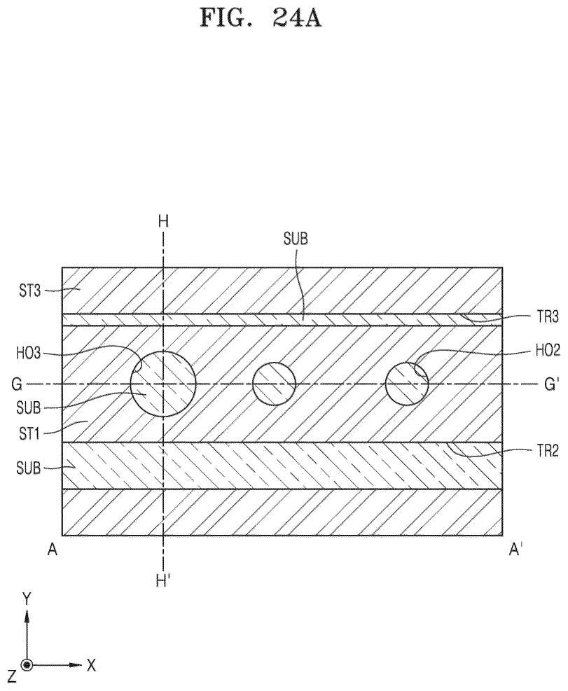

Referring to FIGS. 23A through 23D together, by removing portions of the plurality of second sacrificial layers ST2 through the third trench TR3, a plurality of fifth expansion spaces ES5. The third trench TR3 may be interconnected to the plurality of fifth expansion spaces ES5. The plurality of fifth expansion spaces ES5 may be formed by removing portions of the plurality of second sacrificial layers ST2 such that the second channel layer CH2 is exposed. A surface of a portion of the second channel layer CH2 may be exposed in each of the plurality of fifth expansion spaces ES5.

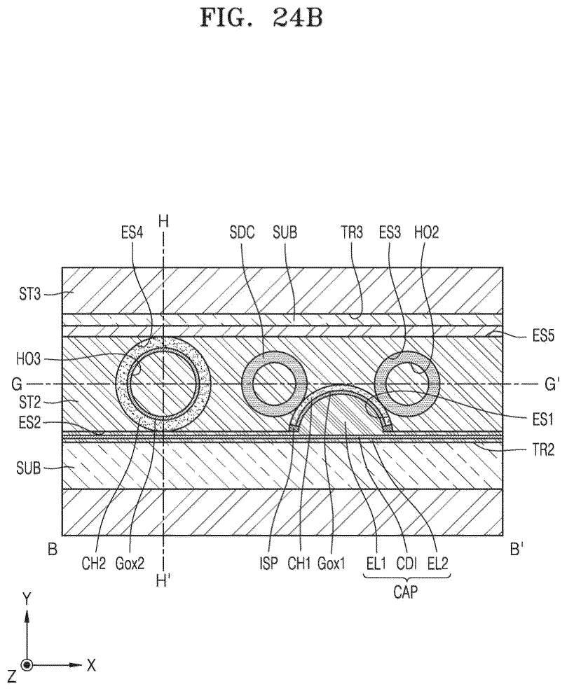

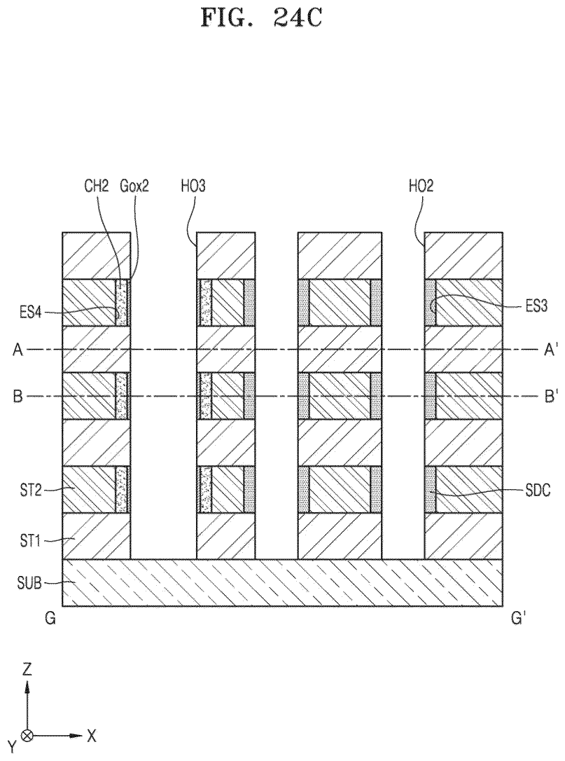

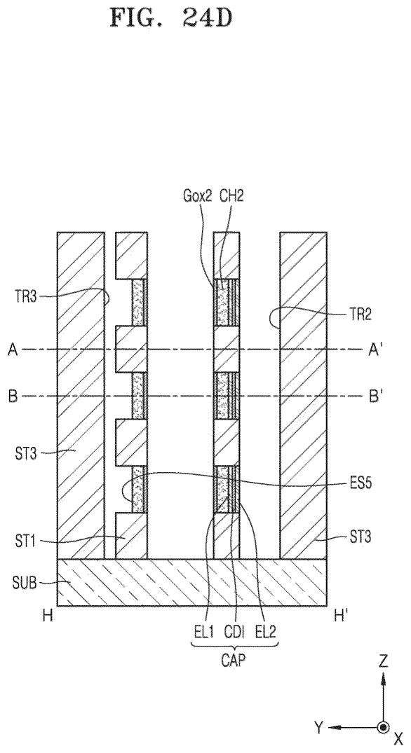

Referring to FIGS. 23A through 23D and 24A through 24D together, a plurality of second sacrificial insulating layers SI2 and the third sacrificial insulating layer SI3 may be removed. As a result of removing the plurality of second sacrificial insulating layers SI2 and the third sacrificial insulating layer SI3, the source/drain contact layer SDC may be exposed in each of the plurality of second through holes HO2, and the second channel layer CH2 may be exposed in the third through hole HO3.

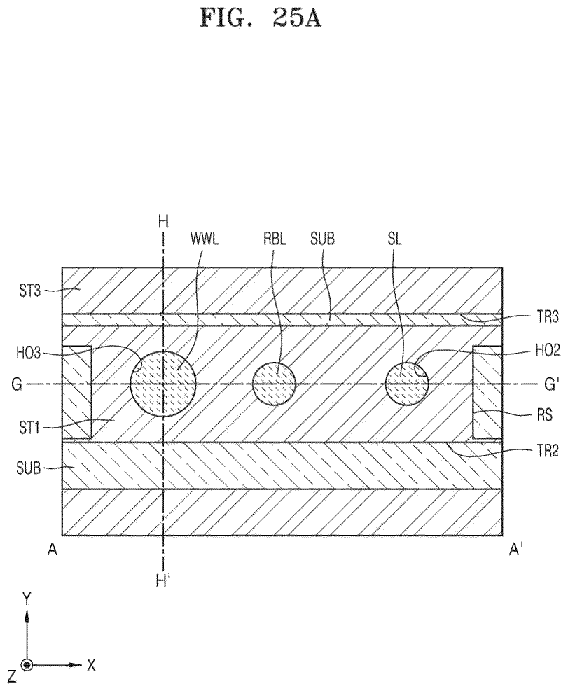

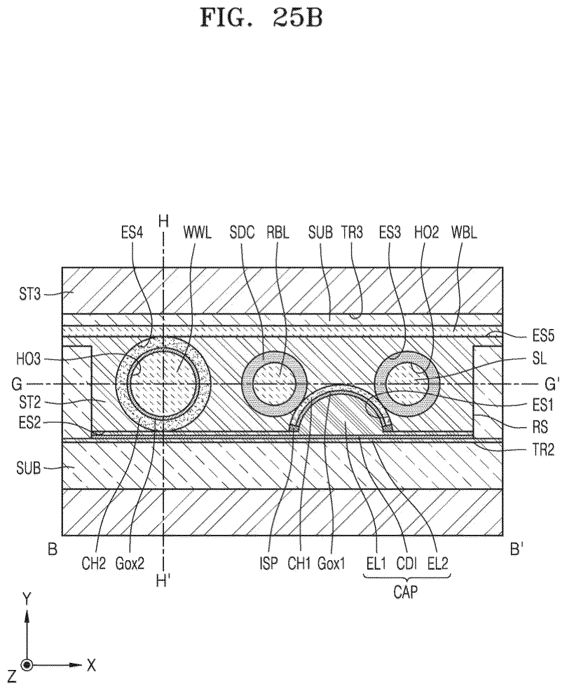

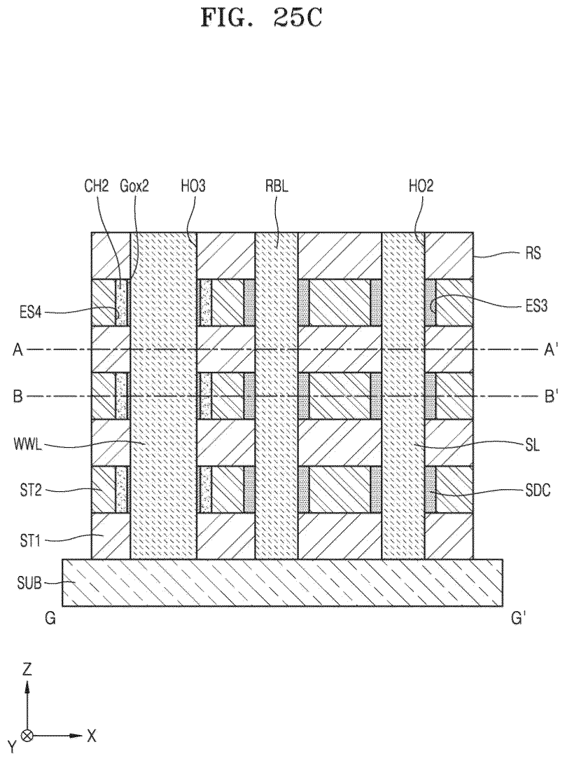

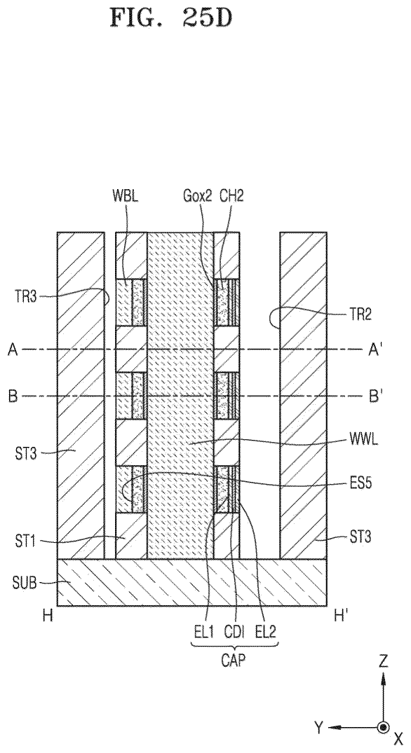

Referring to FIGS. 25A through 25D together, the read bit line RBL and the source line SL filling the plurality of second through holes HO2, the write word line WWL filling the third through hole HO3, and the plurality of write bit lines WBL respectively filling the plurality of fifth expansion spaces ES5 may be formed. After a conductive material filling the plurality of second through holes HO2, the third through hole HO3, the third trench TR3, and the plurality of fifth expansion spaces ES5 is formed, by removing a portion of the conductive material filling the third trench TR3, the read bit line RBL, the source line SL, the write word line WWL, and the plurality of write bit lines WBL may be formed. The read bit line RBL may include a portion of the conductive material filling one second through hole HO2 of two second through holes HO2 adjacent to the capacitor CAP, the source line SL may include a portion of the conductive material filling the other second through hole HO2 of the two second through holes HO2 adjacent to the capacitor CAP, the write word line WWL may include a portion of the conductive material filling the third through hole HO3, and the plurality of write bit lines WBL may include portions of the conductive material filling the plurality of fifth expansion spaces ES5.

Thereafter, by removing portions of the stacked structures of the plurality of first sacrificial layers ST1 and the plurality of second sacrificial layers ST2, a plurality of recess spaces RS penetrating the stacked structure of the plurality of first sacrificial layers ST1 and the plurality of second sacrificial layers ST2. A plurality of recess spaces RS may be formed to be spaced apart from each other in the first horizontal direction. The plurality of recess spaces RS may be formed to be spaced apart from each of the first expansion space ES1, the second trench TR2, the plurality of second through holes HO2, the plurality of third expansion spaces ES3, the third trench TR3, the plurality of fourth expansion spaces ES4, the third through hole HO3, and the plurality of fifth expansion spaces ES5, and from components filling each of these members. In plan view, between two recess spaces RS adjacent to each other in the first horizontal direction, the plurality of second through holes HO2, the plurality of third expansion spaces ES3, the third through hole HO3, and the plurality of fourth expansion spaces ES4 may be arranged.

In the process of forming the recess space RS, a portion of the first electrode EL1 may be removed. In some embodiments, in the process of forming the recess space RS, a portion of the first electrode EL1 and a portion of the capacitor dielectric layer CDI may be removed together. For example, in the recess space RS, a portion of the capacitor dielectric layer CDI or a portion of the second electrode EL2 may be exposed. As a result of removing a portion of the first electrode EL1 by forming the recess space RS, an extension length of the second portion (PT2 in FIGS. 2A and 2B) of the first electrode EL1 of the capacitor CAP in the first horizontal direction may be less than an extension length of the second electrode EL2 of the capacitor CAP. The extension length of the second portion PT2 of the first electrode EL1 of the capacitor CAP in the first horizontal direction may be limited by a space between two recess spaces RS adjacent to each other in the first horizontal direction. In some embodiments, the extension length of the capacitor dielectric layer CDI of the capacitor CAP in the first horizontal direction may be generally the same as the extension length of the second portion PT2 of the first electrode EL1 of the capacitor CAP. For example, the extension length of the capacitor dielectric layer CDI of the capacitor CAP in the first horizontal direction may be limited by the space between two recess spaces RS adjacent to each other in the first horizontal direction.

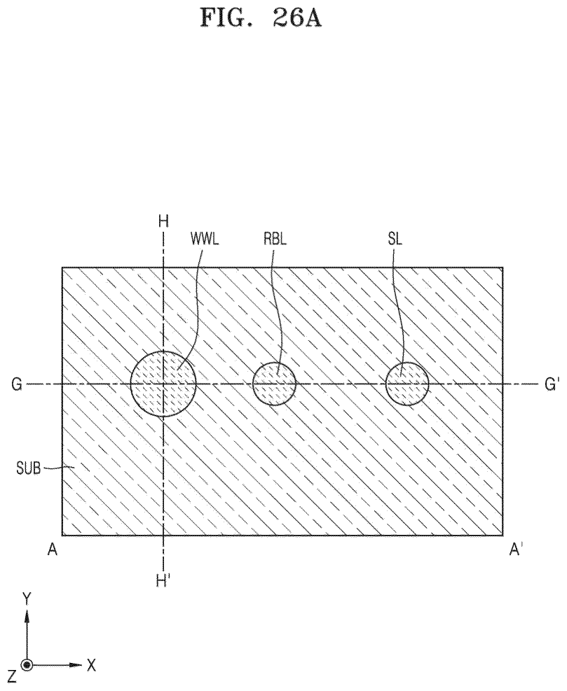

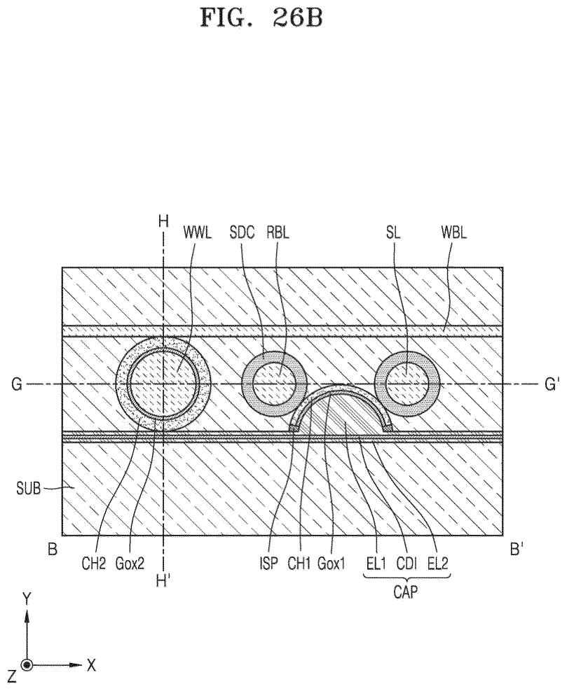

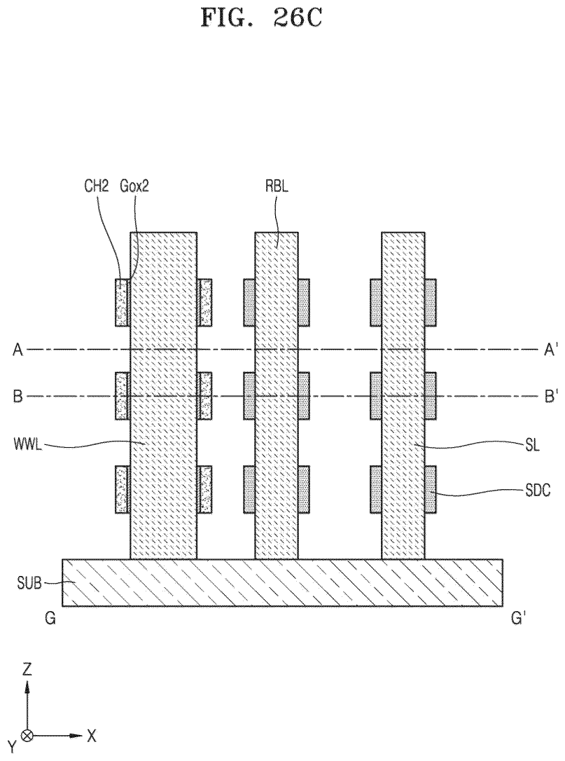

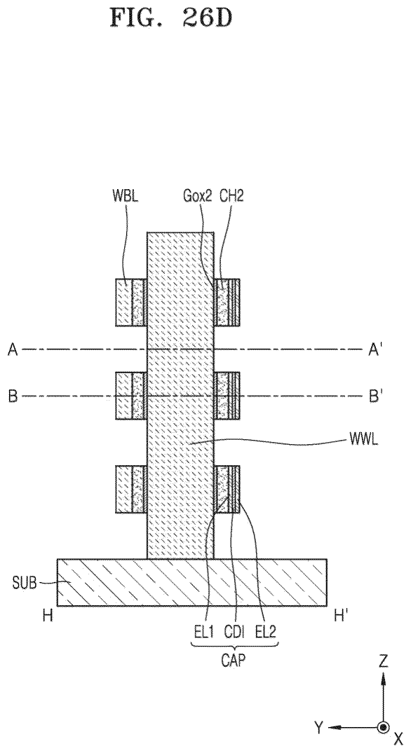

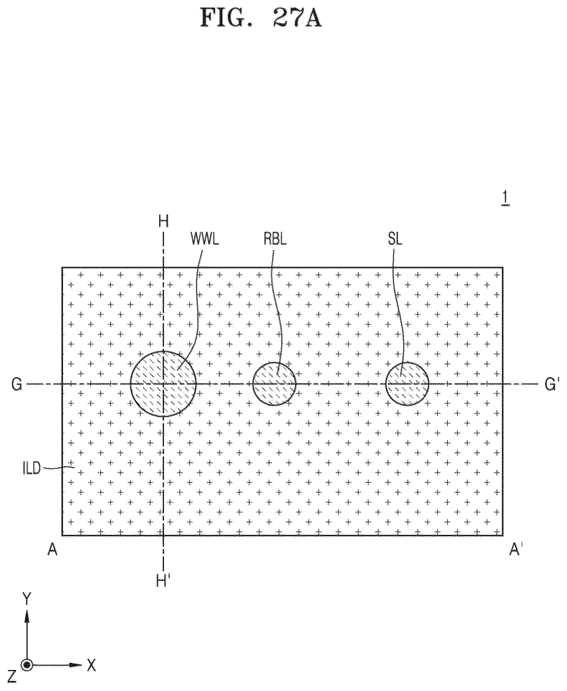

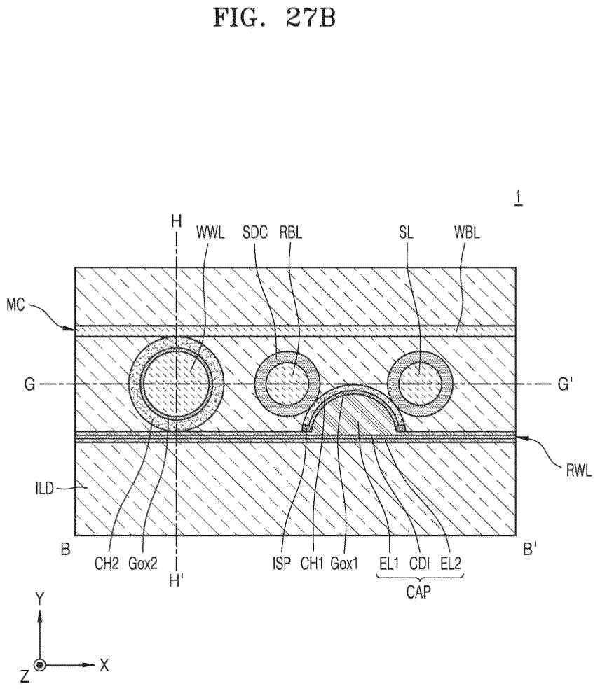

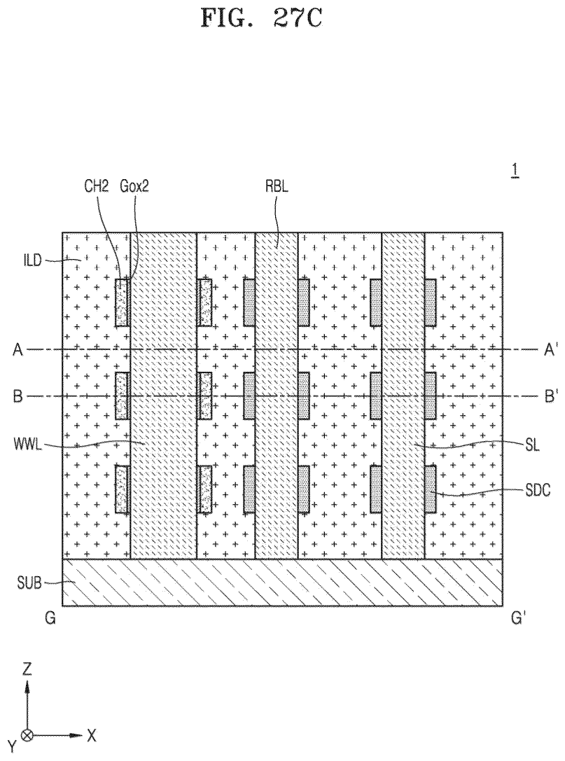

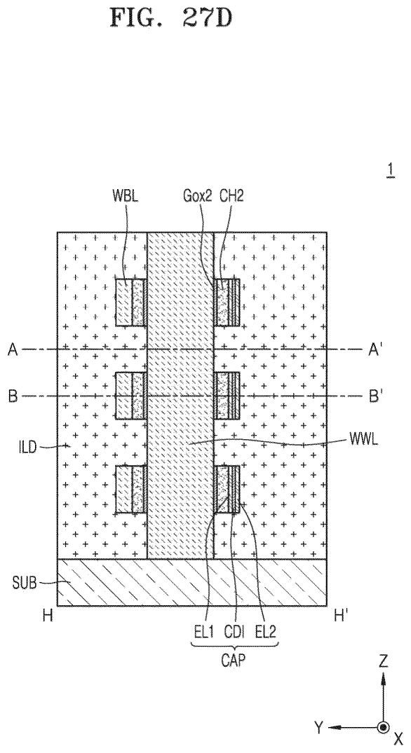

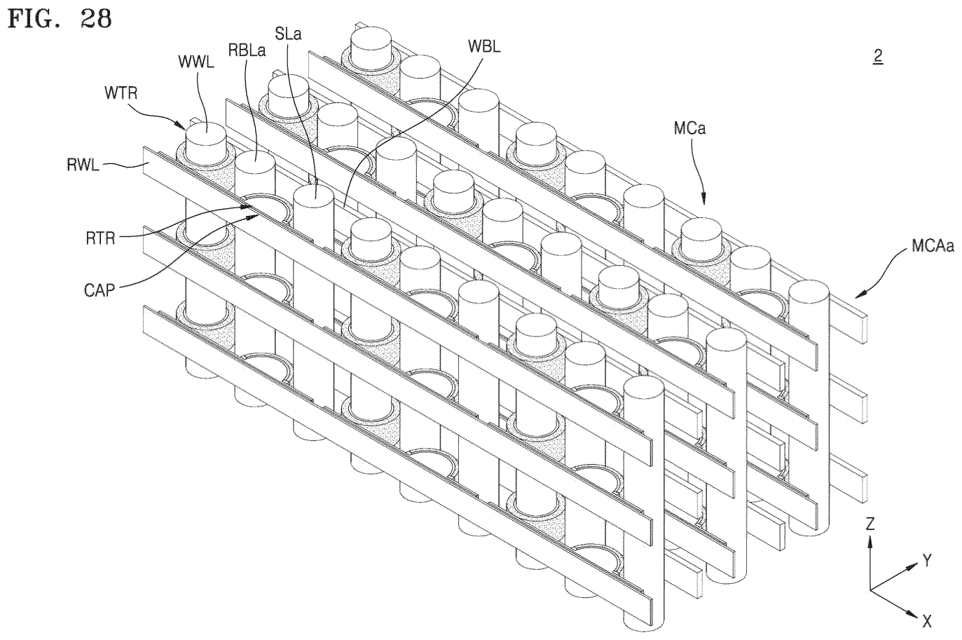

Referring to FIGS. 25A through 25D and 26A through 26D together, the plurality of first sacrificial layers ST1, the plurality of second sacrificial layers ST2, and the plurality of third sacrificial layers ST3 may be all removed. In some embodiments, by removing first the plurality of second sacrificial layers ST2 through the recess space RS, the plurality of first sacrificial layers ST1 and the plurality of third sacrificial layers ST3 may be removed.

As a result of the removing of all of the plurality of first sacrificial layers ST1, the plurality of second sacrificial layers ST2, and the plurality of third sacrificial layers ST3, on the substrate SUB, the capacitor CAP including the first electrode EL1, the second electrode EL2, and the capacitor dielectric layer CDI, the write word line WWL, the write bit line WBL, the source line SL, the source/drain contact layer SDC, the first channel layer CH1, the first gate dielectric layer Gox1, the insulating spacer ISP, the second channel layer CH2, and the second gate dielectric layer Gox2 may be arranged.

Referring to FIGS. 25A through 25D, 26A through 26D, and 27A through 27D together, by forming an interlayer insulating layer ILD filling spaces from which the plurality of first sacrificial layers ST1, the plurality of second sacrificial layers ST2, and the plurality of third sacrificial layers ST3 have been removed, the semiconductor memory device 1 may be formed. The semiconductor memory device 1 may include the plurality of memory cells MC. The memory cell MC has been described with reference to FIGS. 2A and 2B, and thus a detailed description thereof is omitted for conciseness.

The interlayer insulating layer ILD may, on the substrate SUB, surround the capacitor CAP including the first electrode EL1, the second electrode EL2, and the capacitor dielectric layer CDI, the write word line WWL, the write bit line WBL, the read bit line RBL, the source line SL, the source/drain contact layer SDC, the first channel layer CH1, the first gate dielectric layer Gox1, the insulating spacer ISP, the second channel layer CH2, and the second gate dielectric layer Gox2. In some embodiments, the interlayer insulating layer ILD may be formed to cover side surfaces of each of the write word line WWL, the read bit line RBL, and the source line SL, but not to cover an upper surface thereof. For example, the upper surface of the interlayer insulating layer ILD, the upper surface of the write word line WWL, the upper surface of the read bit line RBL, and the upper surface of the source line SL may be at the same vertical level to be coplanar. In some embodiments, the semiconductor memory device 1 may include a wiring line connected to each of the write word line WWL, the read bit line RBL, and the source line SL in the substrate SUB and/or on the interlayer insulating layer ILD. In some embodiments, the semiconductor memory device 1 may include a wiring line or a wiring plug connected to each of the second electrode EL2 of the capacitor CAP, which is the read word line RWL, and the write bit line WBL, at the same vertical level as the interlayer insulating layer ILD.

FIG. 28 is a perspective view of a memory cell array MCAa of a semiconductor memory device 2, according to an embodiment.

Referring to FIG. 28, the semiconductor memory device 2 may include the memory cell array MCAa. The memory cell array MCAa may include a plurality of memory cells MCa arranged apart from each other in a first horizontal direction (e.g., an X direction), a second horizontal direction (e.g., a Y direction) orthogonal to the first horizontal direction, and a vertical direction (e.g., a Z direction), and arranged to form rows in the first horizontal direction and columns in the second horizontal direction. Each of the plurality of memory cells MCa may include the write transistor WTR, the read transistor RTR, and the capacitor CAP. The semiconductor memory device 2 may include a three-dimensional 2T1C semiconductor memory device.

In the memory cell array MCAa, a plurality of read word lines RWL may be spaced apart from each other in each of the second horizontal direction and the vertical direction, and may extend in the first horizontal direction. Each of the plurality of read word lines RWL may have a bar shape extending in the first horizontal direction. For example, the memory cells MCa arranged in the first horizontal direction may share the read word line RWL.

In the memory cell array MCAa, the plurality of write bit lines WBL may be spaced apart from each other in each of the second horizontal direction and the vertical direction, and may extend in the first horizontal direction. In the memory cell array MCAa, the plurality of read word lines RWL and the plurality of write bit lines WBL may be alternately arranged in the second horizontal direction at the same vertical level. The memory cells MCa arranged in the first horizontal direction may share the write bit line WBL.

In the memory cell array MCAa, the plurality of write word lines WWL, a plurality of read bit lines RBLa, and a plurality of source lines SLa may be spaced apart from each other in each of the first horizontal direction and the second horizontal direction, and may extend in the vertical direction. The memory cells MCa arranged in the vertical direction may share the write word line WWL, a read bit line RBLa, and a source line SLa. The write word line WWL, the read bit line RBLa, and the source line SLa may be repeatedly arranged in the first horizontal direction. For example, the semiconductor memory device 2 may include a three-dimensional 2T-MFeFET or a three-dimensional 2T-MFMFET.

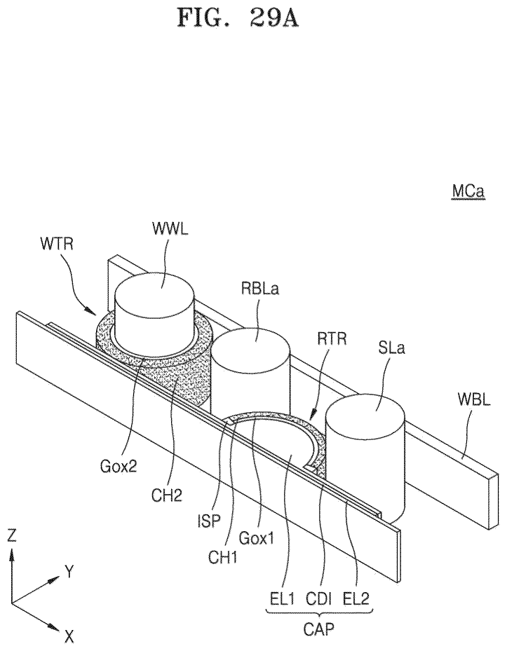

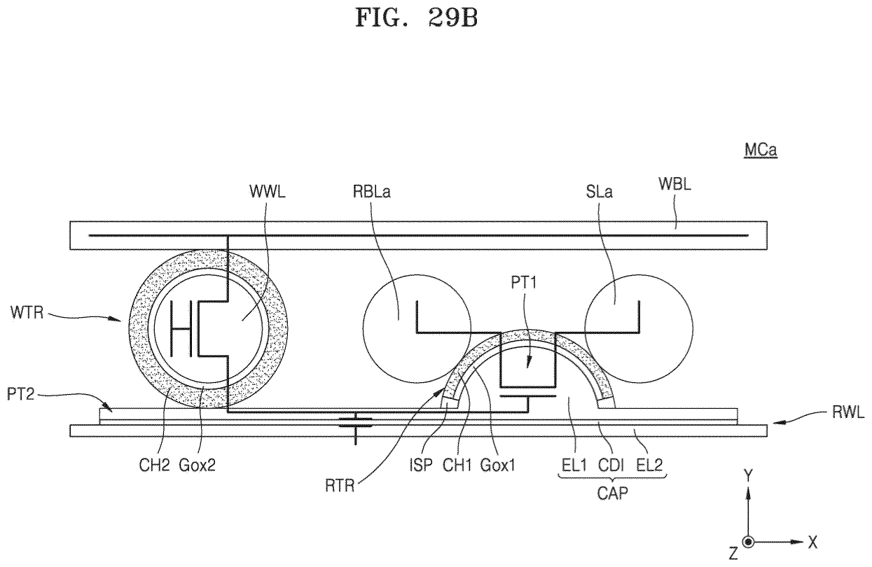

FIGS. 29A and 29B are a perspective view of the memory cell MCa of the semiconductor memory device 2 and plan view of an equivalent circuit diagram thereof, according to embodiments, respectively.

Referring to FIGS. 29A and 29B, the memory cell MCa may include the write transistor WTR, the read transistor RTR, and the capacitor CAP. In some embodiments, the memory cell MCa may include a 2T-MFeFET or a 2T-MFMFET in which the capacitor CAP includes a ferroelectric capacitor.

The capacitor CAP may include the first electrode EL1, the second electrode EL2, and the capacitor dielectric layer CDI arranged between the first electrode EL1 and the second electrode EL2. The first electrode EL1 of the capacitor CAP may include a first portion PT1 adjacent to the read bit line RBLa and the source line SLa between the read bit line RBLa and the source line SLa, and a second portion PT2 extending in the first horizontal direction between the write transistor WTR and the read transistor RTR. The second electrode EL2 of the capacitor CAP may be referred to as the read word line RWL. In some embodiments, the capacitor CAP may include a ferroelectric capacitor including a ferroelectric material which is an insulating material in which the capacitor dielectric layer CDI of the capacitor CAP has hysteresis characteristics.

The read transistor RTR may include the first channel layer CH1 and the first gate dielectric layer Gox1. The first side of the first channel layer CH1 may be interconnected to the source line SLa, and the second side of the first channel layer CH1 may be interconnected to the read bit line RBLa. The first electrode EL1 of the capacitor CAP may include the gate electrode of the read transistor RTR. An insulating spacer ISP may be arranged between the first channel layer CH1 and the first electrode EL1 of the capacitor CAP.

The first channel layer CH1 and the source line SLa may directly contact each other, and the first channel layer CH1 and the read bit line RBLa may directly contact each other. In other words, the memory cell MCa may omit the source/drain contact layer SDC1 included in the memory cell MC and the source/drain contact layer SDC including the source contact layer SDC2 illustrated in FIGS. 2A and 2B.

The write transistor WTR may include the second channel layer CH2 and the second gate dielectric layer Gox2. A first side of the second channel layer CH2 may be interconnected to the second portion PT2 of the first electrode EL1 of the capacitor CAP, and a second side of the second channel layer CH2 may be interconnected to the write bit line WBL. The write word line WWL may include the gate electrode of the write transistor WTR.

Referring to FIGS. 28, 29A, and 29B together, in the semiconductor memory device 2, the write word line WWL, the read bit line RBLa, and the source line SLa may extend in the vertical direction, share the memory cells MCa arranged in the vertical direction, and because the write bit line WBL and the read word line RWL extend in the first horizontal direction and share the memory cells MCa arranged in the first horizontal direction, the plurality of memory cells MCa may constitute the memory cell array MCAa arranged in three-dimensions. The semiconductor memory device 2 may sense the capacitance ratio of the capacitor CAP to the read transistor RTR, and thus, the capacitor CAP of a small size may be implemented and the power consumption thereof may be reduced.

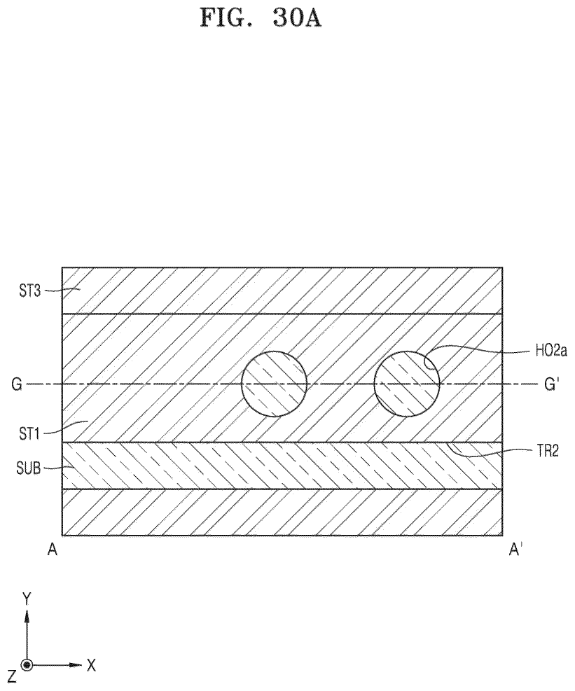

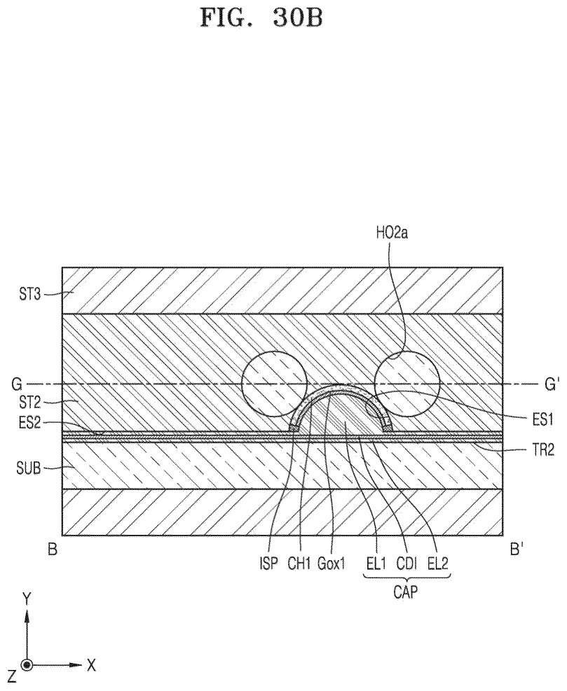

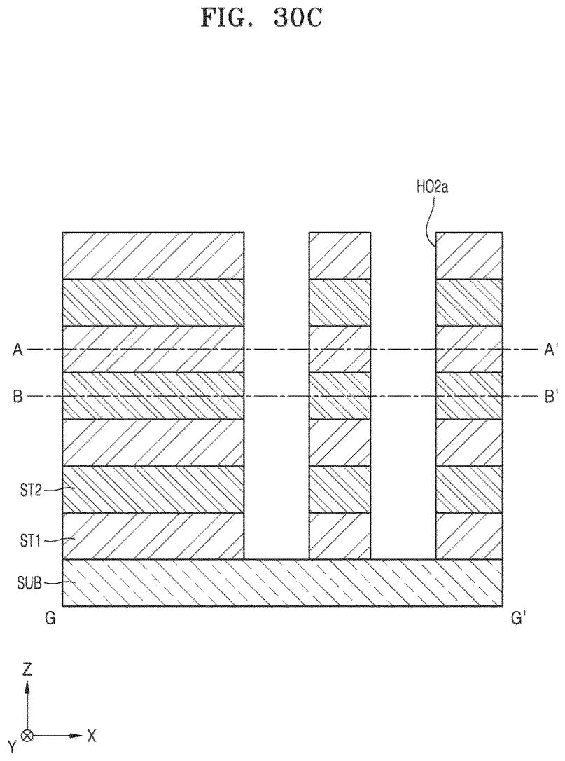

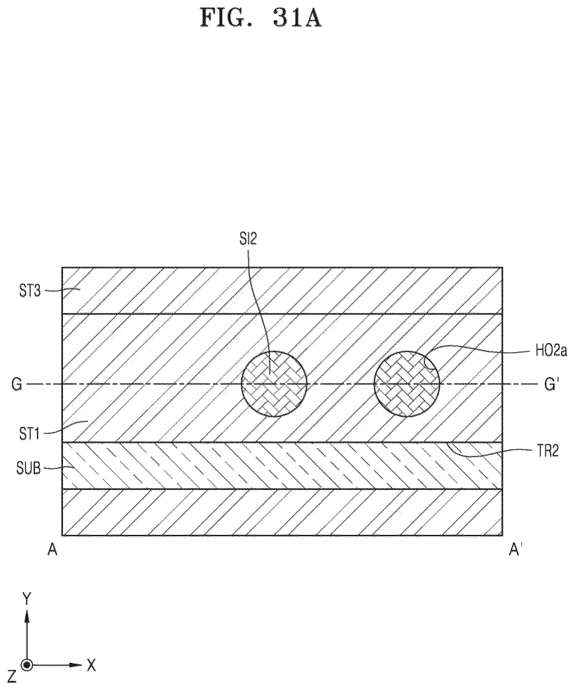

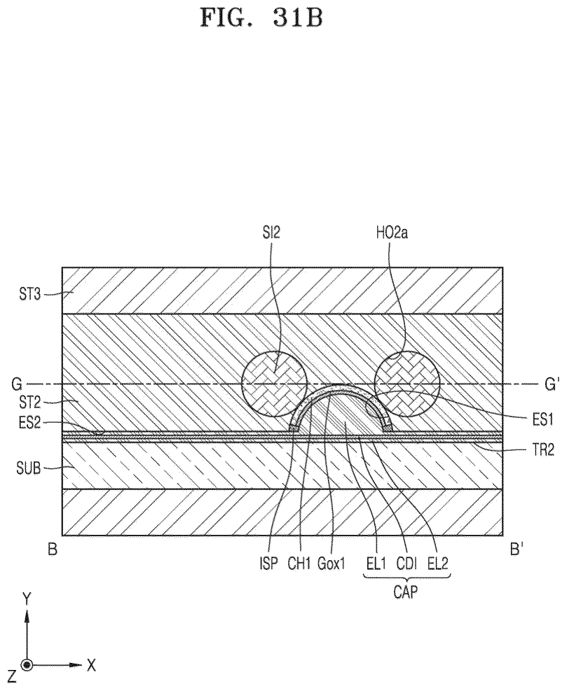

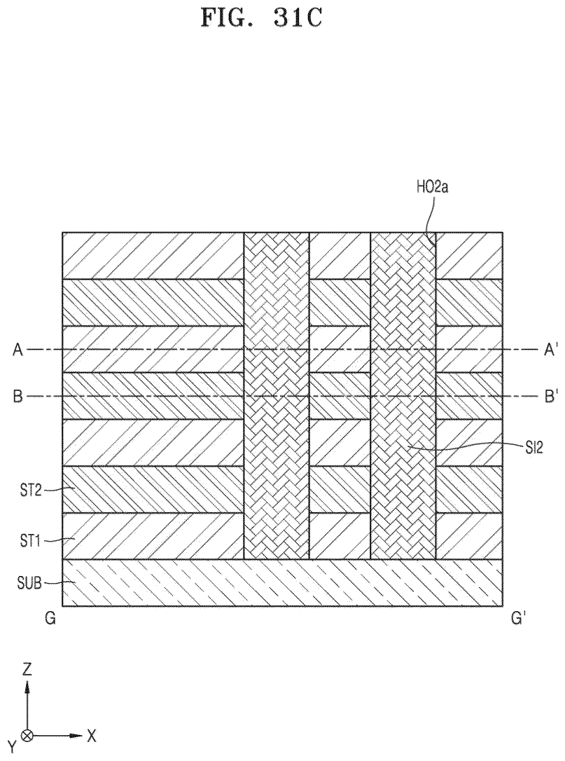

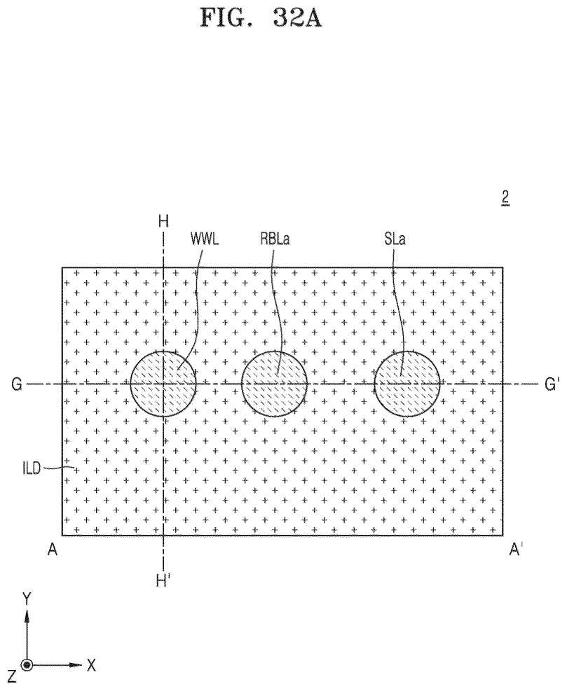

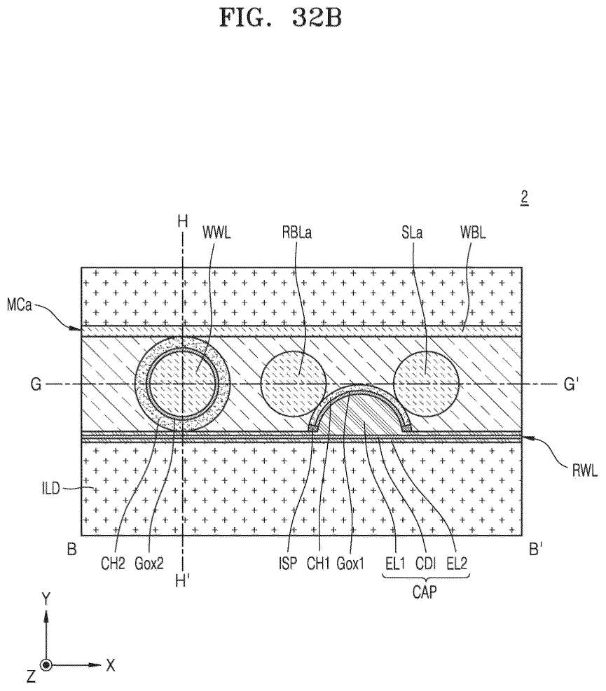

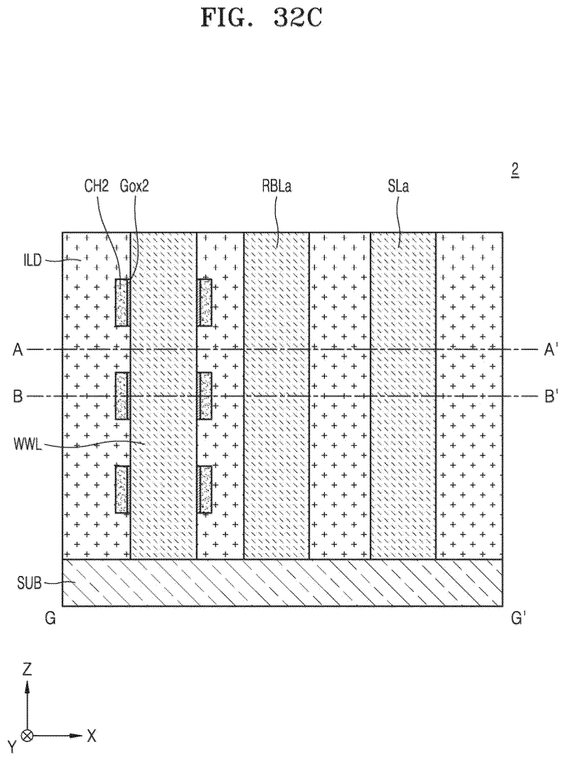

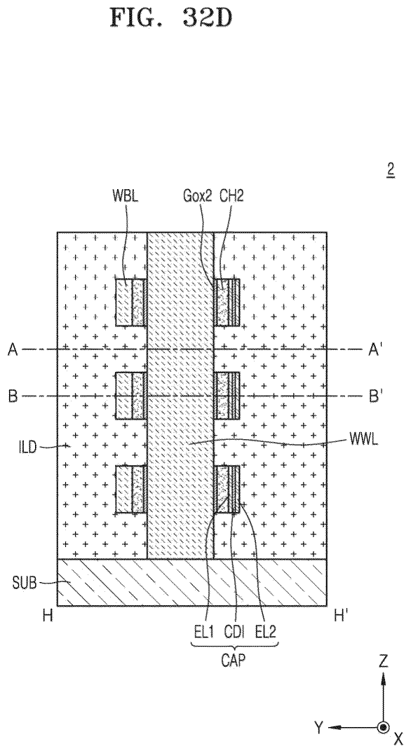

FIGS. 30A through 30C and 31A through 31C are plan views and cross-sectional views of a manufacturing method of a semiconductor memory device according to a process sequence, according to embodiments, and FIGS. 32A through 32D are diagrams of the semiconductor memory device 2 according to embodiments. FIGS. 30A, 31A, and 32A are plan views taken along line A-A′ in FIGS. 30C, 31C, and 32C, viewed from the top side, respectively; FIGS. 30B, 31B, and 32B are plan views taken along line B-B′ in FIGS. 30C, 31C, and 32C, viewed from the top, respectively; FIGS. 30C, 31C, and 32C are cross-sectional views taken along line G-G′ in FIGS. 30A, 31A, and 32A; and FIG. 32D is a cross-sectional view taken along line H-H′ in FIG. 32A.

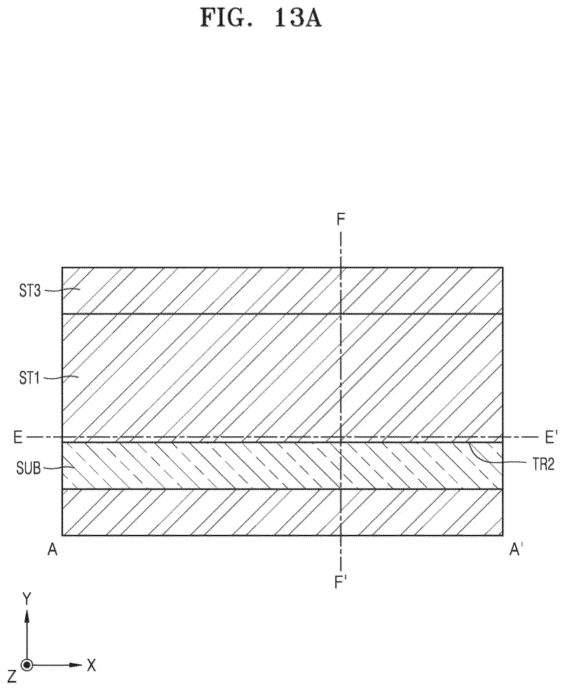

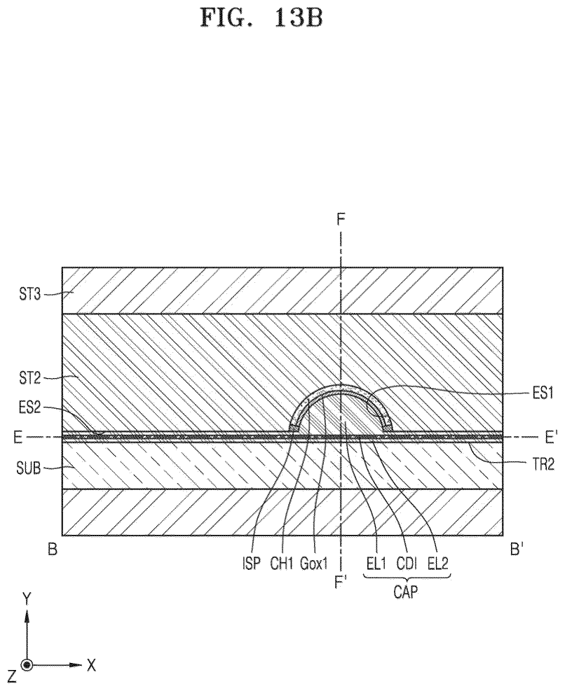

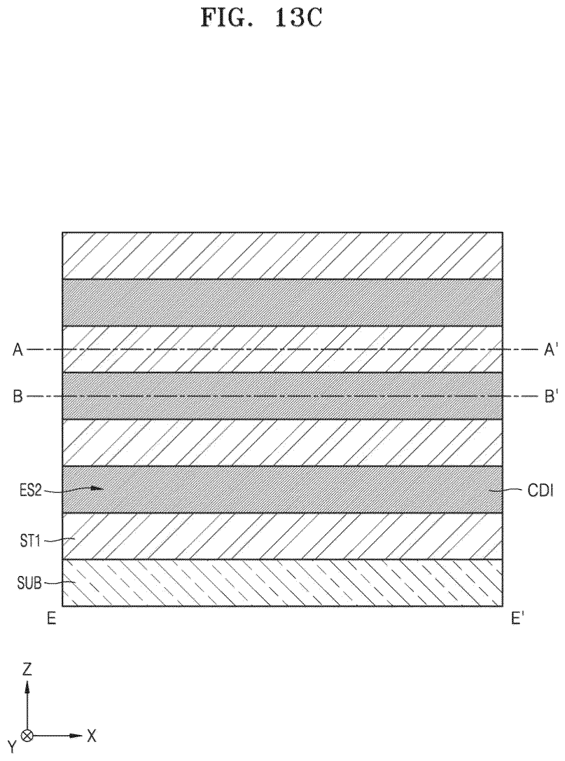

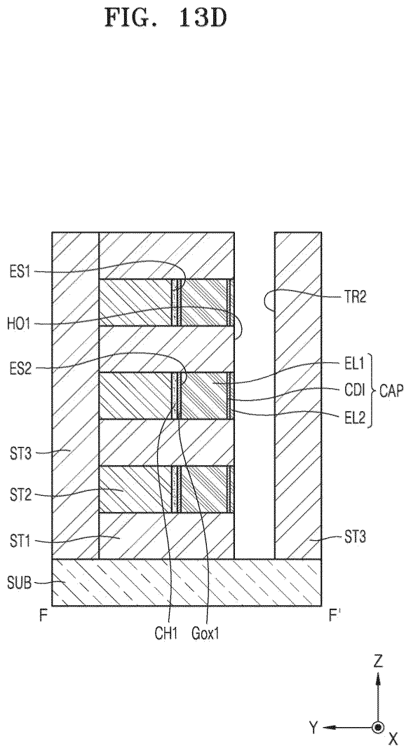

Referring to FIGS. 30A through 30C, by removing portions of the stacked structures of the plurality of first sacrificial layers ST1 and the plurality of second sacrificial layers ST2 from the results of FIGS. 13A through 13C, a plurality of second through holes HO2a penetrating the stacked structure of the plurality of first sacrificial layers ST1 and the plurality of second sacrificial layers ST2 may be formed. For example, two second through holes HO2a may be formed adjacent to each other in one first expansion space ES1. In some embodiments, the second through hole HO2a may be formed such that a horizontal cross-section thereof has a circular shape.

Each of the two second through holes HO2a may be formed to be adjacent to and to contact the first expansion space ES1. A portion of the first channel layer CH1 may be exposed in each of the two second through holes HO2a. For example, the plurality of first sacrificial layers ST1 and the plurality of second sacrificial layers ST2 may be exposed on an inner side wall of each of the two second through holes HO2, and the substrate SUB may be exposed on a bottom surface thereof.

Two second through holes HO2a adjacent to one first expansion space ES1 may be formed to be spaced apart from each other in the first horizontal direction. Two second through holes HO2a adjacent to one first expansion space ES1 may be formed to be more adjacent to the other third sacrificial layer ST3 than the one first expansion space ES1. The second through hole HO2a may be formed to be spaced apart from each of a plurality of second trenches TR2 and the third sacrificial layer ST3 in the second horizontal direction, between the plurality of second trenches TR2 and the third sacrificial layer ST3 in plan view. For example, the second through hole HO2a may be formed by removing a portion of each of the plurality of first sacrificial layers ST1 and the plurality of second sacrificial layers ST2, positioned between the plurality of second trenches TR2 and the third sacrificial layer ST3 in plan view.

Referring to FIGS. 31A through 31C together, the second sacrificial insulating layer SI2 filling the plurality of second through holes HO2a may be formed. The second sacrificial insulating layer SI2 may be formed to completely fill the plurality of second through holes HO2a.

Referring to FIGS. 32A through 32D together, and referring to descriptions given with reference to FIGS. 18A through 18C, 19A through 19C, 20A through 20C, 21A through 21C, 22A through 22C, 23A through 23C, 24A through 24D, 25A through 25D, 26A through 26D, and 27A through 27C, by forming the second channel layer CH2, the second gate dielectric layer Gox2, the read bit line RBLa, the source line SLa, the write word line WWL, the plurality of write bit lines WBL, and the interlayer insulating layer ILD, the semiconductor memory device 2 may be formed. The semiconductor memory device 2 may include the plurality of memory cells MCa. The memory cell MCa has been described with reference to FIGS. 29A and 29B, and thus a detailed description thereof is omitted for conciseness.

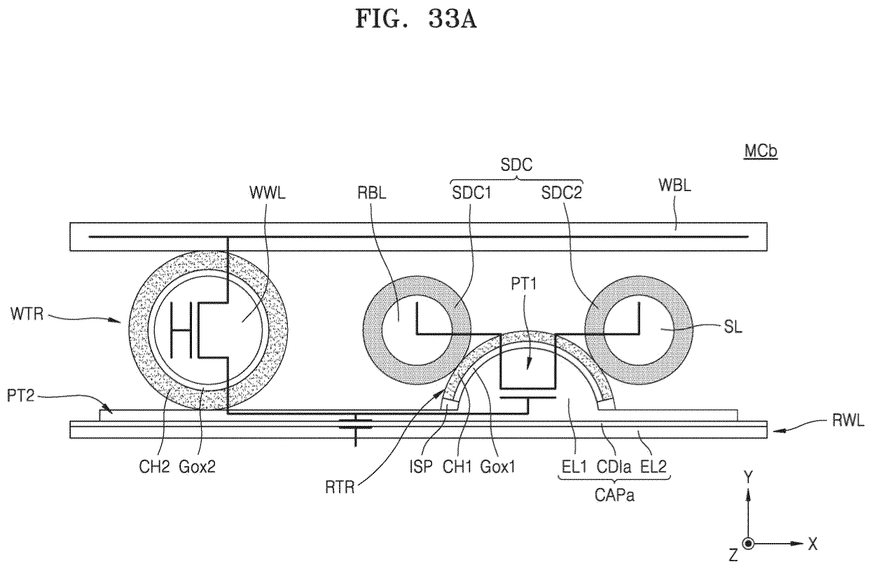

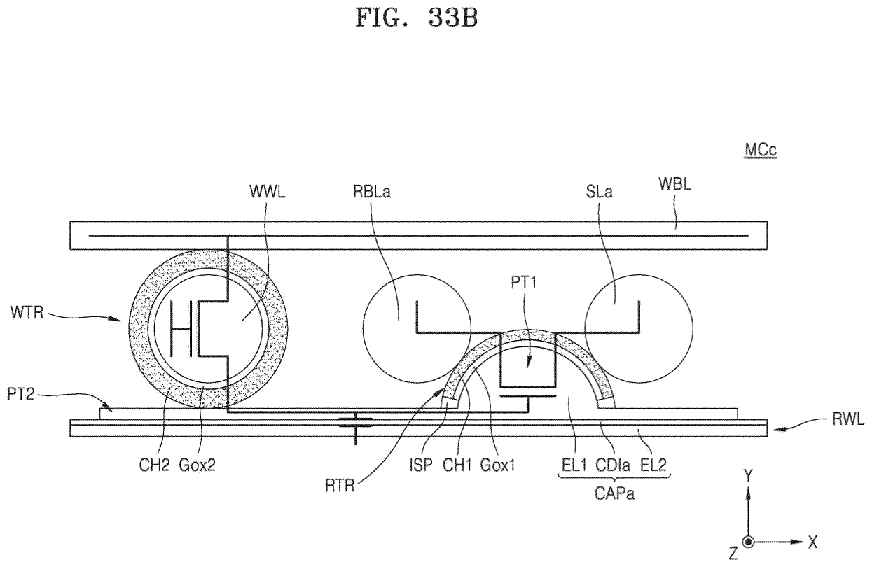

FIGS. 33A and 33B are plan views of equivalent circuit diagrams of memory cells MCb and MCc of a semiconductor memory device, respectively, according to embodiments.

Referring to FIGS. 33A, the memory cell MCb may include the write transistor WTR, the read transistor RTR, and a capacitor CAPa. In some embodiments, the memory cell MCb may include a 2T-MFeFET or a 2T-MFMFET in which the capacitor CAPa includes a ferroelectric capacitor.

The capacitor CAPa may include the first electrode EL1, the second electrode EL2, and a capacitor dielectric layer CDIa arranged between the first electrode EL1 and the second electrode EL2. The first electrode EL1 of the capacitor CAPa may include a first portion PT1 adjacent to the read bit line RBL and the source line SL between the read bit line RBL and the source line SL, and a second portion PT2 extending in the first horizontal direction (e.g., the X direction) between the write transistor WTR and the read transistor RTR. An extension length of the capacitor dielectric layer CDIa included in the capacitor CAPa in the first horizontal direction may be greater than the extension length of the second portion PT2 of the first electrode EL1 of the capacitor CAPa. The capacitor dielectric layer CDIa may have a bar shape extending in the first horizontal direction corresponding to the memory cells MCb arranged in the first horizontal direction and sharing the read word line RWL. For example, the extension length of the capacitor dielectric layer CDIa may be substantially the same as the extension length of the second electrode EL2, in the first horizontal direction.

In the process of forming the plurality of recess spaces RS illustrated in FIGS. 25A through 25C, when a portion of the first electrode EL1 is removed without removing a portion of the capacitor dielectric layer CDI, the capacitor dielectric layer CDIa having an extension length substantially the same as that of the second electrode EL2 illustrated in FIG. 33A may be formed.

Referring to FIGS. 33B, the memory cell MCc may include the write transistor WTR, the read transistor RTR, and the capacitor CAPa. In some embodiments, the memory cell MCc may include a 2T-MFeFET or a 2T-MFMFET in which the capacitor CAPa includes a ferroelectric capacitor.

The capacitor CAPa may include the first electrode EL1, the second electrode EL2, and the capacitor dielectric layer CDIa arranged between the first electrode EL1 and the second electrode EL2. The first electrode EL1 of the capacitor CAPa may include the first portion PT1 adjacent to the read bit line RBLa and the source line SLa between the read bit line RBLa and the source line SLa, and the second portion PT2 extending in the first horizontal direction between the write transistor WTR and the read transistor RTR. An extension length of the capacitor dielectric layer CDIa included in the capacitor CAPa in the first horizontal direction may be greater than the extension length of the second portion PT2 of the first electrode EL1 of the capacitor CAPa. The capacitor dielectric layer CDIa may have a bar shape extending in the first horizontal direction corresponding to the memory cells MCc arranged in the first horizontal direction and sharing the read word line RWL. For example, the extension length of the capacitor dielectric layer CDIa may be substantially the same as the extension length of the second electrode EL2, in the first horizontal direction.

While various embodiments have been particularly shown and described with reference to the drawings, it will be understood that various change in form and details may be made therein without departing from the spirit and scope of the following claims.

What is claimed is:

1. A semiconductor memory device comprising:
a write bit line and a read word line each extending in a first horizontal direction, the write bit line being spaced apart from the read word line in a second horizontal direction orthogonal to the first horizontal direction;
a write word line, a read bit line, and a source line, each between the write bit line and the read word line and extending in a vertical direction, the write word line, the read bit line, and the source line spaced apart from each other in the first horizontal direction;
a capacitor electrode comprising a first portion and a second portion;
a capacitor dielectric layer arranged between the capacitor electrode and the read word line;
a first gate dielectric layer covering a side surface of the first portion of the capacitor electrode;
a first channel layer adjacent to the read bit line and the source line and covering the first gate dielectric layer;
a second gate dielectric layer covering a portion of a side surface of the write word line; and
a second channel layer connected to the second portion of the capacitor electrode and to the write bit line and covering the second gate dielectric layer.

2. The semiconductor memory device of claim 1, further comprising a plurality of memory cells, each including a capacitor, a read transistor, and a write transistor,
wherein the capacitor electrode, the read word line, and the capacitor dielectric layer constitute the capacitor,
wherein the first channel layer, the first gate dielectric layer, the source line, the read bit line, and the first portion of the capacitor electrode constitute the read transistor, and
wherein the second channel layer, the second gate dielectric layer, the second portion of the capacitor electrode, the write bit line, and the write word line constitute the write transistor.

3. The semiconductor memory device of claim 1,
wherein the first portion of the capacitor electrode has a semi-circular shape in plan view, and
wherein the second portion of the capacitor electrode has a bar shape extending in the first horizontal direction.

4. The semiconductor memory device of claim 3,
wherein, in the first horizontal direction, an extension length of the second portion of the capacitor electrode is less than an extension length of the read word line.

5. The semiconductor memory device of claim 3,
wherein each of the first gate dielectric layer and the first channel layer has a half-ring shape in plan view.

6. The semiconductor memory device of claim 1,
wherein the write word line has a circular shape in plan view, and
wherein each of the second gate dielectric layer and the second channel layer has a ring shape in plan view.

7. The semiconductor memory device of claim 1, wherein each of the source line and the read bit line has a circular shape in plan view.

8. The semiconductor memory device of claim 7, further comprising a source/drain contact layer that is arranged between the source line and the first channel layer and arranged between the read bit line and the first channel layer,
wherein the source/drain contact layer has a ring shape in plan view.

9. The semiconductor memory device of claim 7, wherein each of the source line and the read bit line is directly in contact with the first channel layer.

10. The semiconductor memory device of claim 1, further comprising an insulating spacer arranged between the first channel layer and the capacitor electrode.

11. A semiconductor memory device comprising:
a plurality of memory cells each including a capacitor, a read transistor, and a write transistor, the plurality of memory cells spaced apart from each other in rows in a first horizontal direction and in columns in a second horizontal direction, and spaced apart from each other in a vertical direction,
wherein the capacitor comprises a capacitor electrode including a first portion and a second portion, a read word line extending in the first horizontal direction, and a capacitor dielectric layer arranged between the first portion of the capacitor electrode and the read word line,
wherein the read transistor comprises:
a source line extending in the vertical direction,
a read bit line extending in the vertical direction and spaced apart from the source line in the first horizontal direction,
the first portion of the capacitor electrode,
a first gate dielectric layer covering a side surface of the first portion of the capacitor electrode, and
a first channel layer adjacent to each of the read bit line and the source line and covering the first gate dielectric layer, and
wherein the write transistor comprises:
the second portion of the capacitor electrode,
a write bit line extending in the first horizontal direction,
a write word line extending in the vertical direction,
a second gate dielectric layer covering a portion of a side surface of the write word line, and
a second channel layer connected to the second portion of the capacitor electrode and to the write bit line and covering the second gate dielectric layer.

12. The semiconductor memory device of claim 11,
wherein the write bit line is spaced apart from the read word line in the second horizontal direction, and
wherein the write word line, the read bit line, and the source line are sequentially spaced apart from each other in the first horizontal direction between the write bit line and the read word line that are spaced apart from each other in the second horizontal direction.

13. The semiconductor memory device of claim 11,
wherein memory cells that are arranged in the first horizontal direction among the plurality of memory cells share the write bit line, and
wherein a drain of the write transistor included in each of the memory cells that are arranged in the first horizontal direction is connected to the write bit line.

14. The semiconductor memory device of claim 11,
wherein memory cells that are arranged in the vertical direction among the plurality of memory cells share the write word line, and
wherein a gate of the write transistor included in each of the memory cells that are arranged in the vertical direction is connected to the write word line.

15. The semiconductor memory device of claim 11,
wherein memory cells that are arranged in the vertical direction among the plurality of memory cells share the read bit line,
wherein a source of the read transistor included in each of the memory cells that are arranged in the vertical direction is connected to the source line, and
wherein a drain of the read transistor is connected to the read bit line.

16. The semiconductor memory device of claim 11,
wherein the first portion of the capacitor electrode has a semi-circular shape in plan view, and the second portion of the capacitor electrode extends less than an extension length of the read word line in the first horizontal direction, and
wherein memory cells that are arranged in the first horizontal direction among the plurality of memory cells share the read word line.

17. The semiconductor memory device of claim 16,
wherein each of the first gate dielectric layer and the first channel layer has a half-ring shape in plan view,
wherein each of the second gate dielectric layer and the second channel layer has a ring shape in plan view.

18. A semiconductor memory device comprising:
a plurality of memory cells, each including a capacitor, a read transistor, and a write transistor, the plurality of memory cells spaced apart from each other in rows in a first horizontal direction and in columns a second horizontal direction, and spaced apart from each other in a vertical direction,
wherein the capacitor comprises:
a capacitor electrode in which a first portion having a semi-circular shape in plan view and a second portion having a bar shape extending in the first horizontal direction are integrated,
a read word line extending longer than the second portion of the capacitor electrode in the first horizontal direction, and
a capacitor dielectric layer arranged between the first portion of the capacitor electrode and the read word line,
wherein the read transistor comprises:
a source line extending in the vertical direction,
a read bit line extending in the vertical direction and spaced apart from the source line in the first horizontal direction,
the first portion of the capacitor electrode,
a first gate dielectric layer covering a side surface of the first portion of the capacitor electrode and having a half-ring shape in plan view,
a first channel layer having a half-ring shape in plan view,
the first channel layer adjacent to each of the read bit line and the source line and covering the first gate dielectric layer, and
a source/drain contact layer arranged between the source line and the first channel layer and arranged between the read bit line and the first channel layer,
wherein the write transistor comprises:
the second portion of the capacitor electrode,
a write bit line extending in the first horizontal direction and spaced apart from the read word line in the second horizontal direction,
a write word line extending in the vertical direction,
a second gate dielectric layer covering a portion of a side surface of the write word line and having a ring shape in plan view, and
a second channel layer having a half-ring shape in plan view, the second channel layer connected to each of the second portion of the capacitor electrode and the write bit line and covering the second gate dielectric layer, and
wherein the write bit line is spaced apart from the read word line in the second horizontal direction, and the write word line, the read bit line, and the source line are sequentially spaced apart from each other in the first horizontal direction between the write bit line and the read word line that are spaced apart from each other in the second horizontal direction.

19. The semiconductor memory device of claim 18,
wherein each of the source line and the read bit line has a circular shape in plan view, and
wherein the source/drain contact layer has a ring shape in plan view.

20. The semiconductor memory device of claim 18,
wherein the capacitor dielectric layer comprises a ferroelectric material, and
wherein each of the first channel layer and the second channel layer comprises an oxide semiconductor material.
